(19) United States
(12) Patent Application Publication
(10) Pub. No.: US 2026/0204223 A1
(43) Pub. Date: Jul. 16, 2026

(54) Gate Driving Circuit, Display Substrate and Display Apparatus

(71) Applicants: Yunnan Invensight Optoelectronics Technology Co., Ltd., Kunming, Yunnan (CN); BOE Technology Group Co., Ltd., Beijing (CN); Beijing BOE Technology Development Co., Ltd., Beijing (CN)

(72) Inventors: Zhijian ZHU, Beijing (CN); Qingshan SHAN, Beijing (CN); Yinhu HUANG, Beijing (CN); Shengji YANG, Beijing (CN); Yue HUANG, Beijing (CN); Dacheng ZHANG, Beijing (CN); Jiazao PENG, Beijing (CN)

(21) Appl. No.: 18/866,997

(22) PCT Filed: Jan. 8, 2024
(86) PCT No.: PCT/CN2024/071152

§ 371 Date: Nov. 18, 2024

(51) Int. Cl. G09G 3/3266

(52) U.S. Cl. CPC G09G 3/3266; G09G 2300/0408; G09G 2300/0426; G09G 2300/0814; G09G 2320/0233

(57) ABSTRACT

Disclosed are a gate driving circuit, a display substrate, and a display apparatus. The gate driving circuit includes an output circuit (300) disposed on a silicon base substrate, and the output circuit (300) includes at least one level converter and the row driving enhancer, wherein the level converter is configured to perform voltage domain conversions on target timings, the row driving enhancer is configured to enhance the converted signals and output them to a scanning signal line of the display region, at least one input signal of the row driving enhancer is provided by the level converter, and the row driving enhancer is disposed on a side of the level converter close to the display region.

### CROSS-REFERENCE TO RELATED APPLICATION

The present application is a U.S. National Phase Entry of International Application No. PCT/CN2024/071152 having an international filing date of Jan. 8, 2024. The above-identified application is hereby incorporated by reference.

### TECHNICAL FIELD

The present disclosure relates to, but is not limited to, the field of display technologies, and particularly to a gate driving circuit, a display substrate and a display apparatus.

### BACKGROUND

Micro organic light emitting diodes (Micro OLEDs) are micro displays developed in recent years, and a silicon-based OLED is one of them. Silicon-based OLED is a new display technology that combines semiconductor process and OLED display technology and uses wafers as the substrate to prepare OLED devices. Since it has the advantages of both semiconductor process technology and OLED display technology, silicon-based OLED not only has high pixel density (Pixels Per Inch, PPI for short), but also has the advantages of high brightness, low power consumption, high response speed, high color gamut and high thermal stability.

### SUMMARY

The following is a summary of subject matters described herein in detail. This summary is not intended to limit the protection scope of claims.

In one aspect, an embodiment of the present disclosure provides a gate driving circuit including an output circuit disposed on a silicon base substrate, and the output circuit includes at least one level converter and at least one row driving enhancer, wherein the level converter is configured to perform voltage domain conversions on target timings, the row driving enhancer is configured to enhance converted signals and output them to a scanning signal line of a display region, and at least one input signal of the row driving enhancer is provided by the level converter, and the row driving enhancer is disposed on a side of the level converter close to the display region.

In an exemplary implementation, the level converter includes at least a first inverter, a first level conversion unit, and a second level conversion unit; an input end of the first level conversion unit is connected to an input end of the first inverter, and an output end of the first level conversion unit is connected to the row driving enhancer; an input end of the second level conversion unit is connected to an output end of the first inverter, and an output end of the second level conversion unit is connected to the row driving enhancer; and the first level conversion unit is disposed on a side of the first inverter close to the display region, and the second level conversion unit is disposed on a side of the first level conversion unit close to the display region.

In an exemplary implementation, the level converter further includes a selection output unit, which is connected to the output end of the first level conversion unit and the output end of the second level conversion unit, respectively, and the selection output unit is configured to selectively output an output signal of the first level conversion unit or an output signal of the second level conversion unit under the control of a selection input signal.

In an exemplary implementation, the first inverter includes a first P-type transistor and a first N-type transistor disposed on a side of the first P-type transistor in a second direction; the first level conversion unit includes a first P-type transistor unit disposed on a side of the first P-type transistor in a first direction and a first N-type transistor unit disposed on a side of the first P-type transistor unit in the second direction, the second level conversion unit includes a second P-type transistor unit disposed on a side of the first P-type transistor unit in the first direction and a second N-type transistor unit disposed on a side of the second P-type transistor unit in the second direction, and the first direction intersects with the second direction; the first P-type transistor unit includes a second P-type transistor to a seventh P-type transistor disposed on a side of the first P-type transistor in the first direction and sequentially along the first direction; the second P-type transistor unit includes an eighth P-type transistor to a thirteenth P-type transistor disposed on a side of the seventh P-type transistor in the first direction and sequentially along the first direction; the first N-type transistor unit includes a second N-type transistor disposed on a side of the seventh P-type transistor in the second direction, and the second N-type transistor unit includes a third N-type transistor disposed on a side of the eighth P-type transistor in the second direction; at least one P-type transistor includes at least a P-type active layer, at least one N-type transistor includes at least an N-type active layer, and the P-type active layers of the second P-type transistor to the thirteenth P-type transistor are of an integral structure connected to each other; the second P-type transistor to the seventh P-type transistor and the eighth P-type transistor to the thirteenth P-type transistor are symmetrical with respect to an active center line, the second N-type transistor and the third N-type transistor are symmetrical with respect to the active center line, the active center line is a straight line that bisects the P-type active layers of the second P-type transistor to the thirteenth P-type transistor in the first direction and extends along the second direction.

In an exemplary implementation, the at least one P-type transistor further includes a P-type gate electrode, and the at least one N-type transistor further includes an N-type gate electrode; P-type gate electrodes of the second P-type transistor to the seventh P-type transistor and P-type gate electrodes of the eighth P-type transistor to the thirteenth P-type transistor are symmetrical with respect to the active center line and N-type gate electrode of the second N-type transistor, and N-type gate electrode of the third N-type transistor are symmetrical with respect to the active center line.

In an exemplary implementation, the at least one P-type transistor further includes a P-type source electrode and a P-type drain electrode, and the at least one N-type transistor further includes an N-type source electrode and an N-type drain electrode; P-type source electrodes of the second to seventh P-type transistors and P-type source electrodes of the eighth to thirteenth P-type transistors are symmetrical with respect to the active center line, and P-type drain electrodes of the second to seventh P-type transistors and P-type drain electrodes of the eighth to thirteenth P-type transistors are symmetrical with respect to the active center line; an N-type source electrode of the second N-type transistor and an N-type source electrode of the third N-type transistor are symmetrical with respect to the active center line, and an N-type drain electrode of the second N-type transistor and an N-type drain electrode of the third N-type transistor are symmetrical with respect to the active center line.

In an exemplary implementation, in the first direction, there is a voltage domain distance between an edge of a P-type drain electrode of the first P-type transistor on a side close to the second P-type transistor and an edge of a P-type source electrode of the second P-type transistor on a side close to the first P-type transistor, and the voltage domain distance is greater than or equal to 3.67 μm.

In an exemplary implementation, the level converter further includes a first power supply line, a second power supply line, and a ground line, and the first power supply line, the second power supply line, and the ground line are in a shape of a line or a bend line extending along the first direction; the first power supply line is disposed on a side of the first P-type transistor to the thirteenth P-type transistor away from the first N-type transistor to the third N-type transistor, the second power supply line is disposed on a side of the second N-type transistor to the third N-type transistor away from the second P-type transistor to the thirteenth P-type transistor, and the ground line is disposed on a side of the first N-type transistor away from the first P-type transistor; and there is a voltage line distance between an edge of the second power supply line on a side close to the ground line and an edge of the ground line on a side close to the second power supply line, and the voltage line distance is greater than or equal to 5 μm.

In an exemplary implementation, the row driving enhancer includes a plurality of transistor groups disposed sequentially along a first direction, at least one transistor group includes a P-type transistor and an N-type transistor disposed on a side of the P-type transistor in a second direction, and the first direction intersects with the second direction; a plurality of transistor groups form a first NAND gate, a first transmission gate, a second NAND gate, a second inverter, and an output unit disposed sequentially along a direction close to the display region, wherein there is a first distance between a transistor group in the second inverter and a transistor group in the output unit, there is a second distance between two adjacent transistor groups in the first NAND gate, the first transmission gate, the second NAND gate and the second inverter, the first distance is larger than the second distance, and both the first distance and the second distance are dimensions in the first direction.

In an exemplary implementation, there is a first distance between the P-type transistor in the second inverter and the P-type transistor in the output unit, and there is a second distance between two adjacent P-type transistors in the first NAND gate, the first transmission gate, the second NAND gate, and the second inverter; and/or there is a first distance between the N-type transistor in the second inverter and the N-type transistor in the output unit, and there is a second distance between two adjacent N-type transistors in the first NAND gate, the first transmission gate, the second NAND gate, and the second inverter.

In an exemplary implementation, a ratio of the first distance to the second distance is 0.7 to 0.8.

In an exemplary implementation, the first distance is greater than or equal to 0.5 μm and the second distance is greater than or equal to 0.36 μm.

In an exemplary implementation, the at least one P-type transistor includes a P-type active region, and the at least one N-type transistor includes an N-type active region; there is a first distance between a P-type active region in the second inverter and a P-type active region in the output unit, and there is a second distance between two adjacent P-type active regions in the first NAND gate, the first transmission gate, the second NAND gate, and the second inverter; and/or there is a first distance between an N-type active region in the second inverter and an N-type active region in the output unit, and there is a second distance between two adjacent N-type active regions in the first NAND gate, the first transmission gate, the second NAND gate, and the second inverter.

In an exemplary implementation, the gate driving circuit further includes a shift register circuit and a logic operation circuit disposed on the silicon base substrate, wherein the shift register circuit is configured to generate timings of row-by-row shifts according to timing signals, and the logic operation circuit is configured to generate target timings through a logic operation.

In another aspect, an embodiment of the present disclosure provides a display substrate including a display region and a non-display region; the display region includes a plurality of sub-pixels, and at least one sub-pixel includes a pixel driving circuit and at least one scanning signal line, which is configured to provide a scanning signal to the connected pixel driving circuit; and the non-display region includes a plurality of gate driving circuits which are cascaded, at least one gate driving circuit is connected to a scanning signal line in the display region, and at least one gate driving circuit includes the aforementioned gate driving circuit.

In yet another aspect, an example of the present disclosure provides a display apparatus, which includes the aforementioned display substrate.

Other aspects may become clear after the drawings and the detailed description are read and understood.

### BRIEF DESCRIPTION OF DRAWINGS

The drawings are used for providing understanding of technical solutions of the present disclosure, constitute a part of the specification, and together with the embodiments of the present disclosure, are used for explaining the technical solutions of the present disclosure, but do not form limitations on the technical solutions of the present disclosure. Shapes and sizes of each component in the drawings do not reflect actual scales, but are only intended to schematically illustrate contents of the present disclosure.

FIG. 1 is a schematic diagram of a structure of a silicon-based OLED display apparatus.

FIG. 2 is a schematic diagram of a planar structure of a display region in a display apparatus of a silicon-based OLED.

FIG. 3 is a schematic diagram of a sectional structure of a display region in a silicon-based OLED display apparatus.

FIG. 4 is an equivalent circuit diagram of a pixel driving circuit.

FIG. 5 is a drive timing diagram of the pixel driving circuit shown in FIG. 4.

FIG. 6 is a schematic diagram of a structure of a gate driving circuit according to an exemplary embodiment of the present disclosure.

FIG. 7 is a working principle diagram of a level converter according to an exemplary embodiment of the present disclosure.

FIG. 8 is a working principle diagram of a row driving enhancer according to an exemplary embodiment of the present disclosure.

FIG. 9 is an equivalent circuit diagram of a level converter according to an exemplary embodiment of the present disclosure.

FIG. 10 is an equivalent circuit diagram of a row driving enhancer according to an exemplary embodiment of the present disclosure.

FIG. 11 is an equivalent circuit diagram of an output circuit according to an exemplary embodiment of the present disclosure.

FIG. 12 is a schematic diagram of a structure of an output circuit according to an exemplary embodiment of the present disclosure.

FIGS. 13A and 13B are schematic diagrams after patterns of a deep N-well, an N-well region, and an active region are formed according to an embodiment of the present disclosure.

FIGS. 14A and 14B are schematic diagrams after a pattern of a gate conductive layer is formed according to an embodiment of the present disclosure.

FIGS. 15A and 15B are schematic diagrams after a pattern of a P-type doped region is formed according to an embodiment of the present disclosure.

FIGS. 16A and 16B are schematic diagrams after a pattern of an N-type doped region is formed according to an embodiment of the present disclosure.

FIG. 17 is a schematic diagram after a pattern of a second insulation layer is formed according to an embodiment of the present disclosure.

FIGS. 18A and 18B are schematic diagrams after a pattern of a first conductive layer is formed according to an embodiment of the present disclosure.

FIG. 19 is a schematic diagram after a pattern of a third insulation layer is formed according to an embodiment of the present disclosure.

FIGS. 20A and 20B are schematic diagrams after a pattern of a second conductive layer is formed according to an embodiment of the present disclosure.

FIG. 21 is an equivalent circuit diagram of another level converter according to an exemplary embodiment of the present disclosure.

Reference signs are described as follows.

| | | |
|---|---|---|
| 10-Deep N-well region; | 20-N well region; | 31-First P-type doped region; |
| 32-Second P-type doped | 33-Third P-type doped | 34-Fourth P-type doped |
| region; | region; | region; |
| 41-First N-type doped | 42-Second N-type doped | 43-Third N-type doped |
| region; | region; | region; |
| 44-Fourth N-type doped | 51-First power supply | 52-Second power supply |
| region; | line | line |
| 53-Ground line | 100-Shift register circuit | 101-Silicon base |
| | | substrate; |
| 102-Driving circuit | 103-Light emitting | 104-First encapsulation |
| layer; | structure layer; | layer; |
| 105-Color filter structure | 106-Second | 107-Cover plate layer; |
| layer; | encapsulation layer; | |
| 200-Logic operation | 201-First transmission | 300-Output circuit |
| circuit | gate | |
| 301-First NAND gate; | 302-Second NAND gate; | 401-First inverter; |
| 402-Second inverter; | 500-Selection output | 501P-First P-type |
| | unit; | transistor unit; |
| 501N-First N-type | 502P-Second P-type | 502N-Second N-type |
| transistor unit; | transistor unit; | transistor unit; |
| 503P-Third P-type | 503N-Third N-type | |
| transistor unit; | transistor unit. | |

### DETAILED DESCRIPTION

To make objectives, technical solutions, and advantages of the present disclosure clearer, the embodiments of the present disclosure will be described in detail below with reference to the accompany drawings. It is to be noted that implementation modes may be implemented in a plurality of different forms. Those of ordinary skills in the art may easily understand such a fact that modes and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict. In order to keep following description of the embodiments of the present disclosure clear and concise, detailed description of part of known functions and known components are omitted in the present disclosure. The drawings in the embodiments of the present disclosure relate only to the structures involved in the embodiments of the present disclosure, and other structures may be described with reference to conventional designs.

Scales of the drawings in the present disclosure may be used as a reference in actual processes, but are not limited thereto. For example, a width-length ratio of a channel, a thickness and spacing of various film layers, and a width and spacing of various signal lines may be adjusted according to actual needs. A quantity of pixels in a display apparatus and a quantity of sub-pixels in each pixel are not limited to the quantity shown in the drawings. The drawings described in the present disclosure are schematic structural diagrams only, and a implementation of the present disclosure is not limited to the shapes or numerical values, or the like shown in the drawings.

Ordinal numerals “first”, “second”, “third”, etc., in the specification are set not to form limits in numbers but only to avoid confusion between composition elements.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements with reference to the accompanying drawings, not to indicate or imply that involved devices or elements are required to have specific orientations and be structured and operated with the specific orientations but only to easily and simply describe the present specification, and thus should not be understood as limitations on the present disclosure. The positional relationships between the constituent elements may be changed as appropriate according to a direction according to which each constituent element is described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, a connection may be a fixed connection, or a detachable connection, or an integral connection; it may be a mechanical connection or an electrical connection; it may be a direct connection, or an indirect connection through middleware, or internal communication inside two elements. Those of ordinary skills in the art may understand specific meanings of the above terms in the present disclosure according to specific situations.

In the specification, a transistor refers to an element that at least includes three ends, i.e., a gate electrode, a drain electrode, and a source electrode. The transistor has a channel region between the drain electrode (drain electrode end, drain region, or drain) and the source electrode (source electrode end, source region, or source), and a current can flow through the drain electrode, the channel region, and the source electrode. It is to be noted that in the specification, the channel region refers to a region through which a current mainly flows.

In the specification, sequentially to distinguish two electrodes of the transistor except the gate electrode, one of the two electrodes is directly referred to as a first electrode and the other is referred to as a second electrode. The first electrode may be a drain electrode and the second electrode may be a source electrode, or the first electrode may be a source electrode and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode” are interchangeable in the specification.

In the specification, an “electrical connection” includes a case that constituent elements are connected together through an element with a certain electrical action. An “element with a certain electrical action” is not particularly limited as long as electrical signals between the connected constituent elements may be sent and received. Examples of the “element with a certain electrical action” not only include an electrode and a wiring, but also include a switching element such as a transistor, a resistor, an inductor, a capacitor, other elements with various functions, etc.

In the specification, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 85° and below 95°.

In the specification, a “film” and a “layer” are interchangeable. For example, a “conductive layer” may be replaced with a “conductive film” sometimes. Similarly, an “insulation film” may be replaced with an “insulation layer” sometimes.

In the specification, “arranged in a same layer” described refers to a structure formed by patterning two (or more than two) structures through a same patterning process, and their materials may be the same or different. For example, materials of precursors for forming a plurality of structures arranged in a same layer are the same, and final materials may be the same or different.

A triangle, rectangle, trapezoid, pentagon, or hexagon, etc. in the specification is not strictly defined, and it may be an approximate triangle, rectangle, trapezoid, pentagon, or hexagon, etc. There may be some small deformations caused by tolerance, and there may be a chamfer, an arc edge, deformation, etc.

In the present disclosure, “about” refers to that a boundary is not defined so strictly and numerical values within a range of process and measurement errors are allowed.

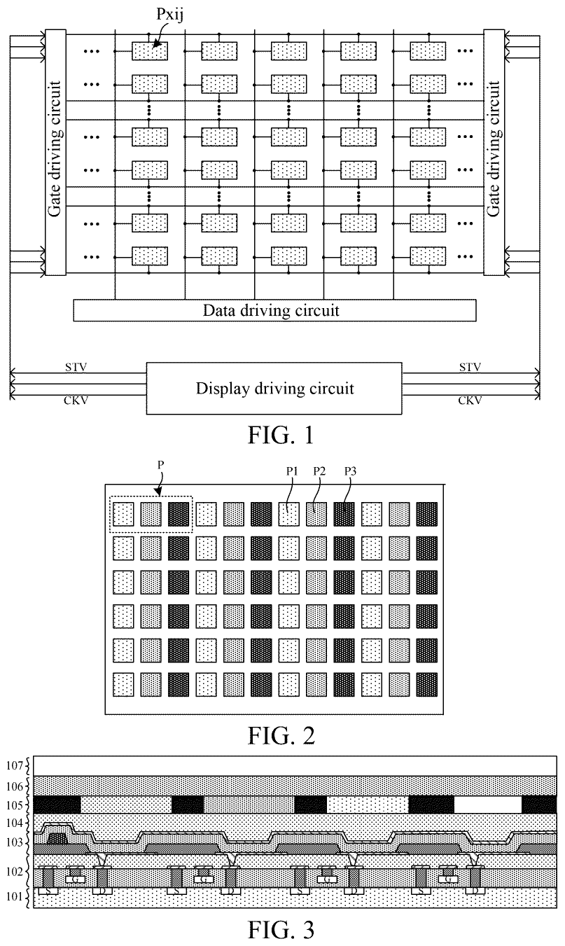

FIG. 1 is a schematic diagram of a structure of a silicon-based OLED display apparatus. As illustrated in FIG. 1, the silicon-based OLED display apparatus may include a display region and a non-display region. The display region may include a plurality of scanning signal lines, a plurality of data signal lines and a plurality of sub-pixels Pxij forming a plurality of pixel rows and a plurality of pixel columns, wherein the plurality of scanning signal lines are disposed in the plurality of pixel rows, respectively, and the plurality of data signal lines are disposed in the plurality of pixel columns, respectively. Each sub-pixel Pxij may at least include a pixel driving circuit and a light emitting device, and the pixel driving circuit is configured to supply a current required for emitting light to the connected light emitting device. The pixel driving circuit of each sub-pixel Pxij may be connected to a scanning signal line of a corresponding pixel row and a data signal line of a corresponding pixel column, the sub-pixel Pxij may be referred to a sub-pixel of an i-th pixel row and a j-th pixel column, and the pixel driving circuit of the sub-pixel Pxij is connected to the i-th scanning signal line and the j-th data signal line, respectively, wherein i and j may be natural numbers. The non-display region may include a Display Drive Circuit (such as a Display Driver Integrated Circuit, DDIC for short), a Gate Driver (GD for short), and a Data Driver (such as a Source Driver, SD for short), wherein the Display Drive Circuit may at least include a Timer Controller (TCON for short), which is configured to generate timing signals required by the Gate Driver, such as a starting signal (STV) and a clock signal (CKV), and transmit the timing signals to the Gate Driver. The Gate Driver is respectively connected to a plurality of scanning signal lines in the display region, and the Gate Driver is configured to provide required timing signals to the connected pixel driving circuit to achieve a row-by-row scanning function. The Data Driver is respectively connected to a plurality of data signal lines in the display region, and the Data Driver is configured to provide required data signals (data) to the connected pixel driving circuit to achieve switching and control of the display picture.

In an exemplary implementation, the silicon-based OLED display apparatus may be a single chip display architecture (One Chip) in which a Gate Driver, a Data Driver, a clock control unit, an image processing unit, a storage unit, and the like are integrated on the same chip. The chip with the One Chip architecture includes digital and analog parts, and is a mixed-signal chip.

In another exemplary implementation, the silicon-based OLED display apparatus may be a two-chip display architecture (Two Chip) in which a Gate Driver and a Data Driver are integrated in a display substrate, and a clock control unit, an image processing unit, a mobile industry processor interface (MIPI), and a storage unit are integrated in a chip, the chip is bonded to the display substrate through a COC process.

FIG. 2 is a schematic diagram of a planar structure of a display region in a display apparatus of a silicon-based OLED. As shown in FIG. 2, on a plane parallel to the display substrate, the first display region may include a plurality of pixel units P arranged in a matrix. At least one pixel unit P may include a first sub-pixel P1 emitting light of a first color, a second sub-pixel P2 emitting light of a second color, and a third sub-pixel P3 emitting light of a third color. The three sub-pixels may each include a pixel driving circuit and a light emitting device, wherein the pixel driving circuit in each of the sub-pixels is respectively connected to a scanning signal line, and a data signal line, and the pixel driving circuit is configured to receive a data voltage transmitted by the data signal line and output a corresponding current to the light emitting device of the display under the control of the scanning signal line. The light emitting device in the sub-pixel is connected to a pixel driving circuit of a sub-pixel where the light emitting device is located, and is configured to emit light with a corresponding brightness in response to a current output by the pixel driving circuit of the sub-pixel where the light emitting device is located.

In an exemplary implementation, the first sub-pixel P1 may be a red (R) sub-pixel emitting red light, the second sub-pixel P2 may be a blue (B) sub-pixel emitting blue light, and the third sub-pixel P3 may be a green (G) sub-pixel emitting green light.

In an exemplary implementation, the sub-pixels may be in a shape of any one or more of a triangle, a square, a rectangle, a rhombus, a trapezoid, a parallelogram, a pentagon, a hexagon and other polygons. The three sub-pixels may be arranged side by side horizontally, side by side vertically or in a shape of delta, which is not limited here in the present disclosure. In some other possible implementations, the pixel unit may include four sub-pixels, and the present disclosure is not limited thereto.

FIG. 3 is a schematic diagram of a sectional structure of a display region in a silicon-based OLED display apparatus, which illustrates a structure in which full color is implemented in a manner of white light+color filter. As shown in FIG. 3, in a direction perpendicular to the display apparatus, the silicon-based OLED display apparatus may include a silicon base substrate 101, a driving circuit layer 102 disposed on the silicon base substrate 101, a light emitting structure layer 103 disposed on one side of the driving circuit layer 102 away from the silicon base substrate 101, a first encapsulation layer 104 disposed on one side of the light emitting structure layer 103 away from the silicon base substrate 101, a color filter structure layer 105 disposed on one side of the first encapsulation layer 104 away from the silicon base substrate 101, a second encapsulation layer 106 disposed on one side of the color filter structure layer 105 away from the silicon base substrate 101, and a cover plate layer 107 disposed on one side of the second encapsulation layer 106 away from the silicon base substrate 101. In some possible implementations, the silicon-based OLED display apparatus may include other film layers, and the present disclosure is not limited thereto.

In an exemplary implementation, the silicon base substrate 101 may be a bulk silicon base substrate or a Silicon-On-Insulator (SOI) substrate. The driving circuit layer 102 may be fabricated on the silicon base 101 through a silicon semiconductor process. The driving circuit layer 102 may include a plurality of circuit units, a circuit unit may at least include a pixel driving circuit connected to a scanning signal line and a data signal line, respectively. The pixel driving circuit may include a plurality of transistor and a storage capacitor. One transistor is shown only in FIG. 3 as an example. A transistor may include a gate electrode G, a source electrode S and a drain electrode D. The gate electrode G, and the source electrode S and the drain electrode D may be connected respectively to corresponding connection electrodes through via holes filled with tungsten metal (i.e., tungsten via, W-via), and may be connected to other electrical structures (e.g., wires) through the connection electrodes.

In an exemplary implementation, the light emitting structure layer 103 may include a plurality of light emitting devices, and a light emitting device may at least include an anode, an organic light emitting layer and a cathode. The anode may be connected to the drain electrode D of the transistor through a connection electrode, the organic light emitting layer is connected to the anode, the cathode is connected to the organic light emitting layer, and the cathode is connected to a second power supply line. The organic light emitting layer emits light under the driving of the anode and the cathode. In an exemplary implementation, the organic light emitting layer may include an Emitting Layer (EML) and any one or more of a Hole Injection Layer (HIL), a Hole Transport Layer (HTL), an Electron Block Layer (EBL), a Hole Block Layer (HBL), an Electron Transport Layer (ETL), and an Electron Injection Layer (EIL). In an exemplary implementation, for a light emitting device emitting white light, organic light emitting layers of all sub-pixels may be connected together to form a common layer.

In an exemplary implementation, the first encapsulation layer 104 and the second encapsulation layer 106 may be in a Thin Film Encapsulation (TFE) mode, which may ensure that external water vapor cannot enter the light emitting structure layer. The color filter structure layer 105 may at least include a red filter unit, a blue filter unit and a green filter unit, wherein the red filter unit is disposed at the red sub-pixels to filter white light emitted from the light emitting device into red light, the blue filter unit is disposed at the blue sub-pixels to filter white light emitted from the light emitting device into blue light, and the green filter unit is disposed at the green sub-pixels to filter white light emitted from the light emitting device into green light. The cover plate layer 107 may be made of glass, or plastic colorless polyimide or the like with flexible properties.

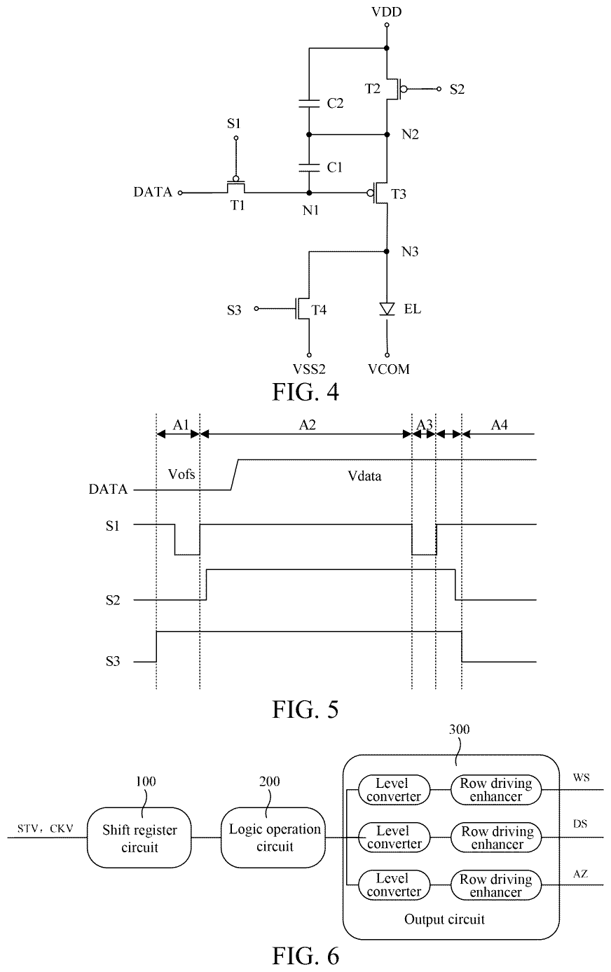

FIG. 4 is an equivalent circuit diagram of a pixel driving circuit. As shown in FIG. 4, the pixel driving circuit has a 4T2C structure, may include four transistors (a first transistor T1, a second transistor T2, a third transistor T3, and a fourth transistor T4) and two storage capacitors (a first capacitor C1 and a second capacitor C2), and is connected to six signal lines (a first scanning signal line S1, a second scanning signal line S2, a third scanning signal line S3, a data signal line DATA, a first power supply line VDD, and a second power supply line VSS).

In an exemplary implementation, the pixel driving circuit may include a first node N1, a second node N2, and a third node N3. The first node N1 is respectively connected to a second electrode of the first transistor T1, a gate electrode of the third transistor T3 and a first end of the first capacitor C1. The second node N2 is connected to a second electrode of the second transistor T2, a first electrode of the third transistor T3, a second end of the first capacitor C1, and a first end of the second capacitor C2, respectively. The third node N3 is connected to a second electrode of the third transistor T3, and a second electrode of the fourth transistor T4, respectively.

In an exemplary implementation, the first transistor T1 may be referred to as a Write Switch transistor, wherein a gate electrode of the first transistor T1 is connected to the first scanning signal line S1, a first electrode of the first transistor T1 is connected to the data signal line DATA, and a second electrode of the first transistor T1 is connected to the first node N1.

In an exemplary implementation, the second transistor T2 may be referred to as a Display Switch transistor, wherein a gate electrode of the second transistor T2 is connected to the second scanning signal line S2, a first electrode of the second transistor T2 is connected to the first power supply line VDD, and a second electrode of the second transistor T2 is connected to the second node N2.

In an exemplary implementation, the third transistor T3 may be referred to as a Driver transistor, the gate electrode of the third transistor T3 is connected with the first node N1, the first electrode of the third transistor T3 is connected with the second node N2, and the second electrode of the third transistor T3 is connected with the third node N3.

In an exemplary implementation, the fourth transistor T4 may be referred to as an Auto Zero transistor, wherein a gate electrode of the fourth transistor T4 is connected to the third scanning signal line S3, a first electrode of the fourth transistor T4 is connected to the second power supply line VSS, and a second electrode of the fourth transistor T4 is connected to the third node N3.

In an exemplary implementation, a first end of the first capacitor C1 is connected to the first node N1, and a second end of the first capacitor C1 is connected to the first node N2. A first end of the second capacitor C2 is connected to the second node N2, and a second end of the second capacitor C2 is connected with the first power supply line VDD.

In an exemplary implementation, the light emitting device XL may be an Organic Light Emitting Diode (OLED) including a first electrode (anode), an organic emitting layer, and a second electrode (cathode) that are stacked. A first electrode of the light emitting device XL is connected to the third node N3, and a second electrode of the light emitting device XL is connected to a common voltage line VCOM.

In an exemplary implementation, the signal of the first power supply line VDD may be a continuously provided high-level signal, and the signals of the second power supply line VSS and the common voltage line VCOM may be continuously provided low-level signals.

In an exemplary implementation, the first transistor T1 to the fourth transistor T4 may be P-type transistors (PMOS), or may be N-type transistors (NMOS). For example, the first transistor T1 to the fourth transistor T4 are all P-type transistors. Using the same type of transistor in the pixel driving circuit may simplify the process flow, reduce the process difficulty of the display substrate, and improve the yield of a product.

In an exemplary implementation, the first transistor T1 to the fourth transistor T4 may include P-type transistors and N-type transistors. For example, as shown in FIG. 4, the first transistor T1 to the third transistor T3 may be P-type transistors, and the fourth transistor T4 may be an N-type transistor.

FIG. 5 is a drive timing diagram of the pixel driving circuit shown in FIG. 4. As shown in FIG. 5, in an exemplary implementation, an operating process of the pixel driving circuit may include following stages A1 to A6.

The first stage A1 may be referred to as an initialization stage. The signals of the first scanning signal line S1 and the second scanning signal line S2 are low-level signals, and the signal of the third scanning signal line S3 is a high-level signal, such that the first transistor T1, the second transistor T2, and the fourth transistor T4 are turned on. The first transistor T1 is turned on, such that a bias voltage Vofs output by the DATA signal line DATA is written into the first capacitor C1, and a potential Vs of the first node N1 (i.e. the gate electrode of the third transistor T3) is equal to Vofs. The second transistor T2 is turned on, such that the first power supply voltage ELVDD output by the first power supply line VDD is written into the second node N2, and a potential Vg of the second node N2 (i.e. the first electrode of the third transistor T3) is equal to ELVDD. At this time, a gate-source voltage Vgs of the third transistor T3 is equal to ELVDD-Vofs, a storage voltage Vcs of the first capacitance C1 is equal to ELVDD-Vofs, and a potential Vd of the third node N3 (i.e. the second electrode of the third transistor T3) is equal to Vg+Vth, which is ready for discharging in the next stage. Herein, ELVDD-Vofs>Vth, and Vth is a threshold voltage of the third transistor T3.

The second stage A2 may be referred to as a self-discharge stage. The signal of the third scanning signal line S3 is a high-level signal, and the fourth transistor T4 is continuously turned on. The signal of the first scanning signal line S13 changes from a low-level signal to a high-level signal, such that the first transistor T1 is turned off first, and the first node N1 is floating. Subsequently, the signal of the second scanning signal line S2 changes from a low-level signal to a high-level signal, such that the second transistor T2 is turned off, the second node N2 forms a loop through the turned-on third transistor T3, the third node N3 and the turned-on fourth transistor T4 and starts discharging, and the potential of the second node N2 decreases. Since the first node N1 is floating, a voltage difference across the first capacitor C1 does not change, and thus the potential of the first node N1 decreases as the potential of the second node N2 decreases. The gate-source voltage Vgs of the third transistor T3 remains constant due to a back-gate effect of the third transistor T3, so that an equivalent threshold voltage |V_{th_EF}| of the third transistor T3 gradually increases as the potential of the second node N2 decreases, and the equivalent threshold voltage |V_{th_EF}| of the third transistor T3 is equal to α (ELVDD−Vs)+|Vth|, wherein α is a back-gate coefficient. When the equivalent threshold voltage |V_{th_EF}| of the third transistor T3 increases to the gate-source voltage Vgs of the third transistor T3, the third transistor T3 is turned off, and the second node N2 stops discharging.

The third stage A3 may be referred to as a data writing stage and a threshold compensation stage. The signal of the second scanning signal line S2 is a high-level signal, such that the second transistor T2 is continuously turned off. The signal of the third scanning signal line S3 is a high-level signal, and the fourth transistor T4 is continuously turned on. The signal of the first scanning signal line S13 changes from a high-level signal to a low-level signal, such that the first transistor T1 is turned on. When the first transistor T1 is turned on, the data voltage Vdata output from the data signal line DATA is written to the first node N1, and the potential of the first node N1 changes from Vofs to Vdata. Since the second node N2 is floating, threshold compensation may be achieved in this stage.

The fourth stage A4 may be referred to as a light emitting stage. The signals of the second scanning signal line S2 and the third scanning signal line S3 are low-level signals, and the signal of the first scanning signal line S1 is a high-level signal, such that the second transistor T2 is turned on, and the first transistor T1 and the fourth transistor T4 are turned off. The second transistor T2 is turned on, such that a power supply voltage output from the first power supply line VDD provides a driving voltage to a first electrode of the light emitting device EL through the turned-on second transistor T2 and the third transistor T3 to drive the light emitting device EL to emit light.

In the light emitting stage, the driving current of the third transistor T3 is not affected by the threshold voltage of the third transistor T3, the influence of the threshold voltage of the third transistor T3 on the driving current is eliminated, the display brightness of the display product is ensured to be uniform, and the display effect of the entire display product is improved.

An exemplary embodiment of the present disclosure provides a display substrate including a display region and a non-display region; the display region includes a plurality of sub-pixels forming a plurality of pixel rows and a plurality of pixel columns, at least one sub-pixel includes a pixel driving circuit, and at least one scanning signal line, the scanning signal line is configured to provide a scanning signal to the pixel driving circuit; the non-display region includes a plurality of cascaded gate driving circuits, at least one gate driving circuit is connected to a scanning signal line in a pixel row in the display region; at least one gate driving circuit includes a shift register circuit, a logic operation circuit and an output circuit arranged sequentially along a direction close to the display region, wherein the shift register circuit is configured to generate timings of row-by-row shifts according to timing signals, the logic operation circuit is configured to generate target timings through a logic operation, and the output circuit is configured to perform voltage domain conversions and signal enhancements; the output circuit includes at least one level converter and at least one row driving enhancer, wherein the level converter is configured to perform voltage domain conversions on the target timings, and the row driving enhancer is configured to output the converted signals to a scanning signal line of the display region after enhancing the converted signals, at least one input signal of the row driving enhancer is provided by the level converter, the row driving enhancer is disposed on a side of the level converter close to the display region.

In an exemplary implementation, the level converter includes at least a first inverter, a first level conversion unit, and a second level conversion unit; an input end of the first level conversion unit is connected to an input end of the first inverter, and an output end of the first level conversion unit is connected to the row driving enhancer; an input end of the second level conversion unit is connected to an output end of the first inverter, and an output end of the second level conversion unit is connected to the row driving enhancer; and the first level conversion unit is disposed on a side of the first inverter close to the display region, and the second level conversion unit is disposed on a side of the first level conversion unit close to the display region.

In an exemplary implementation, the level converter further includes a selection output unit, which is connected to the output end of the first level conversion unit and the output end of the second level conversion unit, respectively, and the selection output unit is configured to selectively output an output signal of the first level conversion unit or an output signal of the second level conversion unit under the control of a selection input signal.

In an exemplary implementation, the first inverter includes a first P-type transistor and a first N-type transistor disposed on a side of the first P-type transistor in a second direction; the first level conversion unit includes a first P-type transistor unit disposed on a side of the first P-type transistor unit in a first direction and a first N-type transistor unit disposed on a side of the first P-type transistor unit in the second direction, the second level conversion unit includes a second P-type transistor unit disposed on a side of the first P-type transistor unit in the first direction and a second N-type transistor unit disposed on a side of the second P-type transistor unit in the second direction, and the first direction intersects with the second direction; the first P-type transistor unit includes a second P-type transistor to a seventh P-type transistor disposed on a side of the first P-type transistor in the first direction and disposed sequentially along the first direction; the second P-type transistor unit includes an eighth P-type transistor to a thirteenth P-type transistor disposed on a side of the seventh P-type transistor in the first direction and disposed sequentially along the first direction; and the first N-type transistor unit includes a second N-type transistor disposed on a side of the seventh P-type transistor in the second direction, and the second N-type transistor unit includes a third N-type transistor disposed on a side of the eighth P-type transistor in the second direction.

In an exemplary implementation, the row driving enhancer includes a plurality of transistor groups disposed sequentially along a first direction, at least one transistor group includes a P-type transistor and an N-type transistor disposed on a side of the P-type transistor in a second direction, and the first direction intersects with the second direction; a plurality of transistor groups form a first NAND gate, a first transmission gate, a second NAND gate, a second inverter, and an output unit disposed sequentially along a direction close to the display region, wherein there is a first distance between a transistor group in the second inverter and a transistor group in the output unit, there is a second distance between two adjacent transistor groups in the first NAND gate, the first transmission gate, the second NAND gate and the second inverter, the first distance is larger than the second distance, and both the first distance and the second distance are dimensions in the first direction.

The technical schemes of the display substrate in accordance with the present disclosure will be described below through exemplary embodiments.

FIG. 6 is a schematic diagram of a structure of a gate driving circuit according to an exemplary embodiment of the present disclosure. In an exemplary implementation, the Gate Drivers may be disposed in the non-display region, may be located on a side of the display region in the pixel row direction, or may be located on both sides of the display region in the pixel row direction, respectively. The Gate Drivers may each include a plurality of cascaded gate driving circuits, at least one gate driving circuit is connected to a scanning signal line in a pixel row in the display region and provides a scanning signal to the connected scanning signal line. When the Gate Drivers are arranged on both sides of the display region in the pixel row direction, the scanning signal lines in the pixel row are driven by two gate driving circuits to form a bilateral driving structure, which may ensure a driving ability of high pixel density and avoid a distortion of the driving signal. As shown in FIG. 6, the gate driving circuit may include a shift register circuit 100, a logical operation circuit (such as a Logical Transition Unit) 200, and an output circuit 300.

In an exemplary implementation, the shift register circuit 100 may be a shift register circuit including a trigger (such as a D Flip Flop), the shift register circuit 100 is connected to the display driving circuit and receives a timing signal generated by the display driving circuit, and the timing signal may include a starting signal STV and a clock signal CKV. The shift register circuit 100 is configured to shift and register the received timing signal to initially generate a timing that may be shifted row by row. The logic operation circuit 200 is connected to the shift register circuit 100, and is configured to perform a logic operation on the shifted signal to generate a plurality of target timings of different waveforms. The output circuit 300 is connected to the logic operation circuit 200, and is configured to perform voltage domain conversions on the target timings, and output scanning signals to the display region after enhancing the converted signals.

In an exemplary implementation, when the pixel driving circuit in the display region includes the first scanning signal line S1, the second scanning signal line S2, and the third scanning signal line S3, the output circuit 300 may include three output sub-circuits, one of which is connected to the first scanning signal line S1 in one pixel row in the display region and is configured to output the first scanning signal to the display region, another of which is connected to the second scanning signal line S2 in one pixel row in the display region and is configured to output the second scanning signal to the display region, and yet another of which is connected to the third scanning signal line S3 in one pixel row in the display region and is configured to output the third scanning signal to the display region.

In an exemplary implementation, the first scanning signal may be referred to as a Write Switch (WS for short) signal, and is configured to control the first transistor T1 in the pixel driving circuit to be turned on and off. The second scanning signal may be referred to as a Display Switch (DS for short) signal, and is configured to control the second transistor T2 in the pixel driving circuit to be turned on and off. The third scanning signal may be referred to as an Auto Zero (AZ for short) signal, and is configured to control the fourth transistor T4 in the pixel driving circuit to be turned on and off.

In an exemplary implementation, each output sub-circuit may include a lever converter (such as a Level shifter) and a row driving enhancer (such as a Line Driver). The level converter is connected to the logic operation circuit 200, and is configured to perform voltage domain conversions on the target timings. The row driving enhancer is connected to the level converter and is configured to enhance the converted signal, enhance the output capability, and output the scanning signal to the display region.

In the exemplary embodiment, since the signals such as the starting signal and the clock signal are output by the display driving circuit, the voltage domain thereof is inconsistent with the voltage domain of the pixel driving circuit, and the required voltage (0V to −2V & −5 V) is introduced through the conversion of the level converter, so that the voltage of the output gate driving signal may be guaranteed to match the voltage of the pixel driving circuit.

In an exemplary implementation, the starting signal STV may be referred to as a frame starting signal with a period of one frame. The clock signal CKV may be referred to as a row driving clock signal with a period of one row.

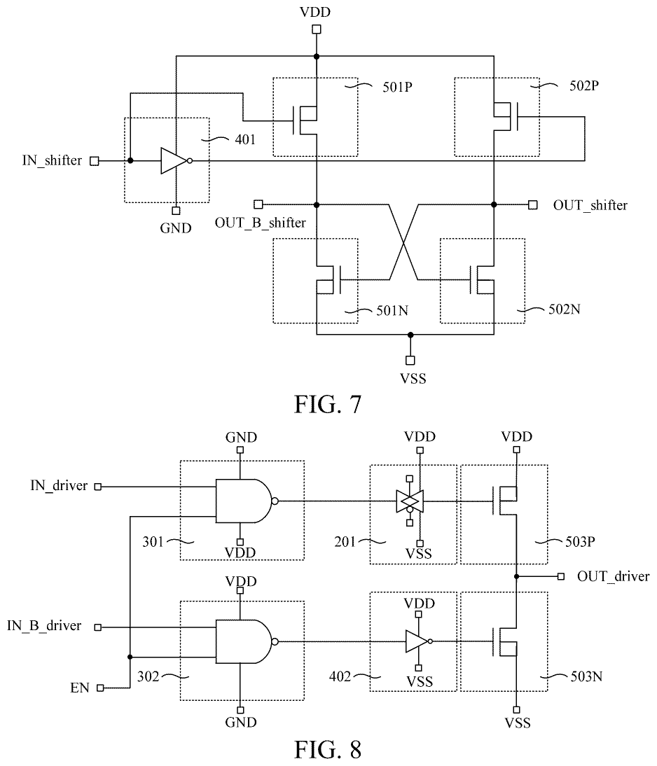

FIG. 7 is a working principle diagram of a level converter according to an exemplary embodiment of the present disclosure. As illustrated in FIG. 7, the level converter may include a first inverter 401, a first P-type transistor unit 501P, a second P-type transistor unit 502P, a first N-type transistor unit 501N, and a second N-type transistor unit 502N.

In an exemplary implementation, an input end IN_shifter of the level converter is respectively connected to an input end of the first inverter 401 and a gate electrode of the first P-type transistor unit 501P, and an output end of the first inverter 401 is connected to an gate electrode of the second P-type transistor unit 502P. A first electrode of the first P-type transistor unit 501P and a first electrode of the second P-type transistor unit 502P are both connected to the first power supply line VDD, and a second electrode of the first P-type transistor unit 501P is respectively connected to a second electrode of the first N-type transistor unit 501N, a gate electrode of the second N-type transistor unit 502P, and a second output end OUT_B_shifter of the level converter. A second electrode of the second P-type transistor unit 502P is respectively connected to a gate electrode of the first N-type transistor unit 501N, a second electrode of the second N-type transistor unit 502N and a first output end OUT_shifter of the level converter, and a first electrode of the first N-type transistor unit 501N and a first electrode of the second N-type transistor unit 502N are both connected to the second power supply line VSS.

In an exemplary implementation, an operation principle of the level converter is that when an input signal of the input end IN_shifter of the level converter is at a low level, the first P-type transistor unit 501P is turned on, the second P-type transistor unit 502P is turned off, an output signal of the second output end OUT_B_shifter of the level converter is a signal of the first power supply line VDD, the first N-type transistor unit 501N is turned off, the second N-type transistor unit 502N is turned on, and an output signal of the first output end OUT_shifter of the level converter is a signal of the second power supply line VSS. When an input signal of the input end IN_shifter of the level converter is at a high level, the first P-type transistor unit 501P is turned off, the second P-type transistor unit 502P is turned on, an output signal of the first output end OUT_shifter of the level converter is a signal of the first power supply line VDD, the first N-type transistor unit 501N is turned on, the second N-type transistor unit 502N is turned off, and an output signal of the second output end OUT_B_shifter of the level converter is a signal of the second power supply line VSS.

FIG. 8 is a working principle diagram of a row driving enhancer according to an exemplary embodiment of the present disclosure. As illustrated in FIG. 8, the row driving enhancer may include a first NAND gate 301, a second NAND gate 302, a first transmission gate 201, a second inverter 402, a third P-type transistor unit 503P, and a third N-type transistor unit 503N. The third P-type transistor unit 503P and the third N-type transistor unit 503N have a relatively large aspect ratio to achieve improvement in driving capability.

In an exemplary implementation, an first input end IN_driver and an enabling signal end EN of the row driving enhancer are connected to an input end of the first NAND gate 301, an output end of the first NAND gate 301 is connected to an input end of the first transmission gate 201, an output end of the first transmission gate 201 is connected to a gate electrode of the third P-type transistor unit 503P, and a first electrode of the third P-type transistor unit 503P is connected to the first power supply line VDD. A second input end IN_B_driver of the row driving enhancer and the enabling signal end EN are connected to an input end of the second NAND gate 302, an output end of the second NAND gate 302 is connected to an input end of the second inverter 402, an output end of the second inverter 402 is connected to a gate electrode of the third N-type transistor unit 503N, and a first electrode of the third N-type transistor unit 503N is connected to the second power supply line VSS. A second electrode of the third P-type transistor unit 503P and a second electrode of the third N-type transistor unit 503N are connected to an output end OUT_driver of the row driving enhancer. High-level active enabling ends of the first transmission gate 201 and the second inverter 402 are connected to the first power supply line VDD, and low-level active enable ends are connected to the second power supply line VSS. High-level active enabling ends of the first NAND gate 301 and the second NAND gate 302 are connected to the first power supply line VDD, and low-level active enabling ends are connected to the ground line GND.

In an exemplary implementation, a working principle of the row driving enhancer is as follows.

When the enabling signal of the enabling signal end EN is 0, the first NAND gate 301 and the second NAND gate 302 output 1 (at a high level). An output of the first NAND gate 301 passes through the first transmission gate 201 and outputs 1 (at a high level), the third P-type transistor unit 503 P is turned off, an output of the second NAND gate 302 outputs 0 (at a low level) after passing through the second inverter 402, the third N-type transistor unit 503 N is turned off, and the entire circuit state is in a high resistance state.

When the enabling signal of the enabling signal end EN is 1, the circuit output is determined by input signals of a first input end IN_driver of the row driving enhancer and a second input end IN_B_driver of the row driving enhancer, and the input signal of the first input end IN_driver of the row driving enhancer and the input signal of the second input end IN_B_driver of the row driving enhancer are mutually directional signals.

When the input signal of the first input end IN_driver of the row driving enhancer is 1 and the input signal of the second input end IN_B_driver is 0, the first NAND gate 301 outputs 0, the first NAND gate 301 outputs 0 after passing through the first transmission gate 201, and the third P-type transistor unit 503P is turned on. The second NAND gate 302 outputs 1, the second NAND gate 302 outputs 0 after passing through the second inverter 402, the third N-type transistor unit 503N is turned off, and an output signal of the output end OUT_driver of the row driving enhancer is a signal (at a high level) of the first power supply line VDD.

When the input signal of the first input end IN_driver of the row driving enhancer is 0 and the input signal of the second input end IN_B_driver is 1, the first NAND gate 301 outputs 1, the first NAND gate 301 outputs 1 after passing through the first transmission gate 201, and the third P-type transistor unit 503P is turned off. The second NAND gate 302 outputs 0, the second NAND gate 302 outputs 1 after passing through the second inverter 402, the third N-type transistor unit 503N is turned on, and an output signal of the output end OUT_driver of the row driving enhancer is a signal (at a low level) of the second power supply line VSS.

In an exemplary implementation, when the enabling signal of the enabling signal end EN is 0, the circuit outputs is in a high impedance state. When the enabling signal of the enabling signal end EN is 1, the circuit output does not change a logical relationship between high and low input and output, and the enabling signal of the enabling signal end EN is a high-impedance-state control signal. In principle, the row driving enhancer is a buffer with a relatively large length-breadth radio, so the output current is large and the driving capability is high. At the same time, the row driving enhancer has small output impedance, the small output impedance leads to a strong driving ability.

In an exemplary implementation, the input end IN_shifter of the level converter may be connected to an output end of the logic operation circuit 200, the first output end OUT_shifter of the level converter may be connected to the first input end IN_driver of the row driving enhancer, the second output end OUT_B_shifter of the level converter may be connected to the second input end IN_B_driver of the row driving enhancer, and the output end OUT_driver of the row driving enhancer may be connected to the scanning signal line in the display region.

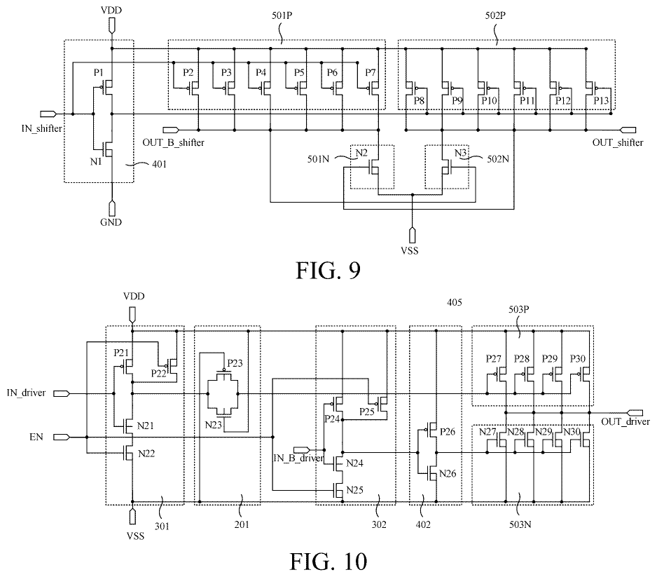

FIG. 9 is an equivalent circuit diagram of a level converter according to an exemplary embodiment of the present disclosure. As shown in FIG. 9, the level converter of the gate driving circuit in the display substrate of an embodiment of the present disclosure may include 16 transistors. Herein, the first inverter 401 includes one P-type transistor and one N-type transistor, the first P-type transistor unit 501P includes six P-type transistors, the second P-type transistor unit 502P includes six P-type transistors, the first N-type transistor unit 501N includes one N-type transistor, and the second N-type transistor unit 502N includes one N-type transistor.

In an exemplary implementation, the first P-type transistor P1 and the first N-type transistor N1 form the first inverter 401. A gate electrode of the first P-type transistor P1 and a gate electrode of the first N-type transistor N1 are both connected to an input end IN_shifter of the converter, a first electrode of the first P-type transistor P1 is connected to the first power supply line VDD, a first electrode of the first N-type transistor N1 is connected to the ground line GND, and a second electrode of the first P-type transistor P1 is connected to a second electrode of the first N-type transistor N1.

In an exemplary implementation, the first P-type transistor unit 501P and the first N-type transistor unit 501N may be referred to as first level conversion units, and the second P-type transistor unit 502P and the second N-type transistor unit 502N may be referred to as second level conversion units.

In an exemplary implementation, the second P-type transistor P2, the third P-type transistor P3, the fourth P-type transistor P4, the fifth P-type transistor P5, the sixth P-type transistor P6, and the seventh P-type transistor P7 connected in parallel form the first P-type transistor unit 501P, wherein gate electrodes of the second P-type transistor P2 to the seventh P-type transistors P7 are all connected to the input end IN_shifter of the converter, first electrodes of the second P-type transistor P2 to the seventh P-type transistors P7 are all connected to the first power supply line VDD, and second electrodes of the second P-type transistor P2 to the seventh P-type transistor P2 are all respectively connected to a gate electrode of the third N-type transistor and a second output end OUT_B_shifter of the converter.

In an exemplary implementation, the eighth P-type transistor P8, the ninth P-type transistor P9, the tenth P-type transistor P10, the eleventh P-type transistor P11, the twelfth P-type transistor P12, and the thirteenth P-type transistor P13 connected in parallel form the second P-type transistor unit 502P, wherein gate electrodes of the eighth P-type transistor P8 to the thirteenth P-type transistor P13 are connected to a second electrode of the first P-type transistor P1 and a second electrode of the first N-type transistor N1, first electrodes of the eighth P-type transistor P8 to the thirteenth P-type transistor P13 are all connected to the first power supply line VDD, and second electrodes of the eighth P-type transistor P8 to the thirteenth P-type transistor P13 are respectively connected to a gate electrode of the second N-type transistor N2 and a first output end OUT_shifter of the converter.

In an exemplary implementation, the second N-type transistor N2 serves as the first N-type transistor unit 501N, and the gate electrode of the second N-type transistor N2 is respectively connected to the first output end OUT_shifter of the converter and the second electrodes of the eighth P-type transistor P8 to the thirteenth P-type transistor P13. The first electrode of the second N-type transistor N2 is connected to the second power supply line VSS, and the second electrode of the second N-type transistor N2 is respectively connected to the second output end OUT_B_shifter of the converter and the second electrodes of the second P-type transistor P2 to the seventh P-type transistor P7.

In an exemplary implementation, the third N-type transistor N3 serves as the second N-type transistor unit 502N, the gate electrode of the third N-type transistor N3 is respectively connected to the second output end OUT_B_shifter of the converter and the second electrodes of the second P-type transistor P2 to the seventh P-type transistor P7, the first electrode of the third N-type transistor N3 is connected to the second power supply line VSS, and the second electrode of the third N-type transistor N3 is respectively connected to the first output end OUT_shifter of the converter and the second electrodes of the eighth P-type transistor P8 to the thirteenth P-type transistor P13.

In some possible implementations, the first P-type transistor unit 501P may include 1, 2, 3, 4, or 5 P-type transistors, and the second P-type transistor unit 502P may include 1, 2, 3, 4, or 5 P-type transistors, which is not limited here in the present disclosure.

FIG. 10 is an equivalent circuit diagram of a row driving enhancer according to an exemplary embodiment of the present disclosure. As shown in FIG. 10, the row driving enhancer of the gate driving circuit in the display substrate of an embodiment of the present disclosure may include 20 transistors. Herein, the first NAND gate 301 includes two P-type transistors and two N-type transistors, the second NAND gate 302 includes two P-type transistors and two N-type transistors, the first transmission gate 201 includes one P-type transistor and one N-type transistor, the second inverter 402 includes one P-type transistor and one N-type transistor, the third P-type transistor unit 503P includes four P-type transistors, and the third N-type transistor unit 503N includes four N-type transistors.

In an exemplary implementation, the first NAND gate 301, the first transmission gate 201, the second NAND gate 302, and the second inverter 402 may be disposed sequentially along the first direction X (a direction close to the display region), the third P-type transistor unit 503P and the third N-type transistor unit 503N may be disposed on a side of the second inverter 402 in the first direction X, and the third N-type transistor unit 503N may be disposed on a side of the third P-type transistor unit 503P in the second direction Y.

In an exemplary implementation, the twenty-first P-type transistor P21, the twenty-second P-type transistor P22, the twenty-first N-type transistor N21, and the twenty-second N-type transistor N22 form the first NAND gate 301. A gate electrode of the twenty-first P-type transistor P21 and a gate electrode of the twenty-first N-type transistor N21 are connected to each other, and are connected to a first input end In_driver of the enhancer. A gate electrode of the twenty-second P-type transistor P22 and a gate electrode of the twenty-second N-type transistor N22 are connected to each other, and are connected to the enabling signal end EN. A first electrode of the twenty-first P-type transistor P21 and a first electrode of the twenty-second P-type transistor P22 are both connected to the first power supply line VDD. A first electrode of the twenty-second N-type transistor N22 is connected to the second power supply line VSS, and a second electrode of the twenty-second N-type transistor N22 is connected to a first electrode of the twenty-first N-type transistor N21. A second electrode of the twenty-first P-type transistor P21 and a second electrode of the twenty-second P-type transistor P22 are connected to each other, and are respectively connected to a second electrode of the twenty-first N-type transistor N21, a first electrode of the twenty-third P-type transistor P23 and a first electrode of the twenty-third N-type transistor N23.

In an exemplary implementation, the twenty-third P-type transistor P23 and the twenty-third N-type transistor N23 form the first transmission gate 201. A gate electrode of the twenty-third P-type transistor P23 is connected to the second power supply line VSS, and a gate electrode of the twenty-third N-type transistor N23 is connected to the first power supply line VDD. A first electrode of the twenty-third P-type transistor P23 and a first electrode of the twenty-third N-type transistor N23 are connected to each other, and are respectively connected to a second electrode of the twenty-first P-type transistor P21, a second electrode of the twenty-first N-type transistor N21, and a second electrode of the twenty-second P-type transistor P22. A second electrode of the twenty-third P-type transistor P23 and a second electrode of the twenty-third N-type transistor N23 are connected to each other, and are respectively connected to gate electrodes of the twenty-seventh P-type transistor P27 to the thirtieth P-type transistor P30.

In an exemplary implementation, the twenty-fourth P-type transistor P24, the twenty-fifth P-type transistor P25, the twenty-fourth N-type transistor N24, and the twenty-fifth N-type transistor N25 form the second NAND gate 302. A gate electrode of the twenty-fourth P-type transistor P24 and a gate electrode of the twenty-fourth N-type transistor N24 are connected to each other, and are connected to a second input end IN_B_driver of the enhancer. A gate electrode of the twenty-fifth P-type transistor P25 and a gate electrode of the twenty-fifth N-type transistor N25 are connected to each other, and are connected to the enabling signal end EN. A first electrode of the twenty-fourth P-type transistor P24 and a first electrode of the twenty-fifth P-type transistor P25 are both connected to the first power supply line VDD. A first electrode of the twenty-fifth N-type transistor N25 is connected to the second power supply line VSS, and a second electrode of the twenty-fifth N-type transistor N25 is connected to a first electrode of the twenty-fourth N-type transistor N24. A second electrode of the twenty-fourth P-type transistor P24 and a second electrode of the twenty-fifth P-type transistor P25 are connected to each other, and are respectively connected to a second electrode of the twenty-fourth N-type transistor N24, a gate electrode of the twenty-sixth P-type transistor P26 and a gate electrode of the twenty-sixth N-type transistor N26.

In an exemplary implementation, the twenty-sixth P-type transistor P26 and the twenty-sixth N-type transistor N26 form the second inverter 402. A gate electrode of the twenty-sixth P-type transistor P26 and a gate electrode of the twenty-sixth N-type transistor N26 are connected to each other, and are respectively connected to a second electrode of the twenty-fourth P-type transistor P24, a second electrode of the twenty-fourth N-type transistor N24, and a second electrode of the twenty-fifth P-type transistor P25. A first electrode of the twenty-sixth P-type transistor P26 is connected to the first power supply line VDD, and a first electrode of the twenty-sixth N-type transistor N26 is connected to the second power supply line VSS. A second electrode of the twenty-sixth P-type transistor P26 and a second electrode of the twenty-sixth N-type transistor N26 are connected to each other, and are respectively connected to gate electrodes of the twenty-seventh N-type transistor N27 to the thirtieth N-type transistor N30.

In an exemplary implementation, the third P-type transistor unit 503P and the third N-type transistor unit 503N may be referred to as output units of the row driving enhancer.

In an exemplary implementation, the twenty-seventh P-type transistor P27, the twenty-eighth P-type transistor P28, the twenty-ninth P-type transistor P29, and the thirtieth P-type transistor P30 connected in parallel form the third P-type transistor unit 503P. Gate electrodes of the twenty-seventh P-type transistor P27 to the thirtieth P-type transistor P30 are connected to each other, and are respectively connected to a second electrode of the twenty-third P-type transistor P23 and a second electrode of the twenty-third N-type transistor N23. First electrodes of the twenty-seventh P-type transistor P27 to the thirtieth P-type transistor P30 are both connected to the first power supply line VDD, and second electrodes of the twenty-seventh P-type transistor P27 to the thirtieth P-type transistor P30 are both connected to an output end OUT_driver of the enhancer.

In an exemplary implementation, the twenty-seventh N-type transistor N27, the twenty-eighth N-type transistor N28, the twenty-ninth N-type transistor N29, and the thirtieth N-type transistor N30 connected in parallel form the third N-type transistor unit 503N. Gate electrodes of the twenty-seventh N-type transistor N27 to the thirtieth N-type transistor N30 are connected to each other, and are respectively connected to a second electrode of the twenty-sixth P-type transistor P26 and a second electrode of the twenty-sixth N-type transistor N26. First electrodes of the twenty-seventh N-type transistor N27 to the thirtieth N-type transistor N30 are both connected to the second power supply line VSS, and second electrodes of the twenty-seventh N-type transistor N27 to the thirtieth N-type transistor N30 are both connected to an output end OUT_driver of the enhancer.

In some possible implementations, the third P-type transistor unit 503P may include 1, 2, 3, or 5 or more P-type transistors, and the third N-type transistor unit 503N may include 1, 2, 3, or 5 or more N-type transistors, which is not limited here in the present disclosure.

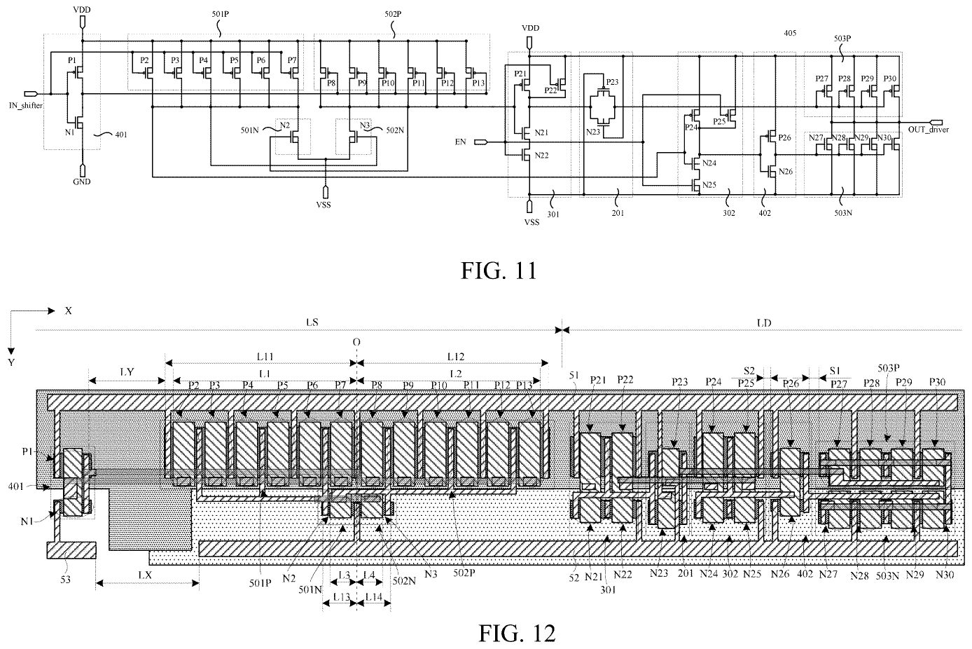

FIG. 11 is an equivalent circuit diagram of an output circuit according to an exemplary embodiment of the present disclosure. As shown in FIGS. 9, 10, and 11, the output circuit includes the level converter shown in FIG. 9 and the row driving enhancer shown in FIG. 10, wherein a first output end OUT_shifter of the converter is connected to a first input end IN_driver of the enhancer, and a second output end OUT_B_shifter of the converter is connected to a second input end IN_B_driver of the enhancer.

FIG. 12 is a schematic diagram of a structure of an output circuit according to an exemplary embodiment of the present disclosure. In an exemplary implementation, the display substrate of an exemplary embodiment of the present disclosure may at least include a display region and a non-display region. The display region may include a plurality of sub-pixels forming a plurality of pixel rows and a plurality of pixel columns, and at least one sub-pixel includes a pixel driving circuit and at least one scanning signal line, which is configured to provide a scanning signal to the connected pixel driving circuit. The non-display region may include a plurality of cascaded gate driving circuits, and at least one gate driving circuit is connected to a scanning signal line in one pixel row in the display region. The at least one gate driving circuit may include a shift register circuit, a logic operation circuit and an output circuit which are disposed on a silicon base substrate, wherein the shift register circuit is configured to generate timings of row-by-row shifts according to timing signals, the logic operation circuit is configured to generate target timings through a logic operation, and the output circuit is configured to output signals to the scanning signal line of the display region after performing a voltage domain conversion and a signal enhancement.

As illustrated in FIG. 12, the silicon base substrate of the output circuit may at least include a first region LS and a second region LD, wherein the second region LD may be disposed on a side of the first region LS in the first direction X (a direction close to the display region), the first region LS is configured to provide a level converter, and the second region LD is configured to provide a row driving enhancer, such that the row driving enhancer is disposed on a side of the level converter close to the display region. In an exemplary implementation, the level converter is configured to perform voltage domain conversions on the target timings, and the row driving enhancer is configured to enhance converted signals and output them to a scanning signal line of the display region.

In an exemplary implementation, the level converter may include a first inverter 401, a first level conversion unit, and a second level conversion unit, which are disposed sequentially along a first direction X (a direction of a pixel row in the display region), wherein the first level conversion unit may include a first P-type transistor unit 501P and a first N-type transistor unit 501N, and the second level conversion unit may include a second P-type transistor unit 502P and a second N-type transistor unit 502N.

In an exemplary implementation, the row driving enhancer may include a first NAND gate 301, a first transmission gate 201, a second NAND gate 302, a second inverter 402, and an output unit, which are disposed sequentially along the first direction X, wherein the output unit may include a third P-type transistor unit 503P and a third N-type transistor unit 503N.

In an exemplary implementation, the first inverter 401 may include a first P-type transistor P1, and a first N-type transistor N1 disposed on a side of the first P-type transistor P1 in the second direction Y (a direction of a pixel column in the display region). The first P-type transistor unit 501P includes a second P-type transistor P2 to a seventh P-type transistor P7 which are disposed on a side of the first P-type transistor P1 close to the display region and disposed sequentially along a direction close to the display region. The second P-type transistor unit 502P includes an eighth P-type transistor P8 to a thirteenth P-type transistor P13 which are disposed on a side of the seventh P-type transistor P7 close to the display region and disposed sequentially along a direction close to the display region. The first N-type transistor unit 501N includes a second N-type transistor N2 disposed on a side of the seventh P-type transistor P7 in the second direction Y, and the second N-type transistor unit 502N includes a third N-type transistor N3 disposed on a side of the eighth P-type transistor P8 in the second direction Y.

In an exemplary implementation, each of the first P-type transistor P1 to the thirteenth P-type transistor P13 may include a P-type active layer, and a second P-type active layer of the second P-type transistor P2 to a thirteenth P-type active layer of the thirteenth P-type transistor P13 may be of an integral structure connected to each other. Each of the first N-type transistor N1 to the third N-type transistor N3 may include an N-type active layer, and a second N-type active layer of the second N-type transistor N2 and a third N-type active layer of the third N-type transistor N3 may be of an integral structure connected to each other.

In an exemplary implementation, the second P-type active region to the thirteenth P-type active region of the integral structure may have an active center line O, which may be a straight line bisecting the integral structure of the second P-type active region to the thirteenth P-type active region in the first direction X and extending along the second direction Y. The second P-type transistor P2 to the seventh P-type transistor P7 in the first P-type transistor unit 501P and the eighth P-type transistor P8 to the thirteenth P-type transistor P13 in the second P-type transistor unit 502P may be mirror-symmetric with respect to the active center line O, and the second N-type transistor N2 in the first N-type transistor unit 501N and the third N-type transistor N3 in the second N-type transistor unit 502N may be mirror-symmetric with respect to the active center line O.

In an exemplary implementation, a second P-type gate electrode of the second P-type transistor P2 to a seventh P-type gate electrode of the seventh P-type transistor P7, and an eighth P-type gate electrode of the eighth P-type transistor P8 to a thirteenth P-type gate electrode of the thirteenth P-type transistor P13 may be mirror-symmetrical with respect to the active center line O.

In an exemplary implementation, there is a first length L1 between an edge of the second P-type gate electrode of the second P-type transistor P2 on a side away from the active center line O and the active center line O, there is a second length L2 between an edge of the thirteenth P-type gate electrode of the thirteenth P-type transistor P13 on a side away from the active center line O and the active center line O, and a ratio of the first length L1 to the second length L2 may be about 0.95 to 1.05.

In an exemplary implementation, the second N-type gate electrode of the second N-type transistor N2 and the third N-type gate electrode of the third N-type transistor N3 may be mirror-symmetrical with respect to the active center line O.

In an exemplary implementation, there is a third length L3 between an edge of the second N-type gate electrode of the second N-type transistor N2 on a side away from the active center line O and the active center line O, there is a fourth length L4 between an edge of the third N-type gate electrode of the third N-type transistor N3 on a side away from the active center line O and the active center line O, and a ratio of the third length L3 to the fourth length L4 may be about 0.95 to 1.05.

In an exemplary implementation, a second P-type source electrode and a second P-type drain electrode of the second P-type transistor P2 to a seventh P-type source electrode and a seventh P-type drain electrode of the seventh P-type transistor P7, and an eighth P-type source electrode and a eighth P-type drain electrode of the eighth P-type transistor P8 to a thirteenth P-type source electrode and a thirteenth P-type drain electrode of the thirteenth P-type transistor P13 may be mirror-symmetrical with respect to the active center line O.

In an exemplary implementation, there is an eleventh length L11 between an edge of the second P-type source electrode of the second P-type transistor P2 on a side away from the active center line O and the active center line O, there is a twelfth length L12 between an edge of the thirteenth P-type source electrode of the thirteenth P-type transistor P13 on a side away from the active center line O and the active center line O, and a ratio of the eleventh length L11 to the twelfth length L12 may be about 0.95 to 1.05.

In an exemplary implementation, the second N-type drain electrode of the second N-type transistor N2 and the third N-type drain electrode of the third N-type transistor N3 may be mirror-symmetrical with respect to the active center line O.

In an exemplary implementation, there is a thirteenth length L13 between an edge of the second N-type drain electrode of the second N-type transistor N2 on a side away from the active center line O and the active center line O, there is a fourteenth length L14 between an edge of the third P-type drain electrode of the third P-type transistor N3 on a side away from the active center line O and the active center line O, and a ratio of the thirteenth length L13 to the fourteenth length L14 may be about 0.95 to 1.05.

In an exemplary implementation, there is a voltage domain distance LY between an edge of a first P-type drain electrode of the first P-type transistor P1 at a side close to the second P-type transistor P2 and an edge of a second P-type source electrode of the second P-type transistor P2 at a side close to the first P-type transistor P1, and the voltage domain distance LY may be greater than or equal to 3.67 μm.

In an exemplary implementation, the output circuit may further include a first power supply line 51, a second power supply line 52, and a ground line 53, whose shapes may be a line shape extending along the first direction X, wherein the first power supply line 51 may be disposed on a side of the plurality of P-type transistors away from the N-type transistors, the second power supply line 52 may be disposed on a side of the plurality of N-type transistors away from the P-type transistors, and the ground line 53 may be disposed on a side of the first N-type transistor N1 away from the first P-type transistor P1. In an exemplary implementation, the first power supply line 51 is configured to transmit a first power supply signal, the second power supply line 52 is configured to transmit a second power supply signal, and the ground line 53 is configured to transmit a ground signal.

In an exemplary implementation, there is a voltage line distance LX between an edge of the second power supply line 52 on a side close to the ground line 53 and an edge of the ground line 53 on a side close to the second power supply line 52, and the voltage line distance LX may be greater than or equal to 5 μm.

In an exemplary implementation, the row driving enhancer may include a plurality of transistor groups disposed sequentially along a first direction X, at least one transistor group includes a P-type transistor and an N-type transistor disposed on a side of the P-type transistor in a second direction Y, and the first direction X intersects with the second direction Y; a plurality of transistor groups form a first NAND gate 301, a first transmission gate 201, a second NAND gate 302, a second inverter 402, and an output unit disposed sequentially along a direction close to the display region, wherein there is a first distance S1 between a transistor group in the second inverter 402 and a transistor group in the output unit, there is a second distance S2 between two adjacent transistor groups in the first NAND gate 301, the first transmission gate 201, the second NAND gate 302 and the second inverter 402, the first distance S1 is larger than the second distance S2, and both the first distance S1 and the second distance S2 are dimensions in the first direction X.

In an exemplary implementation, a ratio of the first distance S1 to the second distance S2 may be about 0.7 to 0.8.

In an exemplary implementation, the first distance S1 may be greater than or equal to 0.5 μm, and the second distance S2 may be greater than or equal to 0.36 μm.

A manufacturing process of the display apparatus will be described below by way of example. A “patterning process” mentioned in the present disclosure includes treatments such as deposition of a film, photoresist coating on a film, mask exposure, development, etching, and photoresist stripping for a metal material, an inorganic material, or a transparent conductive material, and includes treatments such as organic material coating, mask exposure, and development for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B being disposed on the same layer” mentioned in the present disclosure means that A and B are formed simultaneously through the same running of the patterning process, and the “thickness” of the film is the dimension of the film in a direction perpendicular to the display apparatus. In an exemplary implementation of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A is overlapped with the boundary of the orthographic projection of B.

In an exemplary implementation, the manufacturing process of the display substrate may include following acts.

(1) A silicon base substrate is provided. In an exemplary implementation, the silicon base substrate may be a P-type silicon base substrate. In an exemplary implementation, the P-type silicon base substrate may serve as a channel region of an N-type transistor.

In an exemplary implementation, the P-type silicon base substrate may include a first region LS and a second region LD, wherein the second region LD may be disposed on a side of the first region LS in the first direction X (a direction near the display region), the first region LS is configured to dispose a device of a level converter, and the second region LD is configured to dispose a device of a row driving enhancer.

In some possible implementations, the silicon base substrate may be made of an N-type silicon material which may serve as a channel region of a P-type transistor, and the present disclosure is not limited thereto.

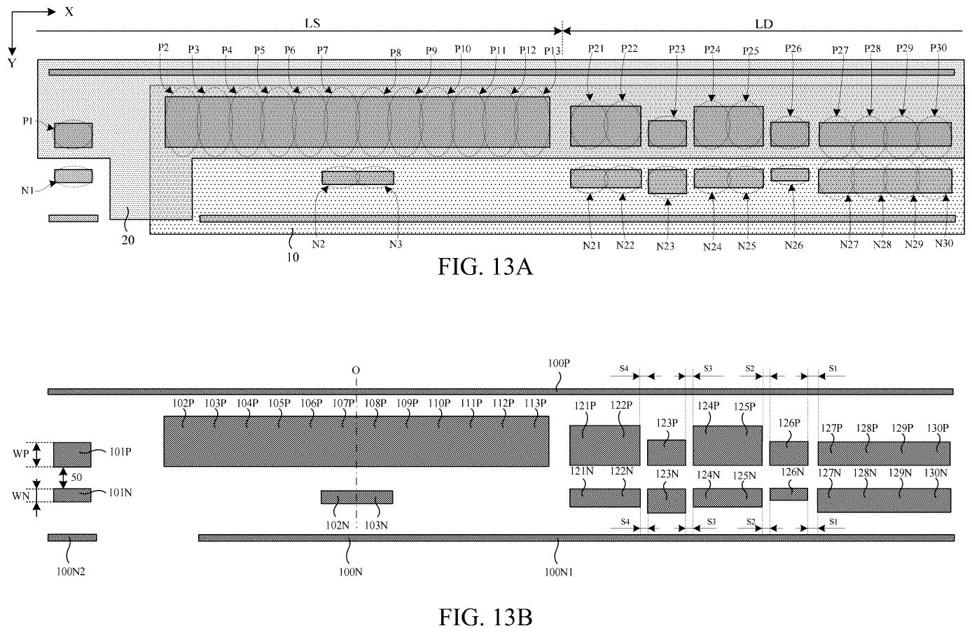

(2) Patterns of a deep N well (Deep N type well, DNW for short) region, an N well (N type well, NW for short) region and an active region (Active Area, AA for short) are sequentially formed. In an exemplary implementation, a photoresist pattern including an opening region may be formed by coating a photoresist on a P-type silicon base substrate, exposure and development, and the photoresist within the opening region is removed to expose a surface of the P-type silicon base substrate. N-type doped ions are implanted within the opening region by ion implantation, the remaining photoresist is peeled off, and a pattern of the deep N-well region 10 may be formed on the P-type silicon base substrate. Subsequently, patterns of the N-well region 20 and the active region are sequentially formed on the silicon base substrate on which the aforementioned pattern is formed, as shown in FIGS. 13A and 13B, and FIG. 13B is a schematic diagram of the active region in FIG. 13A.

In an exemplary implementation, the deep N-well region 10 of the first region LS and the deep N-well region 20 of the second region LD may be of an integral structure connected to each other, and the N-well region 20 of the first region LS and the N-well region 20 of the second region LD may be of an integral structure connected to each other.

In an exemplary implementation, plasma implants such as phosphorus or arsenic may be used for n-type doped ions, and the depth and doping concentration of ion implantation may be achieved by controlling the implantation energy and dose. The process of forming the deep N-well region may further include a process such as annealing, so as to make the ion implant diffuse in the P-type silicon base substrate to form a stable deep N-well structure.

In an exemplary implementation, the deep N-well region 10 is configured to electrically isolate different regions to effectively limit the path through which current flows, thereby reducing leakage and energy loss. The N-well region 20 is configured to form a P-type transistor and a P-type device, and a region other than the N-well region is configured to form an N-type transistor and an N-type device.

In an exemplary implementation, the pattern of the active region may at least include a first P-type active region 101P to a thirteenth P-type active region 113P, a twenty-first P-type active region 121P to a thirtieth P-type active region 130P, a first N-type active region 101N to a third N-type active region 103N, a twenty-first N-type active region 121N to a thirtieth N-type active region 130N, a first power supply active region 100P, a second power supply active region 100N1, and a ground active region 100N2.

In an exemplary implementation, the first P-type active region 101P to the thirteenth P-type active region 113P and the first N-type active region 101N to the third N-type active region 103N may be disposed in the first region LS, and the twenty-first P-type active region 121P to the thirtieth P-type active region 130P and the twenty-first N-type active region 121N to the thirtieth N-type active region 130N may be disposed in the second region LD.

In an exemplary implementation, a shape of the first P-type active region 101P may be a block (such as a rectangle) shape, and the first P-type active region 101P may be located outside a region where the deep N-well region 10 is located but within a region where the N-well region 20 is located. An orthographic projection of the first P-type active region 101P on the silicon base substrate is not overlapped with an orthographic projection of the deep N-well region 10N on the silicon base substrate, the orthographic projection of the first P-type active region 101P on the silicon base substrate is located within a range of the orthographic projection of the N-well region 20 on the silicon base substrate, and the first P-type active region 101P may serve as an active region of the first P-type transistor P1.

In an exemplary implementation, a shape of the first N-type active region 101N may be a block (such as a rectangle) shape, and may be located on a side of the first P-type active region 101P in the second direction Y. The first N-type active region 101N may be located outside a region where the deep N-well region 10 and the N-well region 20 are located. An orthographic projection of the first N-type active region 101N on the silicon base substrate is not overlapped with an orthographic projection of the deep N-well region 10N on the silicon base substrate, the orthographic projection of the first N-type active region 101N on the silicon base substrate is not overlapped with the orthographic projection of the N-well region 20 on the silicon base substrate, and the first N-type active region 101N may serve as an active region of the first N-type transistor N1.

In an exemplary implementation, a shape of the second P-type active region 102P may be a block (such as a rectangle) shape, the second P-type active region 102P may be located within a region where the deep N-well region 10 and the N-well region 20 are located. An orthographic projection of the second P-type active region 102P on the silicon base substrate is located within a range of the orthographic projections of the deep N-well region 10 and the N-well region 20 on the silicon base substrate, and the second P-type active region 102P may serve as an active region of the second P-type transistor P2.

In an exemplary implementation, a shape of the third P-type active region 103P may be a block shape (such as a rectangle), and the third P-type active region 103P may be located within a region where the deep N-well region 10 and the N-well region 20 are located. An orthographic projection of the third P-type active region 103P on the silicon base substrate is located within a range of the orthographic projections of the deep N-well region 10 and the N-well region 20 on the silicon base substrate, and the third P-type active region 103P may serve as an active region of the third P-type transistor P3.

In an exemplary implementation, a shape of the fourth P-type active region 104 P may be a block (such as a rectangle) shape, and the fourth P-type active region 104 P may be located within a region where the deep N-well region 10 and the N-well region 20 are located. An orthographic projection of the fourth P-type active region 104 P on the silicon base substrate is located within a range of the orthographic projections of the deep N-well region 10 and the N-well region 20 on the silicon base substrate, and the fourth P-type active region 104 P may serve as an active region of the fourth P-type transistor P4.

In an exemplary implementation, a shape of the fifth P-type active region 105P may be a block (such as a rectangle) shape, the fifth P-type active region 105P may be located within a region where the deep N-well region 10 and the N-well region 20 are located. An orthographic projection of the fifth P-type active region 105P on the silicon base substrate is located within a range of the orthographic projections of the deep N-well region 10 and the N-well region 20 on the silicon base substrate, and the fifth P-type active region 105P may serve as an active region of the fifth P-type transistor P5.

In an exemplary implementation, a shape of the sixth P-type active region 106P may be a block shape (such as a rectangle), the sixth P-type active region 106P may be located within a region where the deep N-well region 10 and the N-well region 20 are located. An orthographic projection of the sixth P-type active region 106P on the silicon base substrate is located within a range of the orthographic projections of the deep N-well region 10 and the N-well region 20 on the silicon base substrate, and the sixth P-type active region 106P may serve as an active region of the sixth P-type transistor P6.

In an exemplary implementation, a shape of the seventh P-type active region 107P may be a block shape (such as a rectangle), and the seventh P-type active region 107P may be located within a region where the deep N-well region 10 and the N-well region 20 are located. An orthographic projection of the seventh P-type active region 107P on the silicon base substrate is located within a range of the orthographic projections of the deep N-well region 10 and the N-well region 20 on the silicon base substrate, and the seventh P-type active region 107P may serve as an active region of the seventh P-type transistor P7.

In an exemplary implementation, a shape of the eighth P-type active region 108P may be a block (such as a rectangle) shape, the eighth P-type active region 108P may be located within a region where the deep N-well region 10 and the N-well region 20 are located. An orthographic projection of the eighth P-type active region 108P on the silicon base substrate is located within a range of the orthographic projections of the deep N-well region 10 and the N-well region 20 on the silicon base substrate, and the eighth P-type active region 108P may serve as an active region of the eighth P-type transistor P8.

In an exemplary implementation, a shape of the ninth P-type active region 109P may be a block shape (such as a rectangle), the ninth P-type active region 109P may be located within a region where the deep N-well region 10 and the N-well region 20 are located. An orthographic projection of the ninth P-type active region 109P on the silicon base substrate is located within a range of the orthographic projections of the deep N-well region 10 and the N-well region 20 on the silicon base substrate, and the ninth P-type active region 109P may serve as an active region of the ninth P-type transistor P9.

In an exemplary implementation, a shape of the tenth P-type active region 110P may be a block shape (such as a rectangle), and the tenth P-type active region 110P may be located within a region where the deep N-well region 10 and the N-well region 20 are located. An orthographic projection of the tenth P-type active region 110P on the silicon base substrate is located within a range of the orthographic projections of the deep N-well region 10 and the N-well region 20 on the silicon base substrate, and the tenth P-type active region 110P may serve as an active region of the tenth P-type transistor P10.

In an exemplary implementation, a shape of the eleventh P-type active region 111P may be a block (such as a rectangle) shape, the eleventh P-type active region 111P may be located within a region where the deep N-well region 10 and the N-well region 20 are located. An orthographic projection of the eleventh P-type active region 111P on the silicon base substrate is located within a range of the orthographic projections of the deep N-well region 10 and the N-well region 20 on the silicon base substrate, and the eleventh P-type active region 111P may serve as an active region of the eleventh P-type transistor P11.

In an exemplary implementation, a shape of the twelfth P-type active region 112P may be a block (such as a rectangle) shape, the twelfth P-type active region 112P may be located within a region where the deep N-well region 10 and the N-well region 20 are located. An orthographic projection of the twelfth P-type active region 112P on the silicon base substrate is located within a range of the orthographic projections of the deep N-well region 10 and the N-well region 20 on the silicon base substrate, and the twelfth P-type active region 112P may serve as an active region of the twelfth P-type transistor P12.

In an exemplary implementation, a shape of the thirteenth P-type active region 113P may be a block shape (such as a rectangle), and the thirteenth P-type active region 113P may be located within a region where the deep N-well region 10 and the N-well region 20 are located. An orthographic projection of the thirteenth P-type active region 113P on the silicon base substrate is located within a range of the orthographic projections of the deep N-well region 10 and the N-well region 20 on the silicon base substrate, and the thirteenth P-type active region 113P may serve as an active region of the thirteenth P-type transistor P13.

In an exemplary implementation, the second P-type active region 102P to the thirteenth P-type active region 113P may be an integral structure connected to each other.

In an exemplary implementation, a shape of the second N-type active region 102N may be a block (such as a rectangle) shape, and may be located on a side of the seventh P-type active region 107P in the second direction Y. The second N-type active region 102N is located within a region where the deep N-well region 10 is located but outside a region where the N-well region 20 is located. An orthographic projection of the second N-type active region 102N on the silicon base substrate is located within a range of an orthographic projection of the deep N-well region 10 on the silicon base substrate, the orthographic projection of the second N-type active region 102N on the silicon base substrate is not overlapped with an orthographic projection of the N-well region 20 on the silicon base substrate, and the second N-type active region 102N may serve as an active region of the second N-type transistor N2.

In an exemplary implementation, a shape of the third N-type active region 103N may be a block (such as a rectangle) shape, and may be located on a side of the eighth P-type active region 108P in the second direction Y. The third N-type active region 103N is located within a region where the deep N-well region 10 is located but outside a region where the N-well region 20 is located. An orthographic projection of the third N-type active region 103N on the silicon base substrate is located within a range of an orthographic projection of the deep N-well region 10 on the silicon base substrate, the orthographic projection of the third N-type active region 103N on the silicon base substrate is not overlapped with an orthographic projection of the N-well region 20 on the silicon base substrate, and the third N-type active region 103N may serve as an active region of the third N-type transistor N3.

In an exemplary implementation, the second N-type active region 102N and the third N-type active region 103N may be of an integral structure connected to each other.

In an exemplary implementation, the second P-type active region 102P to the thirteenth P-type active region 113P of the integral structure may have an active center line O, which may be a straight line bisecting the integral structure of the second P-type active region 102P to the thirteenth P-type active region 113P in the first direction X and extending along the second direction Y.

In an exemplary implementation, the second P-type active region 102P to the seventh P-type active region 107P, and the eighth P-type active region 108P to the thirteenth P-type active region 113P may be disposed symmetrically with respect to the active center line O. Specifically, the second P-type active region 102P and the thirteenth P-type active region 113P may be symmetrically disposed with respect to the active center line O, the third P-type active region 103P and the twelfth P-type active region 112P may be symmetrically disposed with respect to the active center line O, the fourth P-type active region 104P and the eleventh P-type active region 111P may be symmetrically disposed with respect to the active center line O, the fifth P-type active region 105P and the tenth P-type active region 110P may be symmetrically disposed with respect to the active center line O, the sixth P-type active region 106P and the ninth P-type active region 109P may be symmetrically disposed with respect to the active center line O, and the seventh P-type active region 107P and the eighth P-type active region 108P may be symmetrically disposed with respect to the active center line O.

In an exemplary implementation, the second N-type active region 102N and the third N-type active region 103N may be disposed symmetrically with respect to the active center line O.

In an exemplary implementation, a shape of the twenty-first P-type active region 121P may be a block (such as a rectangle) shape, the twenty-first P-type active region 121P may be located within a region where the deep N-well region 10 and the N-well region 20 are located. An orthographic projection of the twenty-first P-type active region 121P on the silicon base substrate is located within a range of the orthographic projections of the deep N-well region 10 and the N-well region 20 on the silicon base substrate, and the twenty-first P-type active region 121P may serve as an active region of the twenty-first P-type transistor P21.

In an exemplary implementation, a shape of the twenty-second P-type active region 122P may be a block (such as a rectangle) shape, the twenty-second P-type active region 122P may be located within a region where the deep N-well region 10 and the N-well region 20 are located. An orthographic projection of the twenty-second P-type active region 122P on the silicon base substrate is located within a range of the orthographic projections of the deep N-well region 10 and the N-well region 20 on the silicon base substrate, and the twenty-second P-type active region 122P may serve as an active region of the twenty-second P-type transistor P22.

In an exemplary implementation, the twenty-first P-type active region 121P and the twenty-second P-type active region 122P may be of an integral structure connected to each other.

In an exemplary implementation, a shape of the twenty-third P-type active region 123P may be a block shape (such as a rectangle), and the twenty-third P-type active region 123P may be located within a region where the deep N-well region 10 and the N-well region 20 are located. An orthographic projection of the twenty-third P-type active region 123P on the silicon base substrate is located within a range of the orthographic projections of the deep N-well region 10 and the N-well region 20 on the silicon base substrate, and the twenty-third P-type active region 123P may serve as an active region of the twenty-third P-type transistor P23.

In an exemplary implementation, a shape of the twenty-fourth P-type active region 124P may be a block (such as a rectangle) shape, the twenty-fourth P-type active region 124P may be located within a region where the deep N-well region 10 and the N-well region 20 are located. An orthographic projection of the twenty-fourth P-type active region 124P on the silicon base substrate is located within a range of the orthographic projections of the deep N-well region 10 and the N-well region 20 on the silicon base substrate, and the twenty-fourth P-type active region 124P may serve as an active region of the twenty-fourth P-type transistor P24.

In an exemplary implementation, a shape of the twenty-fifth P-type active region 125P may be a block (such as a rectangle) shape, the twenty-fifth P-type active region 125P may be located within a region where the deep N-well region 10 and the N-well region 20 are located. An orthographic projection of the twenty-fifth P-type active region 125P on the silicon base substrate is located within a range of the orthographic projections of the deep N-well region 10 and the N-well region 20 on the silicon base substrate, and the twenty-fifth P-type active region 125P may serve as an active region of the twenty-fifth P-type transistor P25.

In an exemplary implementation, the twenty-fourth P-type active region 124P and the twenty-fifth P-type active region 125P may be of an integral structure connected to each other.

In an exemplary implementation, a shape of the twenty-sixth P-type active region 126P may be a block (such as a rectangle) shape, the twenty-sixth P-type active region 126P may be located within a region where the deep N-well region 10 and the N-well region 20 are located. An orthographic projection of the twenty-sixth P-type active region 126P on the silicon base substrate is located within a range of the orthographic projections of the deep N-well region 10 and the N-well region 20 on the silicon base substrate, and the twenty-sixth P-type active region 126P may serve as an active region of the twenty-sixth P-type transistor P26.

In an exemplary implementation, a shape of the twenty-seventh P-type active region 127P may be a block (such as a rectangle) shape, the twenty-seventh P-type active region 127P may be located within a region where the deep N-well region 10 and the N-well region 20 are located. An orthographic projection of the twenty-seventh P-type active region 127P on the silicon base substrate is located within a range of the orthographic projections of the deep N-well region 10 and the N-well region 20 on the silicon base substrate, and the twenty-seventh P-type active region 127P may serve as an active region of the twenty-seventh P-type transistor P27.

In an exemplary implementation, a shape of the twenty-eighth P-type active region 128P may be a block (such as a rectangle) shape, the twenty-eighth P-type active region 128P may be located within a region where the deep N-well region 10 and the N-well region 20 are located. An orthographic projection of the twenty-eighth P-type active region 128P on the silicon base substrate is located within a range of the orthographic projections of the deep N-well region 10 and the N-well region 20 on the silicon base substrate, and the twenty-eighth P-type active region 128P may serve as an active region of the twenty-eighth P-type transistor P28.

In an exemplary implementation, a shape of the twenty-ninth P-type active region 129P may be a block (such as a rectangle) shape, the twenty-ninth P-type active region 129P may be located within a region where the deep N-well region 10 and the N-well region 20 are located. An orthographic projection of the twenty-ninth P-type active region 129P on the silicon base substrate is located within a range of the orthographic projections of the deep N-well region 10 and the N-well region 20 on the silicon base substrate, and the twenty-ninth P-type active region 129P may serve as an active region of the twenty-ninth P-type transistor P29.

In an exemplary implementation, a shape of the thirtieth P-type active region 130P may be a block shape (such as a rectangle), and the thirtieth P-type active region 130P may be located within a region where the deep N-well region 10 and the N-well region 20 are located. An orthographic projection of the thirtieth P-type active region 130P on the silicon base substrate is located within a range of the orthographic projections of the deep N-well region 10 and the N-well region 20 on the silicon base substrate, and the thirtieth P-type active region 130P may serve as an active region of the thirtieth P-type transistor P30.

In an exemplary implementation, the twenty-seventh P-type active region 127P to the thirtieth P-type active region 130P may be of an integral structure connected to each other.

In an exemplary implementation, a shape of the twenty-first N-type active region 121N may be a block (such as a rectangle) shape, and may be located on a side of the twenty-first P-type active region 121P in the second direction Y. The twenty-first N-type active region 121N may be located within a region where the deep N-well region 10 and the N-well region 20 are located. An orthographic projection of the twenty-first N-type active region 121N on the silicon base substrate is located within a range of the orthographic projections of the deep N-well region 10 and the N-well region 20 on the silicon base substrate, and the twenty-first N-type active region 121N may serve as an active region of the twenty-first N-type transistor N21.

In an exemplary implementation, a shape of the twenty-second N-type active region 122N may be a block (such as a rectangle) shape, and may be located on a side of the twenty-second P-type active region 122P in the second direction Y. The twenty-second N-type active region 122N may be located within a region where the deep N-well region 10 and the N-well region 20 are located. An orthographic projection of the twenty-second N-type active region 122N on the silicon base substrate is located within a range of the orthographic projections of the deep N-well region 10 and the N-well region 20 on the silicon base substrate, and the twenty-second N-type active region 122N may serve as an active region of the twenty-second N-type transistor N22.

In an exemplary implementation, the twenty-first N-type active region 121 N and the twenty-second N-type active region 122 N may be of an integral structure connected to each other.

In an exemplary implementation, a shape of the twenty-third N-type active region 123N may be a block (such as a rectangle) shape, and may be located on a side of the twenty-third P-type active region 123P in the second direction Y. The twenty-third N-type active region 123N may be located within a region where the deep N-well region 10 and the N-well region 20 are located. An orthographic projection of the twenty-third N-type active region 123N on the silicon base substrate is located within a range of the orthographic projections of the deep N-well region 10 and the N-well region 20 on the silicon base substrate, and the twenty-third N-type active region 123N may serve as an active region of the twenty-third N-type transistor N23.

In an exemplary implementation, a shape of the twenty-fourth N-type active region 124N may be a block (such as a rectangle) shape, and may be located on a side of the twenty-fourth P-type active region 124P in the second direction Y. The twenty-fourth N-type active region 124N may be located within a region where the deep N-well region 10 and the N-well region 20 are located. An orthographic projection of the twenty-fourth N-type active region 124N on the silicon base substrate is located within a range of the orthographic projections of the deep N-well region 10 and the N-well region 20 on the silicon base substrate, and the twenty-fourth N-type active region 124N may serve as an active region of the twenty-fourth N-type transistor N24.

In an exemplary implementation, a shape of the twenty-fifth N-type active region 125N may be a block (such as a rectangle) shape, and may be located on a side of the twenty-fifth P-type active region 125P in the second direction Y. The twenty-fifth N-type active region 125N may be located within a region where the deep N-well region 10 and the N-well region 20 are located. An orthographic projection of the twenty-fifth N-type active region 125N on the silicon base substrate is located within a range of the orthographic projections of the deep N-well region 10 and the N-well region 20 on the silicon base substrate, and the twenty-fifth N-type active region 125N may serve as an active region of the twenty-fifth N-type transistor N25.

In an exemplary implementation, the twenty-fourth N-type active region 124N and the twenty-fifth N-type active region 125N may be of an integral structure connected to each other.

In an exemplary implementation, a shape of the twenty-sixth N-type active region 126N may be block (such as a rectangle) shape, and may be located on a side of the twenty-sixth P-type active region 126P in the second direction Y. The twenty-sixth N-type active region 126N may be located within a region where the deep N-well region 10 and the N-well region 20 are located. An orthographic projection of the twenty-sixth N-type active region 126N on the silicon base substrate is located within a range of the orthographic projections of the deep N-well region 10 and the N-well region 20 on the silicon base substrate, and the twenty-sixth N-type active region 126N may serve as an active region of the twenty-sixth N-type transistor N26.

In an exemplary implementation, a shape of the twenty-seventh N-type active region 127N may be a block (such as a rectangle) shape, and may be located on a side of the twenty-seventh P-type active region 127P in the second direction Y. The twenty-seventh N-type active region 127N may be located within a region where the deep N-well region 10 and the N-well region 20 are located. An orthographic projection of the twenty-seventh N-type active region 127N on the silicon base substrate is located within a range of the orthographic projections of the deep N-well region 10 and the N-well region 20 on the silicon base substrate, and the twenty-seventh N-type active region 127N may serve as an active region of the twenty-seventh N-type transistor N27.

In an exemplary implementation, a shape of the twenty-eighth N-type active region 128N may be block (such as a rectangle) shape, and may be located on a side of the twenty-eighth P-type active region 128P in the second direction Y. The twenty-eighth N-type active region 128N may be located within a region where the deep N-well region 10 and the N-well region 20 are located. An orthographic projection of the twenty-eighth N-type active region 128N on the silicon base substrate is located within a range of the orthographic projections of the deep N-well region 10 and the N-well region 20 on the silicon base substrate, and the twenty-eighth N-type active region 128N may serve as an active region of the twenty-eighth N-type transistor N28.

In an exemplary implementation, a shape of the twenty-ninth N-type active region 129N may be a block (such as a rectangle) shape, and may be located on a side of the twenty-ninth P-type active region 129P in the second direction Y. The twenty-ninth N-type active region 129N may be located within a region where the deep N-well region 10 and the N-well region 20 are located. An orthographic projection of the twenty-ninth N-type active region 129N on the silicon base substrate is located within a range of the orthographic projections of the deep N-well region 10 and the N-well region 20 on the silicon base substrate, and the twenty-ninth N-type active region 129N may serve as an active region of the twenty-ninth N-type transistor N29.

In an exemplary implementation, a shape of the thirtieth N-type active region 130N may be a block (such as a rectangle) shape, and may be located on a side of the thirtieth P-type active region 130P in the second direction Y. The thirtieth N-type active region 130N may be located within a region where the deep N-well region 10 and the N-well region 20 are located. An orthographic projection of the thirtieth N-type active region 130N on the silicon base substrate is located within a range of the orthographic projections of the deep N-well region 10 and the N-well region 20 on the silicon base substrate, and the thirtieth N-type active region 130N may serve as an active region of the thirtieth N-type transistor N30.

In an exemplary implementation, the twenty-seventh N-type active region 127N to the thirtieth N-type active region 130N may be of an integral structure connected to each other.

In an exemplary implementation, a shape of the first power supply active region 100P may be a line shape extending along the first direction X, and may be disposed in the first region LS and the second region LD, that is, the first power supply active region 100P extends from the first region LS to the second region LD, and is located on a side of a plurality of P-type active regions away from a plurality of N-type active regions. The first power supply active region 100P is configured to be connected to a first power supply line formed subsequently.

In an exemplary implementation, the first power supply active region 100P may be located outside a region where the deep N-well region 10 is located but within a region where the N-well region 20 is located. An orthographic projection of the first power supply active region 100P on the silicon base substrate is not overlapped with an orthographic projection of the deep N-well region 10N on the silicon base substrate, and the orthographic projection of the first power supply active region 100P on the silicon base substrate is located within a range of an orthographic projection of the N-well region 20 on the silicon base substrate.

In an exemplary implementation, a shape of the second power supply active region 100N1 may be a strip shape extending along the first direction X, and may be disposed in the first region LS and the second region LD, that is, the second power supply active region 100N1 extends from the first region LS to the second region LD, and is located on a side of a plurality of N-type active regions away from a plurality of P-type active regions. The second power supply active region 100N1 is configured to be connected to a second power supply line formed subsequently.

In an exemplary implementation, the second power supply active region 100N1 may be located within a region where the deep N-well region 10 is located but outside a region where the N-well region 20 is located. An orthographic projection of the second power supply active region 100N1 on the silicon base substrate is located with a range of an orthographic projection of the deep N-well region 10 on the silicon base substrate, and the orthographic projection of the second power supply active region 100N1 on the silicon base substrate is not overlapped with an orthographic projection of the N-well region 20 on the silicon base substrate.

In an exemplary implementation, a shape of the ground active region 100N2 may be a strip shape extending along the first direction X, may be disposed in the first region LS, and may be located on a side of the first N-type active region 101N away from the first P-type active region 101P. The ground active region 100N2 is configured to be connected to a ground line formed subsequently.

In an exemplary implementation, the ground active region 100N2 may be located outside a region where the deep N-well region 10 and the N-well region 20 are located. An orthographic projection of the ground active region 100N2 on the silicon base substrate is not overlapped with the orthographic projection of the deep N-well region 10N on the silicon base substrate, and the orthographic projection of the ground active region 100N2 on the silicon base substrate is not overlapped with an orthographic projection of the N-well region 20 on the silicon base substrate.

In an exemplary implementation, in the first region LS, the first P-type active region 101P to the thirteenth P-type active region 113P may be disposed sequentially along the first direction X, and the first N-type active region 101N to the third N-type active region 103N may be disposed sequentially along the first direction X.

In an exemplary implementation, in the second region LD, the twenty-first P-type active region 121P to the thirtieth P-type active region 130P may be disposed sequentially along the first direction X, and the twenty-first N-type active region 121N to the thirtieth N-type active region 130N may be disposed sequentially along the first direction X.

In an exemplary implementation, there is a fourth distance S4 between an edge of the twenty-second P-type active region 122P on a side close to the twenty-third P-type active region 123P and an edge of the twenty-third P-type active region 123P on a side close to the twenty-second P-type active region 122P, there is a fourth distance S4 between an edge of the twenty-second N-type active region 122N on a side close to the twenty-third N-type active region 123N and an edge of the twenty-third N-type active region 123N on a side close to the twenty-second N-type active region 122N, and the fourth distance S4 may be greater than or equal to 0.36 μm.

In an exemplary implementation, there is a third distance S3 between an edge of the twenty-third P-type active region 123P on a side close to the twenty-fourth P-type active region 124P and an edge of the twenty-fourth P-type active region 124P on a side close to the twenty-third P-type active region 123P, there is a third distance S3 between an edge of the twenty-third N-type active region 123N on a side close to the twenty-fourth N-type active region 124N and an edge of the twenty-fourth N-type active region 124N on a side close to the twenty-third N-type active region 123N, and the third distance S3 may be greater than or equal to 0.36 μm.

In an exemplary implementation, there is a second distance S2 between an edge of the twenty-fifth P-type active region 125P on a side close to the twenty-sixth P-type active region 126P and an edge of the twenty-sixth P-type active region 126P on a side close to the twenty-fifth P-type active region 125P, there is a second distance S2 between an edge of the twenty-fifth N-type active region 125N on a side close to the twenty-sixth N-type active region 126N and an edge of the twenty-sixth N-type active region 126N on a side close to the twenty-fifth N-type active region 125N, and the second distance S2 may be greater than or equal to 0.36 μm.

In an exemplary implementation, the second distance S2 may be equal to the third distance S3, and the third distance S3 may be equal to the fourth distance S4.

In an exemplary implementation, there is a first distance S1 between an edge of the twenty-sixth P-type active region 126P on a side close to the twenty-seventh P-type active region 127P and an edge of the twenty-seventh P-type active region 127P on a side close to the twenty-sixth P-type active region 126P, there is a first distance S1 between an edge of the twenty-sixth N-type active region 126N on a side close to the twenty-seventh N-type active region 127N and an edge of the twenty-seventh N-type active region 127N on a side close to the twenty-sixth N-type active region 126N, the first distance S1 may be greater than the second distance S2, the first distance S1 may be greater than the third distance S3, and the first distance S1 may be greater than the fourth distance S4.

In an exemplary implementation, a ratio of the second distance S2 to the first distance S1 may be about 0.7 to 0.8.

In an exemplary implementation, the first distance S1 may be greater than or equal to 0.5 μm.

In an exemplary implementation, the twenty-first P-type active region 121P to the twenty-sixth P-type active region 126P and the twenty-first N-type active region 121N to the twenty-sixth N-type active region 126N are active layers of transistors in the first NAND gate 301, the second NAND gate 302, the first transmission gate 201, and the second inverter 402, respectively, and belong to a signal control circuit portion of the row driving enhancer, and the current in the circuit is small. In the present disclosure, by providing a minimum distance between active regions of the first NAND gate 301 and the first transmission gate 201, a minimum distance between active regions of the first transmission gate 201 and the second NAND gate 302, and a minimum distance between active regions of the second NAND gate 302 and the second inverter 402, the occupied space of the row driving enhancer may be effectively reduced, the length of the signal line may be reduced, and the input impedance may be reduced.

In an exemplary implementation, the twenty-seventh P-type active region 127 P to thirtieth P-type active region 130 P and the twenty-seventh N-type active region 127 N to thirtieth N-type active region 130 N are transistors of the third P-type transistor unit 503 P and the third N-type transistor unit 503 N, respectively, belong to a signal output circuit portion of the row driving enhancer, and require large current output. In the present disclosure, by providing a minimum distance between an active region of the transistors in the signal control circuit portion and an active region of the transistors in the signal output circuit portion, the mutual influence of the transistors in the signal control portion and the transistors in the signal output portion may be effectively reduced, improving the operation reliability and ensuring the signal control and the signal output.

In an exemplary implementation, a distance between the P-type active regions may be equivalent to a distance between the P-type transistors, and/or a distance between the N-type active regions may be equivalent to a distance between the N-type transistors.

In an exemplary implementation, a distance between the P-type transistors and/or a distance between the N-type transistors may be equivalent to a distance between transistor groups.

In an exemplary implementation, a plurality of N-type active regions may be located on a side of a plurality of P-type active regions in the second direction Y, forming a compact arrangement layout in which the plurality of N-type active regions are separated in the second direction Y (up and down) and disposed sequentially (in a strip shape) in the first direction X.

In an exemplary implementation, in the second direction Y, there may be a gap region 50 between a P-type active region and an N-type active region in one transistor group, and the gap region 50 is configured as an isolation region between the P-type transistor and the N-type transistor on the one hand, and is configured to accommodate a gate via hole connecting the gate conductive layer and the first conductive layer on the other hand, so as to optimize a structural layout of the gate driving circuit.

In an exemplary implementation, widths of the gap regions 50 in a portion of the transistor groups may be substantially the same, and widths of the gap regions 50 in the other portion of the transistor groups may be different, wherein the widths of the gap regions may be dimensions in the second direction Y.

In an embodiment of the present disclosure, widths of a plurality of gap regions 50 may be substantially the same, edges of a plurality of P-type active regions on a side close to the gap regions 50 may be substantially located on the same straight line extending along the first direction X, and edges of a plurality of N-type active regions on a side close to the gap regions 50 may be substantially located on the same straight line extending along the first direction X.

In an exemplary implementation, distances between P-type active regions and N-type active regions in one transistor group may be equivalent to distances between P-type transistors and N-type transistors in the transistor group, that is, the gap regions 50 may be gaps between P-type transistors and N-type transistors.

In an exemplary implementation, in one transistor group, P-type active regions may have a P-type active region width WP, and N-type active regions may have an N-type active region width WN. The P-type active region width WP may be a distance between an edge of a second P-type active region 102P on a side close to a power supply active region 100P and an edge of the second P-type active region 102P on a side away from the power supply active region 100P, the N-type active region width WN may be a distance between an edge of a second N-type active region 102N on a side close to a ground active region 100N2 (a second power supply active region 100N1) and an edge of the second N-type active region 102N on a side away from a ground active region 100N2 (the second power supply active region 100N1), and the P-type active region width WP and the N-type active region width WN may be dimensions in the second direction Y.

In an exemplary implementation, P-type active region widths in the first NAND gate and the second NAND gate may be substantially the same, and P-type active region widths in the first inverter and the second inverter may be substantially the same. N-type active region widths in the first NAND gate and the second NAND gate may be substantially the same, and N-type active region widths in the first inverter and the second inverter may be substantially the same.

In an exemplary implementation, P-type active region widths in the first NAND gate and the first inverter may be different, and N-type active region widths in the first NAND gate and the first inverter may be different.

In an exemplary implementation, the P-type active region widths in the first P-type transistor unit and the second P-type transistor unit may be substantially the same, but different from the P-type active region widths in the third P-type transistor unit. The N-type active region widths in the first N-type transistor unit and the second N-type transistor unit may be substantially the same, but different from the N-type active region widths in the third N-type transistor unit.

In an exemplary implementation, the P-type active region widths in the first P-type transistor unit and the second P-type transistor unit may be greater than the P-type active region widths in the first NAND gate and the second NAND gate, and the P-type active region widths in the first NAND gate and the second NAND gate may be greater than the P-type active region width in the first transmission gate. The P-type active region width in the first transmission gate may be greater than the P-type active region widths in the first inverter and the second inverter, and the P-type active region widths in the first inverter and the second inverter may be equal to the P-type active region width in the third P-type transistor unit.

In an exemplary implementation, the N-type active region width in the first transmission gate may be equal to the N-type active region width in the third N-type transistor unit, and the N-type active region width in the first transmission gate may be greater than the N-type active region widths in the first NAND gate and the second NAND gate. The N-type active region widths in the first NAND gate and the second NAND gate may be greater than the N-type active region widths in the first N-type transistor unit and the second N-type transistor unit, and the N-type active region widths in the first N-type transistor unit and the second N-type transistor unit may be greater than the N-type active region widths in the first inverter and the second inverter.

In an exemplary implementation, in the second direction Y, a dimension of the P-type active region in the first P-type transistor unit may be larger than a length of the P-type active region in the first inverter, i.e., a dimension of the P-type transistor in the first P-type transistor unit may be larger than a dimension of the P-type transistor in the first inverter.

In an exemplary implementation, in the second direction Y, a dimension of the P-type active region in the second P-type transistor unit may be larger than a length of the P-type active region in the first inverter, i.e., a dimension of the P-type transistor in the second P-type transistor unit may be larger than a dimension of the P-type transistor in the first inverter.

In an exemplary implementation, in the first NAND gate and the second NAND gate, a distance between the P-type active region and the power supply active region may be substantially equal to a distance between the N-type active region and the second power supply active region in the second direction Y.

In the present disclosure, by setting the positions of the P-type active region and the N-type active region, the shortest connection line between devices may be effectively ensured, which optimizes the layout design space, ensures that the resistance capacitance load (RC Loading) of the gate electrodes of the P-type transistor and the N-type transistor are basically consistent, and improves uniformity.

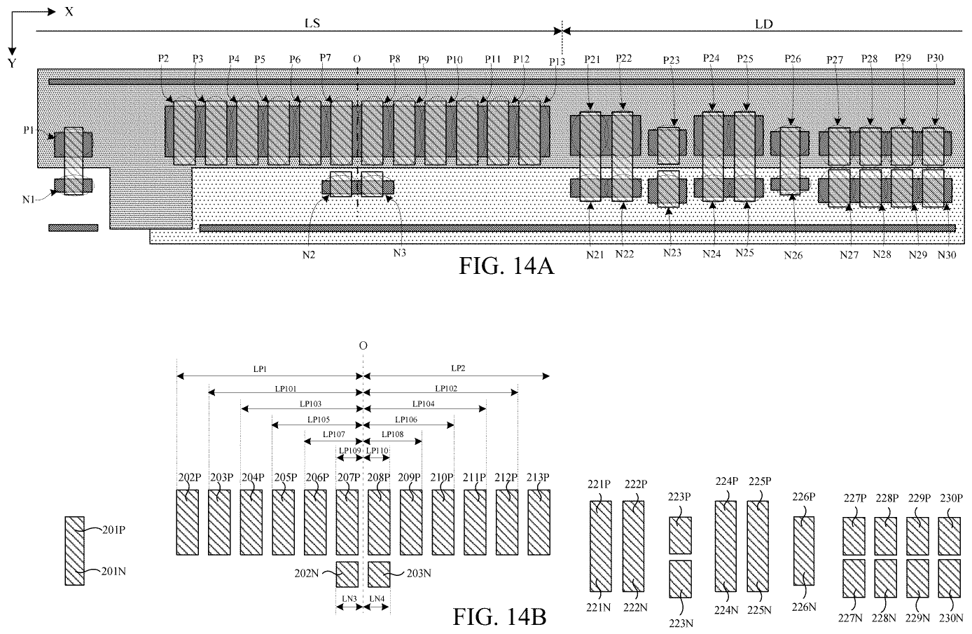

(3) A pattern of a gate conductive layer is formed. In an exemplary implementation, forming the pattern of the gate conductive layer may include: depositing a first insulation thin film and a polysilicon thin film in sequence on the silicon base substrate on which the aforementioned patterns are formed, first patterning the polysilicon thin film through a patterning processes to form a first insulation layer overlaying the silicon base substrate and a polysilicon layer disposed on the first insulation layer, and then performing a doping on the polysilicon layer to form a pattern of a gate conductive layer. As shown in FIG. 14A and FIG. 14B, FIG. 14B is a schematic diagram of the gate conductive layer in FIG. 14A.

In an exemplary implementation, the pattern of the gate conductive layer may at least include a first P-type gate electrode 201P to a thirteenth P-type gate electrode 213P, a twenty-first P-type gate electrode 221P to a thirtieth P-type gate electrode 230P, a first N-type gate electrode 201N to a third N-type gate electrode 203N, and a twenty-first N-type gate electrode 221N to a thirtieth N-type gate electrode 230N.

In an exemplary implementation, the first P-type gate electrode 201P to thirteenth P-type gate electrode 213P, and the first N-type gate electrode 201N to third N-type gate electrode 203N may be disposed in the first region LS, and the twenty-first P-type gate electrode 221P to thirtieth P-type gate electrode 230P, and the twenty-first N-type gate electrode 221N to thirtieth N-type gate electrode 230N may be disposed in the second region LD.

In an exemplary implementation, the first P-type gate electrode 201P may be in a shape of a strip extending in the second direction Y. An orthographic projection of the first P-type gate electrode 201P on the silicon base substrate is at least partially overlapped with an orthographic projection of the first P-type active region 101P on the silicon base substrate, and the first P-type gate electrode 201P may serve as a gate electrode of the first P-type transistor P1.

In an exemplary implementation, the first N-type gate electrode 201N may be in a shape of a strip extending in the second direction Y. An orthographic projection of the first N-type gate electrode 201N on the silicon base substrate is at least partially overlapped with the orthographic projection of the first N-type active region 101N on the silicon base substrate, and the first N-type gate electrode 201N may serve as a gate electrode of the first N-type transistor N1.

In an exemplary implementation, the first P-type gate electrode 201P and the first N-type gate electrode 201N may be of an integral structure connected to each other.

In an exemplary implementation, the second P-type gate electrode 202P may be in a shape of a strip extending in the second direction Y. An orthographic projection of the second P-type gate electrode 202P on the silicon base substrate is at least partially overlapped with an orthographic projection of the second P-type active region 102P on the silicon base substrate, and the second P-type gate electrode 202P may serve as a gate electrode of the second P-type transistor P2.

In an exemplary implementation, the third P-type gate electrode 203P may be in a shape of a strip extending in the second direction Y. An orthographic projection of the third P-type gate electrode 203P on the silicon base substrate is at least partially overlapped with an orthographic projection of the third P-type active region 103P on the silicon base substrate, and the third P-type gate electrode 203P may serve as a gate electrode of the third P-type transistor P3.

In an exemplary implementation, the fourth P-type gate electrode 204P may be in a shape of a strip extending in the second direction Y. An orthographic projection of the fourth P-type gate electrode 204P on the silicon base substrate is at least partially overlapped with an orthographic projection of the fourth P-type active region 104P on the silicon base substrate, and the fourth P-type gate electrode 204P may serve as a gate electrode of the fourth P-type transistor P4.

In an exemplary implementation, the fifth P-type gate electrode 205P may be in a shape of a strip extending in the second direction Y. An orthographic projection of the fifth P-type gate electrode 205P on the silicon base substrate is at least partially overlapped with an orthographic projection of the fifth P-type active region 105P on the silicon base substrate, and the fifth P-type gate electrode 205P may serve as a gate electrode of the fifth P-type transistor P5.

In an exemplary implementation, the sixth P-type gate electrode 206P may be in a shape of a strip extending in the second direction Y. An orthographic projection of the sixth P-type gate electrode 206P on the silicon base substrate is at least partially overlapped with an orthographic projection of the sixth P-type active region 106P on the silicon base substrate, and the sixth P-type gate electrode 206P may serve as a gate electrode of the sixth P-type transistor P6.

In an exemplary implementation, the seventh P-type gate electrode 207P may be in a shape of a strip extending in the second direction Y. An orthographic projection of the seventh P-type gate electrode 207P on the silicon base substrate is at least partially overlapped with an orthographic projection of the seventh P-type active region 107P on the silicon base substrate, and the seventh P-type gate electrode 207P may serve as a gate electrode of the seventh P-type transistor P7.

In an exemplary implementation, the eighth P-type gate electrode 208P may be in a shape of a strip extending in the second direction Y. An orthographic projection of the eighth P-type gate electrode 208P on the silicon base substrate is at least partially overlapped with an orthographic projection of the eighth P-type active region 108P on the silicon base substrate, and the eighth P-type gate electrode 208P may serve as a gate electrode of the eighth P-type transistor P8.

In an exemplary implementation, the ninth P-type gate electrode 209P may be in a shape of a strip extending in the second direction Y. An orthographic projection of the ninth P-type gate electrode 209P on the silicon base substrate is at least partially overlapped with an orthographic projection of the ninth P-type active region 108P on the silicon base substrate, and the ninth P-type gate electrode 209P may serve as a gate electrode of the ninth P-type transistor P9.

In an exemplary implementation, the tenth P-type gate electrode 210P may be in a shape of a strip extending in the second direction Y. An orthographic projection of the tenth P-type gate electrode 210P on the silicon base substrate is at least partially overlapped with an orthographic projection of the tenth P-type active region 110P on the silicon base substrate, and the tenth P-type gate electrode 210P may serve as a gate electrode of the tenth P-type transistor P10.

In an exemplary implementation, the eleventh P-type gate electrode 211P may be in a shape of a strip extending in the second direction Y. An orthographic projection of the eleventh P-type gate electrode 211P on the silicon base substrate is at least partially overlapped with an orthographic projection of the eleventh P-type active region 111P on the silicon base substrate, and the eleventh P-type gate electrode 211P may serve as a gate electrode of the eleventh P-type transistor P11.

In an exemplary implementation, the twelfth P-type gate electrode 212P may be in a shape of a strip extending in the second direction Y. An orthographic projection of the twelfth P-type gate electrode 212P on the silicon base substrate is at least partially overlapped with an orthographic projection of the twelfth P-type active region 112P on the silicon base substrate, and the twelfth P-type gate electrode 212P may serve as a gate electrode of the twelfth P-type transistor P12.

In an exemplary implementation, the thirteenth P-type gate electrode 213P may be in a shape of a strip extending in the second direction Y. An orthographic projection of the thirteenth P-type gate electrode 213P on the silicon base substrate is at least partially overlapped with an orthographic projection of the thirteenth P-type active region 113P on the silicon base substrate, and the thirteenth P-type gate electrode 213P may serve as a gate electrode of the thirteenth P-type transistor P13.

In an exemplary implementation, the second P-type gate electrode 202P to the thirteenth P-type gate electrode 213P may be disposed sequentially along the first direction X, and positions and shapes of a plurality of gate electrodes may be disposed symmetrically with respect to the active center line O.

In an exemplary implementation, the gate electrode of the second P-type transistor P2 to the gate electrode of the seventh P-type transistor P7 in the first P-type transistor unit and the gate electrode of the eighth P-type transistor P8 to the gate electrode of the thirteenth P-type transistor P13 in the second P-type transistor unit are disposed symmetrically with respect to the active center line O, which may ensure the symmetry of the P-type transistor units in the level converter and improve the consistency of outputting high and low levels.

In an exemplary implementation, a length of the second P-type gate electrode 202P and a length of the thirteenth P-type gate electrode 213P are equal, a width of the second P-type gate electrode 202P and a width of the thirteenth P-type gate electrode 213P are equal, and an overlapping area between the second P-type gate electrode 202P and the corresponding active region is equal to an overlapping area between the thirteenth P-type gate electrode 213P and the corresponding active region; and there is a first length LP1 between an edge of the second P-type gate electrode 202P on a side away from the active center line O and the active center line O, and there is a second length LP2 between an edge of the thirteenth P-type gate electrode 213P on a side away from the active center line O and the active center line O, and a ratio of the first length LP1 to the second length LP2 may be about 0.95 to 1.05. In an exemplary implementation, the length is a dimension in the second direction Y, and the width is a dimension in the first direction X.

In an exemplary implementation, the first length LP1 and the second length LP2 may be substantially equal.

In an exemplary implementation, a length of the third P-type gate electrode 203P and a length of the twelfth P-type gate electrode 212P are equal, a width of the third P-type gate electrode 203P and a width of the twelfth P-type gate electrode 212P are equal, and overlapping areas between the two gate electrodes and the corresponding active regions are equal; and there is a first sub-length LP101 between an edge of the third P-type gate electrode 203P on a side away from the active center line O and the active center line O, and there is a second sub-length LP102 between an edge of the twelfth P-type gate electrode 212P on a side away from the active center line O and the active center line O, and a ratio of the first sub-length LP101 to the second sub-length LP102 may be about 0.95 to 1.05.

In an exemplary implementation, the first sub-length LP 101 and the second sub-length LP 102 may be substantially equal.

In an exemplary implementation, a length of the fourth P-type gate electrode 204P and a length of the eleventh P-type gate electrode 211P are equal, a width of the fourth P-type gate electrode 204P and a width of the eleventh P-type gate electrode 211P are equal, and overlapping areas between the two gate electrodes and the corresponding active regions are equal; and there is a third sub-length LP103 between an edge of the fourth P-type gate electrode 204P on a side away from the active center line O and the active center line O, and there is a fourth sub-length LP104 between an edge of the eleventh P-type gate electrode 211P on a side away from the active center line O and the active center line O, and a ratio of the third length LP103 to the fourth length LP104 may be about 0.95 to 1.05.

In an exemplary implementation, the third sub-length LP103 and the fourth sub-length LP104 may be substantially equal.

In an exemplary implementation, a length of the fifth P-type gate electrode 205P and a length of the tenth P-type gate electrode 210P are equal, a width of the fifth P-type gate electrode 205P and a width of the tenth P-type gate electrode 210P are equal, and overlapping areas between the two gate electrodes and the corresponding active regions are equal; and there is a fifth sub-length LP105 between an edge of the fifth P-type gate electrode 205P on a side away from the active center line O and the active center line O, and there is a sixth sub-length LP106 between an edge of the tenth P-type gate electrode 210P on a side away from the active center line O and the active center line O, and a ratio of the fifth sub-length LP105 to the sixth sub-length LP106 may be about 0.95 to 1.05.

In an exemplary implementation, the fifth sub-length LP105 and the sixth sub-length LP106 may be substantially equal.

In an exemplary implementation, a length of the sixth P-type gate electrode 206P and a length of the ninth P-type gate electrode 209P are equal, a width of the sixth P-type gate electrode 206P and a width of the ninth P-type gate electrode 209P are equal, and overlapping areas between the two gate electrodes and the corresponding active regions are equal; and there is a seventh length LP107 between an edge of the sixth P-type gate electrode 206P on a side away from the active center line O and the active center line O, and there is an eighth sub-length LP108 between an edge of the ninth P-type gate electrode 209P on a side away from the active center line O and the active center line O, and a ratio of the seventh length LP107 to the eighth length LP108 may be about 0.95 to 1.05.

In an exemplary implementation, the seventh sub-length LP107 and the eighth sub-length LP108 may be substantially equal.

In an exemplary implementation, a length of the seventh P-type gate electrode 207P and a length of the eighth P-type gate electrode 208P are equal, a width of the seventh P-type gate electrode 207P and a width of the eighth P-type gate electrode 208P are equal, and overlapping areas between the two gate electrodes and the corresponding active regions are equal; and there is a ninth sub-length LP109 between an edge of the seventh P-type gate electrode 207P on a side away from the active center line O and the active center line O, and there is a tenth sub-length LP110 between an edge of the eighth P-type gate electrode 208P on a side away from the active center line O and the active center line O, and a ratio of the ninth sub-length LP109 to the tenth sub-length LP110 may be about 0.95 to 1.05.

In an exemplary implementation, the ninth sub-length LP109 and the tenth sub-length LP110 may be substantially equal.

In an exemplary implementation, the second N-type gate electrode 202N may be in a shape of a strip extending in the second direction Y. An orthographic projection of the second N-type gate electrode 202N on the silicon base substrate is at least partially overlapped with the orthographic projection of the second N-type active region 102N on the silicon base substrate, and the second N-type gate electrode 202N may serve as a gate electrode of the second N-type transistor N2.

In an exemplary implementation, the third N-type gate electrode 203N may be in a shape of a strip extending in the second direction Y. An orthographic projection of the third N-type gate electrode 203N on the silicon base substrate is at least partially overlapped with the orthographic projection of the third N-type active region 103N on the silicon base substrate, and the third N-type gate electrode 203N may serve as a gate electrode of the third N-type transistor N3.

In an exemplary implementation, the second N-type gate electrode 202N and the third N-type gate electrode 203N may be disposed sequentially along the first direction X, and the two gate electrodes may be disposed symmetrically with respect to the active center line O.

In an exemplary implementation, the gate electrode of the second N-type transistor N2 in the first N-type transistor unit and the gate electrode of the third N-type transistor N3 in the second N-type transistor unit are symmetrically disposed with respect to the active center line O, which may ensure the symmetry of the N-type transistor unit in the level converter and improve the consistency of outputting high and low levels.

In an exemplary implementation, a length of the second N-type gate electrode 202N and a length of the third N-type gate electrode 203N are equal, a width of the second N-type gate electrode 202N and a width of the third N-type gate electrode 203N are equal, and overlapping areas between the two gate electrodes and the corresponding active regions are equal; and there is a third length LN3 between an edge of the second N-type gate electrode 202N on a side away from the active center line O and the active center line O, and there is a fourth length LN4 between an edge of the third N-type gate electrode 203N on a side away from the active center line O and the active center line O, and a ratio of the third length LN3 to the fourth length LN4 may be about 0.95 to 1.05.

In an exemplary implementation, the third length LN3 and the fourth length LN4 may be substantially equal.

In an exemplary implementation, the twenty-first P-type gate electrode 221P may be in a shape of a strip extending in the second direction Y. An orthographic projection of the twenty-first P-type gate electrode 221P on the silicon base substrate is at least partially overlapped with an orthographic projection of the twenty-first P-type active region 121P on the silicon base substrate, and the twenty-first P-type gate electrode 221P may serve as a gate electrode of the twenty-first P-type transistor P21.

In an exemplary implementation, the twenty-first N-type gate electrode 221N may be in a shape of a strip extending in the second direction Y. An orthographic projection of the twenty-first N-type gate electrode 221N on the silicon base substrate is at least partially overlapped with the orthographic projection of the twenty-first N-type active region 121N on the silicon base substrate, and the twenty-first N-type gate electrode 221N may serve as a gate electrode of the twenty-first N-type transistor N21.

In an exemplary implementation, the twenty-first P-type gate electrode 221P and the twenty-first N-type gate electrode 221N may be of an integral structure connected to each other.

In an exemplary implementation, the twenty-second P-type gate electrode 222P may be in a shape of a strip extending in the second direction Y. An orthographic projection of the twenty-second P-type gate electrode 222P on the silicon base substrate is at least partially overlapped with an orthographic projection of the twenty-second P-type active region 122P on the silicon base substrate, and the twenty-second P-type gate electrode 222P may serve as a gate electrode of the twenty-second P-type transistor P22.

In an exemplary implementation, the twenty-second N-type gate electrode 222N may be in a shape of a strip extending in the second direction Y. An orthographic projection of the twenty-second N-type gate electrode 222N on the silicon base substrate is at least partially overlapped with the orthographic projection of the twenty-second N-type active region 122N on the silicon base substrate, and the twenty-second N-type gate electrode 222N may serve as a gate electrode of the twenty-second N-type transistor N22.

In an exemplary implementation, the twenty-second P-type gate electrode 222P and the twenty-second N-type gate electrode 222N may be of an integral structure connected to each other.

In an exemplary implementation, the twenty-third P-type gate electrode 223P may be in a shape of a strip extending in the second direction Y. An orthographic projection of the twenty-third P-type gate electrode 223P on the silicon base substrate is at least partially overlapped with an orthographic projection of the twenty-third P-type active region 123P on the silicon base substrate, and the twenty-third P-type gate electrode 223P may serve as a gate electrode of the twenty-third P-type transistor P23.

In an exemplary implementation, the twenty-third N-type gate electrode 223N may be in a shape of a strip extending in the second direction Y. An orthographic projection of the twenty-third N-type gate electrode 223N on the silicon base substrate is at least partially overlapped with the orthographic projection of the twenty-third N-type active region 123N on the silicon base substrate, and the twenty-third N-type gate electrode 201N may serve as a gate electrode of the twenty-third N-type transistor N23.

In an exemplary implementation, the twenty-fourth P-type gate electrode 224P may be in a shape of a strip extending in the second direction Y. An orthographic projection of the twenty-fourth P-type gate electrode 224P on the silicon base substrate is at least partially overlapped with an orthographic projection of the twenty-fourth P-type active region 124P on the silicon base substrate, and the twenty-fourth P-type gate electrode 224P may serve as a gate electrode of the twenty-fourth P-type transistor P24.

In an exemplary implementation, the twenty-fourth N-type gate electrode 224N may be in a shape of a strip extending in the second direction Y. An orthographic projection of the twenty-fourth N-type gate electrode 224N on the silicon base substrate is at least partially overlapped with the orthographic projection of the twenty-fourth N-type active region 124N on the silicon base substrate, and the twenty-fourth N-type gate electrode 224N may serve as a gate electrode of the twenty-fourth N-type transistor N24.

In an exemplary implementation, the twenty-fourth P-type gate electrode 224P and the twenty-fourth N-type gate electrode 224N may be of an integral structure connected to each other.

In an exemplary implementation, the twenty-fifth P-type gate electrode 225P may be in a shape of a strip extending in the second direction Y. An orthographic projection of the twenty-fifth P-type gate electrode 225P on the silicon base substrate is at least partially overlapped with an orthographic projection of the twenty-fifth P-type active region 125P on the silicon base substrate, and the twenty-fifth P-type gate electrode 225P may serve as a gate electrode of the twenty-fifth P-type transistor P22.

In an exemplary implementation, the twenty-fifth N-type gate electrode 225N may be in a shape of a strip extending in the second direction Y. An orthographic projection of the twenty-fifth N-type gate electrode 225N on the silicon base substrate is at least partially overlapped with the orthographic projection of the twenty-fifth N-type active region 125N on the silicon base substrate, and the twenty-fifth N-type gate electrode 225N may serve as a gate electrode of the twenty-fifth N-type transistor N22.

In an exemplary implementation, the twenty-fifth P-type gate electrode 225P and the twenty-fifth N-type gate electrode 225N may be of an integral structure connected to each other.

In an exemplary implementation, the twenty-sixth P-type gate electrode 226P may be in a shape of a strip extending in the second direction Y. An orthographic projection of the twenty-sixth P-type gate electrode 226P on the silicon base substrate is at least partially overlapped with an orthographic projection of the twenty-sixth P-type active region 126P on the silicon base substrate, and the twenty-sixth P-type gate electrode 226P may serve as a gate electrode of the twenty-sixth P-type transistor P26.

In an exemplary implementation, the twenty-sixth N-type gate electrode 226N may be in a shape of a strip extending in the second direction Y. An orthographic projection of the twenty-sixth N-type gate electrode 226N on the silicon base substrate is at least partially overlapped with the orthographic projection of the twenty-sixth N-type active region 126N on the silicon base substrate, and the twenty-sixth N-type gate electrode 226N may serve as a gate electrode of the twenty-sixth N-type transistor N26.

In an exemplary implementation, the twenty-sixth P-type gate electrode 226P and the twenty-sixth N-type gate electrode 226N may be of an integral structure connected to each other.

In an exemplary implementation, the twenty-seventh P-type gate electrode 227P may be in a shape of a strip extending in the second direction Y. An orthographic projection of the twenty-seventh P-type gate electrode 227P on the silicon base substrate is at least partially overlapped with an orthographic projection of the twenty-seventh P-type active region 127P on the silicon base substrate, and the twenty-seventh P-type gate electrode 227P may serve as a gate electrode of the twenty-seventh P-type transistor P27.

In an exemplary implementation, the twenty-seventh N-type gate electrode 227N may be in a shape of a strip extending in the second direction Y. An orthographic projection of the twenty-seventh N-type gate electrode 227N on the silicon base substrate is at least partially overlapped with the orthographic projection of the twenty-seventh N-type active region 127N on the silicon base substrate, and the twenty-seventh N-type gate electrode 227N may serve as a gate electrode of the twenty-seventh N-type transistor N27.

In an exemplary implementation, the twenty-eighth P-type gate electrode 228P may be in a shape of a strip extending in the second direction Y. An orthographic projection of the twenty-eighth P-type gate electrode 228P on the silicon base substrate is at least partially overlapped with an orthographic projection of the twenty-eighth P-type active region 128P on the silicon base substrate, and the twenty-eighth P-type gate electrode 228P may serve as a gate electrode of the twenty-eighth P-type transistor P28.

In an exemplary implementation, the twenty-eighth N-type gate electrode 228N may be in a shape of a strip extending in the second direction Y. An orthographic projection of the twenty-eighth N-type gate electrode 228N on the silicon base substrate is at least partially overlapped with the orthographic projection of the twenty-eighth N-type active region 128N on the silicon base substrate, and the twenty-eighth N-type gate electrode 228N may serve as a gate electrode of the twenty-eighth N-type transistor N28.

In an exemplary implementation, the twenty-ninth P-type gate electrode 229P may be in a shape of a strip extending in the second direction Y. An orthographic projection of the twenty-ninth P-type gate electrode 229P on the silicon base substrate is at least partially overlapped with an orthographic projection of the twenty-ninth P-type active region 129P on the silicon base substrate, and the twenty-ninth P-type gate electrode 229P may serve as a gate electrode of the twenty-ninth P-type transistor P29.

In an exemplary implementation, the twenty-ninth N-type gate electrode 229N may be in a shape of a strip extending in the second direction Y. An orthographic projection of the twenty-ninth N-type gate electrode 229N on the silicon base substrate is at least partially overlapped with the orthographic projection of the twenty-ninth N-type active region 129N on the silicon base substrate, and the twenty-ninth N-type gate electrode 229N may serve as a gate electrode of the twenty-ninth N-type transistor N29.

In an exemplary implementation, the thirtieth P-type gate electrode 230P may be in a shape of a strip extending in the second direction Y. An orthographic projection of the thirtieth P-type gate electrode 230P on the silicon base substrate is at least partially overlapped with an orthographic projection of the thirtieth P-type active region 130P on the silicon base substrate, and the thirtieth P-type gate electrode 230P may serve as a gate electrode of the thirtieth P-type transistor P30.

In an exemplary implementation, the thirtieth N-type gate electrode 230N may be in a shape of a strip extending in the second direction Y. An orthographic projection of the thirtieth N-type gate electrode 230N on the silicon base substrate is at least partially overlapped with the orthographic projection of the thirtieth N-type active region 130N on the silicon base substrate, and the thirtieth N-type gate electrode 230N may serve as a gate electrode of the thirtieth N-type transistor N30.

In an exemplary implementation, the twenty-first P-type gate electrode 221P to the thirtieth P-type gate electrode 230P may be disposed sequentially along the first direction X, and the twenty-first N-type gate electrode 221N to the thirtieth N-type gate electrode 230N may be disposed sequentially along the first direction X.

In an exemplary implementation, widths of the twenty-first P-type gate electrode 221P to the thirtieth P-type gate electrode 230P are substantially equal, and widths of the twenty-first N-type gate electrode 221N to the thirtieth N-type gate electrode 230N are substantially equal.

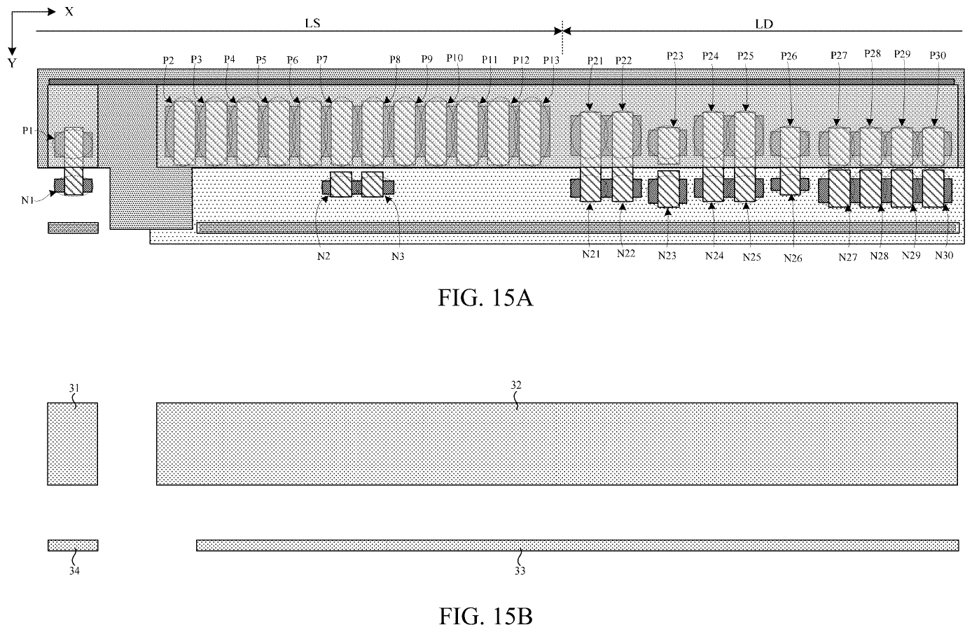

(4) A pattern of a P-type doped (SP) region is formed. In an exemplary implementation, forming the pattern of the P-type doped region may include: coating a photoresist on the silicon base substrate on which the aforementioned patterns are formed, forming a plurality of opening regions through exposure and development, and removing the photoresist within the plurality of opening regions to form a plurality of P-type doped regions within the opening regions through a doping process. As shown in FIG. 15A and FIG. 15B, FIG. 15B is a schematic diagram of the P-type doped region in FIG. 15A.

In an exemplary implementation, the plurality of P-type doped regions may at least include a first P-type doped region 31, a second P-type doped region 32, a third P-type doped region 33, and a fourth P-type doped region 34.

In an exemplary implementation, the first P-type doped region 31 may be disposed in the first region LS and located outside a region where the deep N-well region 10 is located, but within a region where the N-well region 20 is located. An orthographic projection of the first P-type doped region 31 on the silicon base substrate contains an orthographic projection of the first P-type active region 101P on the silicon base substrate, such that the first P-type active regions 101P located on both sides of the first P-type gate electrode 201P in the first direction X form a first P-type source region and a first P-type drain region of the first P-type transistor P1, respectively.

In an exemplary implementation, the second P-type doped region 32 may be disposed in the first region LS and the second region LD, that is, the second P-type doped region 32 extends from the first region LS to the second region LD and is located within regions where the deep N-well region 10 and the N-well region 20 are located. An orthographic projection of the second P-type doped region 32 on the silicon base substrate contains orthographic projections of the second P-type active region 102P to the thirteenth P-type active region 113P and the twenty-first P-type active region 121P to the thirtieth P-type active region 130P on the silicon base substrate, such that active regions located on both sides of a plurality of P-type gate electrodes in the first direction X form a plurality of P-type source regions and a plurality of P-type drain regions, respectively.

In an exemplary implementation, an active region between two P-type gate electrodes adjacent to each other in the first direction X may serve as P-type source regions of two P-type transistors, or may serve as P-type drain regions of two P-type transistors, or may serve as a P-type source region of one P-type transistor and a P-type drain region of another P-type transistor.

In an exemplary implementation, the P-type source region and the P-type drain region of each P-type transistor are P-type heavily doped regions P+.

In an exemplary implementation, the third P-type doped region 33 may be disposed in the first region LS and the second region LD, that is, the second P-type doped region 32 extends from the first region LS to the second region LD, and is located within a region where the deep N-well region 10 is located, but outside a region where the N-well region 20 is located. An orthographic projection of the third P-type doped region 33 on the silicon base substrate contains an orthographic projection of the second power supply active region 100N1 on the silicon base substrate.

In an exemplary implementation, the fourth P-type doped region 34 may be disposed in the first region LS and located outside regions where the deep N-well region 10 and the N-well region 20 are located. An orthographic projection of the fourth P-type doped region 34 on the silicon base substrate contains an orthographic projection of the ground active region 100N2 on the silicon base substrate.

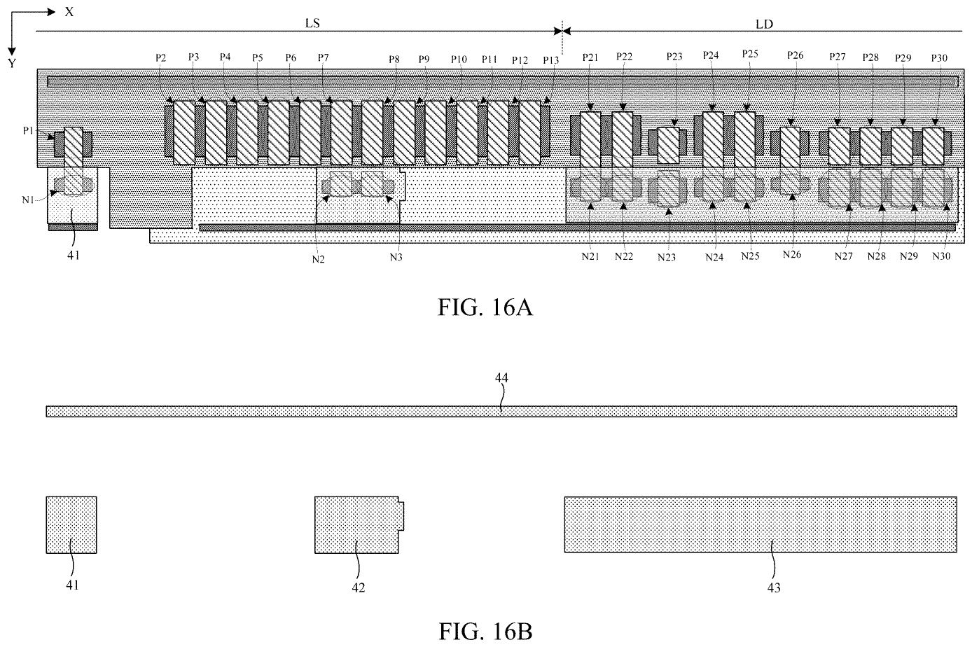

(5) A pattern of an N-type doped (SN) region is formed. In an exemplary implementation, forming the pattern of the N-type doped region may include: coating a photoresist on the silicon base substrate on which the aforementioned patterns are formed, forming a plurality of opening regions through exposure and development, and removing the photoresist within the plurality of opening regions to form a plurality of N-type doped regions within the opening regions through a doping process. As shown in FIG. 16A and FIG. 16B, FIG. 16B is a schematic diagram of the N-type doped region in FIG. 16A.

In an exemplary implementation, the plurality of N-type doped regions may at least include a first N-type doped region 41, a second N-type doped region 42, a third N-type doped region 43, and a fourth N-type doped region 44.

In an exemplary implementation, the first N-type doped region 41 may be disposed in the first region LS and located outside regions where the deep N-well region 10 and the N-well region 20 are located. An orthographic projection of the first N-type doped region 41 on the silicon base substrate contains an orthographic projection of the first N-type active region 101N on the silicon base substrate, such that the first N-type active regions 101N located on both sides of the first N-type gate electrode 201N in the first direction X form a first N-type source region and a first N-type drain region of the first N-type transistor N1, respectively.

In an exemplary implementation, the second N-type doped region 42 may be disposed in the first region LS and located within a region where the deep N-well region 10 is located but outside a region where the N-well region 20 is located. An orthographic projection of the second N-type doped region 42 on the silicon base substrate contains orthographic projections of the second N-type active region 102N and the third N-type active region 103N on the silicon base substrate, such that active regions located on both sides of the second N-type gate electrode 202N and the third N-type gate electrode 203N in the first direction X form an N-type source region and an N-type drain region.

In an exemplary implementation, the third N-type doped region 43 may be disposed in the second region LD and located within a region where the deep N-well region 10 is located but outside a region where the N-well region 20 is located. An orthographic projection of the third N-type doped region 43 on the silicon base substrate contains orthographic projections of the twenty-first N-type active region 121N to the thirtieth N-type active region 130N on the silicon base substrate, such that active regions located on both sides of a plurality of N-type gate electrodes in the first direction X form a plurality of N-type source regions and a plurality of N-type drain regions, respectively.

In an exemplary implementation, an active region between two N-type gate electrodes adjacent to each other in the first direction X may serve as N-type source regions of two N-type transistors, or may serve as N-type drain regions of two N-type transistors, or may serve as a N-type source region of one N-type transistor and a N-type drain region of another N-type transistor.

In an exemplary implementation, the N-type source region and the N-type drain region of each N-type transistor are N-type heavily doped regions N+.

In an exemplary implementation, the fourth N-type doped region 44 may be disposed in the first region LS and the second region LD, that is, the fourth N-type doped region 44 extends from the first region LS to the second region LD, and is located outside a region where the deep N-well region 10 is located, but within a region where the N-well region 20 is located. An orthographic projection of the fourth P-type doped region 44 on the silicon base substrate contains an orthographic projection of the first power supply active region 100P on the silicon base substrate.

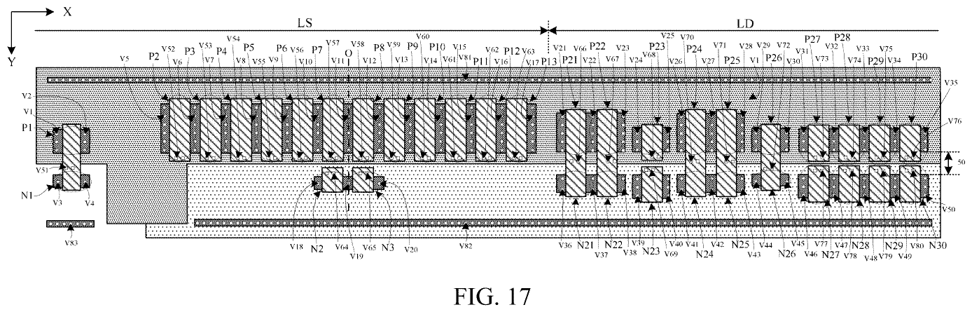

(6) A pattern of a second insulation layer is formed. In an exemplary implementation, forming the pattern of the second insulation layer may include: depositing a second insulation thin film on the silicon base substrate on which the aforementioned patterns are formed, and patterning the second insulation thin film through a patterning process to form the second insulation layer covering the pattern of the gate conductive layer. A plurality of via holes are disposed on the second insulation layer, as shown in FIG. 17.

In an exemplary implementation, the plurality of via holes may at least include a first via hole V1 to an eighty-third via hole V83.

In an exemplary implementation, an orthographic projection of the first via hole V1 on the silicon base substrate may be located within a range of an orthographic projection of the first P-type source region of the first P-type transistor P1 on the silicon base substrate. The first insulation layer and the second insulation layer in the first via hole V1 are etched away to expose a surface of the first P-type source region, and the first via hole V1 is configured such that a sixteenth connection electrode formed subsequently is connected with the first P-type source region through the first via hole.

In an exemplary implementation, an orthographic projection of the second via hole V2 on the silicon base substrate may be located within a range of an orthographic projection of the first P-type drain region of the first P-type transistor P1 on the silicon base substrate. The first insulation layer and the second insulation layer within the second via hole V2 are etched away to expose a surface of the first P-type drain region, and the second via hole V2 is configured such that a seventeenth connection electrode formed subsequently is connected with the first P-type drain region through the second via hole.

In an exemplary implementation, an orthographic projection of the third via hole V3 on the silicon base substrate may be located within a range of an orthographic projection of the first N-type source region of the first N-type transistor N1 on the silicon base substrate. The first insulation layer and the second insulation layer within the third via hole V3 are etched away to expose a surface of the first N-type source region, and the third via hole V3 is configured such that an eighteenth connection electrode formed subsequently is connected with the first N-type source region through the third via hole.

In an exemplary implementation, an orthographic projection of the fourth via hole V4 on the silicon base substrate may be located within a range of an orthographic projection of the first N-type drain region of the first N-type transistor N1 on the silicon base substrate. The first insulation layer and the second insulation layer within the fourth via hole V4 are etched away to expose a surface of the first N-type drain region, and the fourth via hole V4 is configured such that a seventeenth connection electrode formed subsequently is connected with the first N-type drain region through the fourth via hole.

In an exemplary implementation, an orthographic projection of the fifth via hole V5 on the silicon base substrate may be located within a range of an orthographic projection of the second P-type source region of the second P-type transistor P2 on the silicon base substrate. The first insulation layer and the second insulation layer in the fifth via hole V5 are etched away to expose a surface of the second P-type source region, and the fifth via hole V5 is configured such that a nineteenth connection electrode formed subsequently is connected with the second P-type source region through the fifth via hole.

In an exemplary implementation, an orthographic projection of the sixth via hole V6 on the silicon base substrate may be located within a range of an orthographic projection of the second P-type drain region of the second P-type transistor P2 (also the third P-type drain region of the third P-type transistor P3) on the silicon base substrate. The first insulation layer and the second insulation layer within the sixth via hole V6 are etched away to expose a surface of the second P-type drain region (also the third P-type drain region), and the sixth via hole V6 is configured such that a twentieth connection electrode formed subsequently is connected to the second P-type drain region (also the third P-type drain region) through the sixth via hole.

In an exemplary implementation, an orthographic projection of the seventh via hole V7 on the silicon base substrate may be located within a range of an orthographic projection of the third P-type source region of the third P-type transistor P3 (also the fourth P-type source region of the fourth P-type transistor P4) on the silicon base substrate. The first insulation layer and the second insulation layer within the seventh via hole V7 are etched away to expose a surface of the third P-type source region (also the fourth P-type source region), and the seventh via hole V7 is configured such that a twenty-first connection electrode formed subsequently is connected to the third P-type source region (also the fourth P-type source region) through the seventh via hole.

In an exemplary implementation, an orthographic projection of the eighth via hole V8 on the silicon base substrate may be located within a range of an orthographic projection of the fourth P-type drain region of the fourth P-type transistor P4 (also the fifth P-type drain region of the fifth P-type transistor P5) on the silicon base substrate. The first insulation layer and the second insulation layer within the eighth via hole V8 are etched away to expose a surface of the fourth P-type drain region (also the fifth P-type drain region), and the eighth via hole V8 is configured such that a twenty-second connection electrode formed subsequently is connected to the fourth P-type drain region (also the fifth P-type drain region) through the eighth via hole.

In an exemplary implementation, an orthographic projection of the ninth via hole V9 on the silicon base substrate may be located within a range of an orthographic projection of the fifth P-type source region of the fifth P-type transistor P5 (also the sixth P-type source region of the sixth P-type transistor P6) on the silicon base substrate. The first insulation layer and the second insulation layer within the ninth via hole V9 are etched away to expose a surface of the fifth P-type source region (also the sixth P-type source region), and the ninth via hole V9 is configured such that a twenty-third connection electrode formed subsequently is connected to the fifth P-type source region (also the sixth P-type source region) through the ninth via hole.

In an exemplary implementation, an orthographic projection of the tenth via hole V10 on the silicon base substrate may be located within a range of an orthographic projection of the sixth P-type drain region of the sixth P-type transistor P6 (also the seventh P-type drain region of the seventh P-type transistor P7) on the silicon base substrate. The first insulation layer and the second insulation layer within the tenth via hole V10 are etched away to expose a surface of the sixth P-type drain region (also the seventh P-type drain region), and the tenth via hole V10 is configured such that a twenty-fourth connection electrode formed subsequently is connected to the sixth P-type drain region (also the seventh P-type drain region) through the tenth via hole.

In an exemplary implementation, an orthographic projection of the eleventh via hole V11 on the silicon base substrate may be located within a range of an orthographic projection of the seventh P-type source region of the seventh P-type transistor P7 (also the eighth P-type source region of the eighth P-type transistor P8) on the silicon base substrate. The first insulation layer and the second insulation layer within the eleventh via hole V11 are etched away to expose a surface of the seventh P-type source region (also the eighth P-type source region), and the eleventh via hole V11 is configured such that a twenty-fifth connection electrode formed subsequently is connected to the seventh P-type source region (also the eighth P-type source region) through the eleventh via hole.

In an exemplary implementation, an orthographic projection of the twelfth via hole V12 on the silicon base substrate may be within a range of an orthographic projection of the eighth P-type drain region of the eighth P-type transistor P8 (also the ninth P-type drain region of the ninth P-type transistor P9) on the silicon base substrate. The first insulation layer and the second insulation layer within the twelfth via hole V12 are etched away to expose a surface of the eighth P-type drain region (also the ninth P-type drain region), and the twelfth via hole V12 is configured such that a twenty-sixth connection electrode formed subsequently is connected to the eighth P-type drain region (also the ninth P-type drain region) through the twelfth via hole.

In an exemplary implementation, an orthographic projection of the thirteenth via hole V13 on the silicon base substrate may be located within a range of an orthographic projection of the ninth P-type source region of the ninth P-type transistor P9 (also the tenth P-type source region of the tenth P-type transistor P10) on the silicon base substrate. The first insulation layer and the second insulation layer within the thirteenth via hole V13 are etched away to expose a surface of the ninth P-type source region (also the tenth P-type source region), and the thirteenth via hole V13 is configured such that a twenty-seventh connection electrode formed subsequently is connected to the ninth P-type source region (also the tenth P-type source region) through the thirteenth via hole.

In an exemplary implementation, an orthographic projection of the fourteenth via hole V14 on the silicon base substrate may be located within a range of an orthographic projection of the tenth P-type drain region of the tenth P-type transistor P10 (also the eleventh P-type drain region of the eleventh P-type transistor P11) on the silicon base substrate. The first insulation layer and the second insulation layer within the fourteenth via hole V14 are etched away to expose a surface of the tenth P-type drain region (also the eleventh P-type drain region), and the fourteenth via hole V14 is configured such that a twenty-eighth connection electrode formed subsequently is connected to the tenth P-type drain region (also the eleventh P-type drain region) through the fourteenth via hole.

In an exemplary implementation, an orthographic projection of the fifteenth via hole V15 on the silicon base substrate may be located within a range of an orthographic projection of the eleventh P-type source region of the eleventh P-type transistor P11 (also the twelfth P-type source region of the twelfth P-type transistor P12) on the silicon base substrate. The first insulation layer and the second insulation layer within the fifteenth via hole V15 are etched away to expose a surface of the eleventh P-type source region (also the twelfth P-type source region), and the fifteenth via hole V15 is configured such that a twenty-ninth connection electrode formed subsequently is connected to the eleventh P-type source region (also the twelfth P-type source region) through the fifteenth via hole.

In an exemplary implementation, an orthographic projection of the sixteenth via hole V16 on the silicon base substrate may be located within a range of an orthographic projection of the twelfth P-type drain region of the twelfth P-type transistor P12 (also the thirteenth P-type drain region of the thirteenth P-type transistor P13) on the silicon base substrate. The first insulation layer and the second insulation layer within the sixteenth via hole V16 are etched away to expose a surface of the twelfth P-type drain region (also the thirteenth P-type drain region), and the sixteenth via hole V16 is configured such that a thirtieth connection electrode formed subsequently is connected to the twelfth P-type drain region (also the thirteenth P-type drain region) through the sixteenth via hole.

In an exemplary implementation, an orthographic projection of the seventeenth via hole V17 on the silicon base substrate may be located within a range of an orthographic projection of the thirteenth P-type source region of the thirteenth P-type transistor P13 on the silicon base substrate. The first insulation layer and the second insulation layer in the seventeenth via hole V17 are etched away to expose a surface of the seventeenth P-type source region, and the seventeenth via hole V17 is configured such that a thirty-first connection electrode formed subsequently is connected with the seventeenth P-type source region through the seventeenth via hole.

In an exemplary implementation, a position of the fifth via hole V5 and a position of the seventeenth via hole V17 may be symmetrically disposed with respect to the active center line O, a position of the sixth via hole V6 and a position of the sixteenth via hole V16 may be symmetrically disposed with respect to the active center line O, a position of the seventh via hole V7 and a position of the fifteenth via hole V15 may be symmetrically disposed with respect to the active center line O, a position of the eighth via hole V8 and a position of the fourteenth via hole V14 may be symmetrically disposed with respect to the active center line O, a position of the ninth via hole V9 and a position of the thirteenth via hole V13 may be symmetrically disposed with respect to the active center line O, a position of the tenth via hole V10 and a position of the twelfth via hole V12 may be symmetrically disposed with respect to the active center line O, and a position of the eleventh via hole V11 may be symmetrically disposed with respect to the active center line O, which may ensure the symmetry of the P-type transistor units in the level converter and improve the consistency of outputting high and low levels.

In an exemplary implementation, an orthographic projection of the eighteenth via hole V18 on the silicon base substrate may be located within a range of an orthographic projection of the second N-type drain region of the second N-type transistor N2 on the silicon base substrate. The first insulation layer and the second insulation layer within the eighteenth via hole V18 are etched away to expose a surface of the second N-type drain region. The eleventh via hole V18 is configured such that a thirty-second connection electrode formed subsequently is connected with the second N-type drain region through the eighteenth via hole.

In an exemplary implementation, an orthographic projection of the nineteenth via hole V19 on the silicon base substrate may be located within a range of an orthographic projection of the second N-type source region of the second N-type transistor N2 (also the third N-type source region of the third N-type transistor N3) on the silicon base substrate. The first insulation layer and the second insulation layer within the nineteenth via hole V19 are etched away to expose a surface of the second N-type source region (also the third N-type source region), and the nineteenth via hole V19 is configured such that a thirty-third connection electrode formed subsequently is connected to the second N-type source region (also the third N-type source region) through the nineteenth via hole.

In an exemplary implementation, an orthographic projection of the twentieth via hole V20 on the silicon base substrate may be located within a range of an orthographic projection of the third N-type drain region of the third N-type transistor N3 on the silicon base substrate. The first insulation layer and the second insulation layer within the twentieth via hole V20 are etched away to expose a surface of the third N-type drain region, and the twentieth via hole V20 is configured such that a thirty-fourth connection electrode subsequently formed is connected to the third N-type drain region through the twentieth via hole.

In an exemplary implementation, a position of the eighteenth via hole V18 and a position of the twentieth via hole V20 may be symmetrically disposed with respect to the active center line O, and a position of the nineteenth via hole V19 may be symmetrically disposed with respect to the active center line O, which can ensure the symmetry of the N-type transistor unit in the level converter and improve the consistency of outputting high and low levels.

In an exemplary implementation, an orthographic projection of the twenty-first via hole V21 on the silicon base substrate may be located within a range of an orthographic projection of the twenty-first P-type source region of the twenty-first P-type transistor P21 on the silicon base substrate. The first insulation layer and the second insulation layer within the twenty-first via hole V21 are etched away to expose a surface of the twenty-first P-type source region, and the twenty-first via hole V21 is configured such that a forty-fourth connection electrode formed subsequently is connected with the twenty-first P-type source region through the twenty-first via hole.

In an exemplary implementation, an orthographic projection of the twenty-second via hole V22 on the silicon base substrate may be located within a range of an orthographic projection of the twenty-first P-type drain region of the twenty-first P-type transistor P21 (also the twenty-second P-type drain region of the twenty-second P-type transistor P22) on the silicon base substrate. The first insulation layer and the second insulation layer within the twenty-second via hole V22 are etched away to expose a surface of the twenty-first P-type drain region (also the twenty-second P-type drain region), and the twenty-second via hole V22 is configured such that a forty-fifth connection electrode formed subsequently is connected to the twenty-first P-type drain region (also the twenty-second P-type drain region) through the twenty-second via hole.

In an exemplary implementation, an orthographic projection of the twenty-third via hole V23 on the silicon base substrate may be located within a range of an orthographic projection of the twenty-second P-type source region of the twenty-second P-type transistor P22 on the silicon base substrate. The first insulation layer and the second insulation layer in the twenty-third via hole V23 are etched away to expose a surface of the twenty-second P-type source region, and the twenty-third via hole V23 is configured such that a forty-sixth connection electrode formed subsequently is connected with the twenty-second P-type source region through the twenty-third via hole.

In an exemplary implementation, an orthographic projection of the twenty-fourth via hole V24 on the silicon base substrate may be located within a range of an orthographic projection of the twenty-third P-type source region of the twenty-third P-type transistor P23 on the silicon base substrate. The first insulation layer and the second insulation layer in the twenty-fourth via hole V24 are etched away to expose a surface of the twenty-third P-type source region, and the twenty-fourth via hole V24 is configured such that a forty-seventh connection electrode formed subsequently is connected with the twenty-third P-type source region through the twenty-four via hole.

In an exemplary implementation, an orthographic projection of the twenty-fifth via hole V25 on the silicon base substrate may be located within a range of an orthographic projection of the twenty-third P-type drain region of the twenty-third P-type transistor P23 on the silicon base substrate. The first insulation layer and the second insulation layer within the twenty-fifth via hole V25 are etched away to expose a surface of the twenty-third P-type drain region, and the twenty-fifth via hole V25 is configured such that a forty-eighth connection electrode formed subsequently is connected with the twenty-third P-type drain region through the twenty-fifth via hole.

In an exemplary implementation, an orthographic projection of the twenty-sixth via hole V26 on the silicon base substrate may be located within a range of an orthographic projection of the twenty-fourth P-type source region of the twenty-fourth P-type transistor P24 on the silicon base substrate. The first insulation layer and the second insulation layer within the twenty-sixth via hole V26 are etched away to expose a surface of the twenty-fourth P-type source region, and the twenty-sixth via hole V26 is configured such that a forty-ninth connection electrode formed subsequently is connected with the twenty-fourth P-type source region through the twenty-sixth via hole.

In an exemplary implementation, an orthographic projection of the twenty-seventh via hole V27 on the silicon base substrate may be located within a range of an orthographic projection of the twenty-fourth P-type drain region of the twenty-fourth P-type transistor P24 (also the twenty-fifth P-type drain region of the twenty-fifth P-type transistor P22) on the silicon base substrate. The first insulation layer and the second insulation layer within the twenty-seventh via hole V27 are etched away to expose a surface of the twenty-fourth P-type drain region (also the twenty-fifth P-type drain region), and the twenty-seventh via hole V27 is configured such that a fiftieth connection electrode formed subsequently is connected to the twenty-fourth P-type drain region (also the twenty-fifth P-type drain region) through the twenty-seventh via hole.

In an exemplary implementation, an orthographic projection of the twenty-eighth via hole V28 on the silicon base substrate may be located within a range of an orthographic projection of the twenty-fifth P-type source region of the twenty-fifth P-type transistor P25 on the silicon base substrate. The first insulation layer and the second insulation layer within the twenty-eighth via hole V28 are etched away to expose a surface of the twenty-fifth P-type source region, and the twenty-eighth via hole V28 is configured such that a fifty-first connection electrode formed subsequently is connected to the twenty-fifth P-type source region through the twenty-eighth via hole.

In an exemplary implementation, an orthographic projection of the twenty-ninth via hole V29 on the silicon base substrate may be located within a range of an orthographic projection of the twenty-sixth P-type source region of the twenty-sixth P-type transistor P26 on the silicon base substrate. The first insulation layer and the second insulation layer within the twenty-ninth via hole V29 are etched away to expose a surface of the twenty-sixth P-type source region, and the twenty-ninth via hole V29 is configured such that a fifty-second connection electrode formed subsequently is connected with the twenty-sixth P-type source region through the twenty-ninth via hole.

In an exemplary implementation, an orthographic projection of the thirtieth via hole V30 on the silicon base substrate may be located within a range of an orthographic projection of the twenty-sixth P-type drain region of the twenty-sixth P-type transistor P26 on the silicon base substrate. The first insulation layer and the second insulation layer within the thirtieth via hole V30 are etched away to expose a surface of the twenty-sixth P-type drain region, and the thirtieth via hole V30 is configured such that a fifty-third connection electrode formed subsequently is connected with the twenty-sixth P-type drain region through the thirtieth via hole.

In an exemplary implementation, an orthographic projection of the thirty-first via hole V31 on the silicon base substrate may be located within a range of an orthographic projection of the twenty-seventh P-type drain region of the twenty-seventh P-type transistor P27 on the silicon base substrate. The first insulation layer and the second insulation layer within the thirty-first via hole V31 are etched away to expose a surface of the twenty-seven P-type drain region, and the thirty-first via hole V31 is configured such that a fifty-fourth connection electrode formed subsequently is connected to the twenty-seventh P-type drain region through the thirty-first via hole.

In an exemplary implementation, an orthographic projection of the thirty-second via hole V32 on the silicon base substrate may be located within a range of an orthographic projection of the twenty-seventh P-type source region of the twenty-seventh P-type transistor P27 (also the twenty-eighth P-type source region of the twenty-eighth P-type transistor P28) on the silicon base substrate. The first insulation layer and the second insulation layer within the thirty-second via hole V32 are etched away to expose a surface of the twenty-seventh P-type source region (also the twenty-eighth P-type source region), and the thirty-second via hole V32 is configured such that a fifty-fifth connection electrode formed subsequently is connected to the twenty-seventh P-type source region (also the twenty-eighth P-type source region) through the thirty-second via hole.

In an exemplary implementation, an orthographic projection of the thirty-third via hole V33 on the silicon base substrate may be located within a range of an orthographic projection of the twenty-eighth P-type drain region of the twenty-eighth P-type transistor P28 (also the twenty-ninth P-type drain region of the twenty-ninth P-type transistor P29) on the silicon base substrate. The first insulation layer and the second insulation layer within the thirty-third via hole V33 are etched away to expose a surface of the twenty-eighth P-type drain region (also the twenty-ninth P-type drain region), and the thirty-third via hole V33 is configured such that a fifty-sixth connection electrode formed subsequently is connected to the twenty-eighth P-type drain region (also the twenty-ninth P-type drain region) through the thirty-third via hole.

In an exemplary implementation, an orthographic projection of the thirty-fourth via hole V34 on the silicon base substrate may be located within a range of an orthographic projection of the twenty-ninth P-type source region of the twenty-ninth P-type transistor P29 (also the thirtieth P-type source region of the thirtieth P-type transistor P30) on the silicon base substrate. The first insulation layer and the second insulation layer within the thirty-fourth via hole V34 are etched away to expose a surface of the twenty-ninth P-type source region (also the thirtieth P-type source region), and the thirty-fourth via hole V34 is configured such that a fifty-seventh connection electrode formed subsequently is connected to the twenty-ninth P-type source region (also the thirty P-type source region) through the thirty-fourth via hole.

In an exemplary implementation, an orthographic projection of the thirty-fifth via hole V35 on the silicon base substrate may be located within a range of an orthographic projection of the thirtieth P-type drain region of the thirtieth P-type transistor P30 on the silicon base substrate. The first insulation layer and the second insulation layer within the thirty-fifth via hole V35 are etched away to expose a surface of the thirtieth P-type drain region, and the thirty-fifth via hole V35 is configured such that a fifty-eighth connection electrode formed subsequently is connected to the thirtieth P-type drain region through the thirty-fifth via hole.

In an exemplary implementation, an orthographic projection of the thirty-sixth via hole V36 on the silicon base substrate may be located within a range of an orthographic projection of the twenty-first N-type drain region of the twenty-first N-type transistor N21 on the silicon base substrate. The first insulation layer and the second insulation layer within the thirty-sixth via hole V36 are etched away to expose a surface of the twenty-first N-type drain region, and the thirty-sixth via hole V36 is configured such that a fifty-ninth connection electrode formed subsequently is connected with the twenty-first N-type drain region through the thirty-sixth via hole.

In an exemplary implementation, an orthographic projection of the thirty-seventh via hole V37 on the silicon base substrate may be located within a range of an orthographic projection of the twenty-first N-type source region of the twenty-first N-type transistor N21 (also the twenty-second N-type drain region of the twenty-second N-type transistor N22) on the silicon base substrate. The first insulation layer and the second insulation layer within the thirty-seventh via hole V37 are etched away to expose a surface of the twenty-first N-type source region (also the twenty-second N-type drain region), and the thirty-seventh via hole V37 is configured such that a sixtieth connection electrode formed subsequently is connected to the twenty-first N-type source region (also the twenty-second N-type drain region) through the thirty-seventh via hole.

In an exemplary implementation, an orthographic projection of the thirty-eighth via hole V38 on the silicon base substrate may be located within a range of an orthographic projection of the twenty-second N-type source region of the twenty-second N-type transistor N22 on the silicon base substrate. The first insulation layer and the second insulation layer within the thirty-eighth via hole V38 are etched away to expose a surface of the twenty-second N-type source region, and the thirty-eighth via hole V38 is configured such that a sixty-first connection electrode formed subsequently is connected to the twenty-second N-type source region through the thirty-eighth via hole.

In an exemplary implementation, an orthographic projection of the thirty-ninth via hole V39 on the silicon base substrate may be located within a range of an orthographic projection of the twenty-third N-type source region of the twenty-third N-type transistor N23 on the silicon base substrate. The first insulation layer and the second insulation layer within the thirty-ninth via hole V39 are etched away to expose a surface of the twenty-third N-type source region, and the thirty-ninth via hole V39 is configured such that a sixty-second connection electrode formed subsequently is connected with the twenty-third N-type source region through the thirty-ninth via hole.

In an exemplary implementation, an orthographic projection of the fortieth via hole V40 on the silicon base substrate may be located within a range of an orthographic projection of the twenty-third N-type drain region of the twenty-third N-type transistor N23 on the silicon base substrate. The first insulation layer and the second insulation layer within the fortieth via hole V40 are etched away to expose a surface of the twenty-third N-type drain region, and the fortieth via hole V40 is configured such that a sixty-third connection electrode formed subsequently is connected with the twenty-third N-type drain region through the fortieth via hole.

In an exemplary implementation, an orthographic projection of the forty-first via hole V41 on the silicon base substrate may be located within a range of an orthographic projection of the twenty-fourth N-type drain region of the twenty-fourth N-type transistor N24 on the silicon base substrate. The first insulation layer and the second insulation layer within the forty-first via hole V41 are etched away to expose a surface of the twenty-fourth N-type drain region, and the forty-first via hole V41 is configured such that a sixty-fourth connection electrode formed subsequently is connected with the twenty-fourth N-type drain region through the forty-first via hole.

In an exemplary implementation, an orthographic projection of the forty-second via hole V42 on the silicon base substrate may be located within a range of an orthographic projection of the twenty-fourth N-type source region of the twenty-fourth N-type transistor N24 (also the twenty-fifth N-type drain region of the twenty-fifth N-type transistor N22) on the silicon base substrate. The first insulation layer and the second insulation layer within the forty-second via hole V42 are etched away to expose a surface of the twenty-fourth N-type source region (also the twenty-fifth N-type drain region), and the forty-second via hole V42 is configured such that a sixty-fifth connection electrode formed subsequently is connected to the twenty-fourth N-type source region (also the twenty-fifth N-type drain region) through the forty-second via hole.

In an exemplary implementation, an orthographic projection of the forty-third via hole V43 on the silicon base substrate may be located within a range of an orthographic projection of the twenty-fifth N-type source region of the twenty-fifth N-type transistor N25 on the silicon base substrate. The first insulation layer and the second insulation layer within the forty-third via hole V43 are etched away to expose a surface of the twenty-fifth N-type source region, and the forty-third via hole V43 is configured such that a sixty-sixth connection electrode formed subsequently is connected with the twenty-fifth N-type source region through the forty-third via hole.

In an exemplary implementation, an orthographic projection of the forty-fourth via hole V44 on the silicon base substrate may be located within a range of an orthographic projection of the twenty-sixth N-type source region of the twenty-sixth N-type transistor N23 on the silicon base substrate. The first insulation layer and the second insulation layer within the forty-fourth via hole V44 are etched away to expose a surface of the twenty-sixth N-type source region, and the forty-fourth via hole V44 is configured such that a sixty-seventh connection electrode formed subsequently is connected with the twenty-sixth N-type source region through the forty-fourth via hole.

In an exemplary implementation, an orthographic projection of the forty-fifth via hole V45 on the silicon base substrate may be located within a range of an orthographic projection of the twenty-sixth N-type drain region of the twenty-sixth N-type transistor N23 on the silicon base substrate. The first insulation layer and the second insulation layer within the forty-fifth via hole V45 are etched away to expose a surface of the twenty-sixth N-type drain region, and the forty-fifth via hole V45 is configured such that a sixty-eighth connection electrode formed subsequently is connected with the twenty-sixth N-type drain region through the forty-fifth via hole.

In an exemplary implementation, an orthographic projection of the forty-sixth via hole V46 on the silicon base substrate may be located within a range of an orthographic projection of the twenty-seventh N-type drain region of the twenty-seventh N-type transistor N27 on the silicon base substrate. The first insulation layer and the second insulation layer within the forty-sixth via hole V46 are etched away to expose a surface of the twenty-seventh N-type drain region, and the forty-sixth via hole V46 is configured such that a sixty-nine connection electrode formed subsequently is connected with the twenty-seventh N-type drain region through the forty-sixth via hole.

In an exemplary implementation, an orthographic projection of the forty-seventh via hole V47 on the silicon base substrate may be located within a range of an orthographic projection of the twenty-seventh N-type source region of the twenty-seventh N-type transistor N27 (also the twenty-eighth N-type source region of the twenty-eighth N-type transistor N28) on the silicon base substrate. The first insulation layer and the second insulation layer within the forty-seventh via hole V47 are etched away to expose a surface of the twenty-seventh N-type source region (also the twenty-eighth N-type source region), and the forty-seventh via hole V47 is configured such that a seventieth connection electrode formed subsequently is connected to the twenty-seventh N-type source region (also the twenty-eighth N-type source region) through the forty-seventh via hole.

In an exemplary implementation, an orthographic projection of the forty-eighth via hole V48 on the silicon base substrate may be located within a range of an orthographic projection of the twenty-eighth N-type drain region of the twenty-eighth N-type transistor N28 (also the twenty-ninth N-type drain region of the twenty-ninth N-type transistor N29) on the silicon base substrate. The first insulation layer and the second insulation layer within the forty-eighth via hole V48 are etched away to expose a surface of the twenty-eighth N-type drain region (also the twenty-ninth N-type drain region), and the forty-eighth via hole V48 is configured such that a seventy-first connection electrode formed subsequently is connected to the twenty-eighth N-type drain region (also the twenty-ninth N-type drain region) through the forty-eighth via hole.

In an exemplary implementation, an orthographic projection of the forty-ninth via hole V49 on the silicon base substrate may be located within a range of an orthographic projection of the twenty-ninth N-type source region of the twenty-ninth N-type transistor N29 (also the thirtieth N-type source region of the thirtieth N-type transistor N30) on the silicon base substrate. The first insulation layer and the second insulation layer within the forty-ninth via hole V49 are etched away to expose a surface of the twenty-ninth N-type source region (also the thirtieth N-type source region), and the forty-ninth via hole V49 is configured such that a seventy-second connection electrode formed subsequently is connected to the twenty-ninth N-type source region (also the thirtieth N-type source region) through the forty-ninth via hole.

In an exemplary implementation, an orthographic projection of the fiftieth via hole V50 on the silicon base substrate may be located within a range of an orthographic projection of the thirtieth N-type drain region of the thirtieth N-type transistor N30 on the silicon base substrate. The first insulation layer and the second insulation layer within the fiftieth via hole V50 are etched away to expose a surface of the thirtieth N-type drain region, and the fiftieth via hole V50 is configured such that a seventy-third connection electrode subsequently formed is connected to the thirtieth N-type drain region through the fiftieth via hole.

In an exemplary implementation, an orthographic projection of the fifty-first via hole V51 on the silicon base substrate may be located within a range of an orthographic projection of the first P-type gate electrode 201P (also the first N-type gate electrode 201N) on the silicon base substrate. The second insulation layer within the fifty-first via hole V51 is etched away to expose a surface of the first P-type gate electrode 201P (also the first N-type gate electrode 201N), and the fifty-first via hole V51 is configured such that a first connection electrode formed subsequently is connected to the first P-type gate electrode 201P (also the first N-type gate electrode 201N) through the fifty-first via hole.

In an exemplary embodiment, an orthographic projection of the fifty-second via hole V52 on the silicon base substrate may be located within a range of an orthographic projection of the second P-type gate electrode 202P on the silicon base substrate. The second insulation layer within the fifty-second V52 is etched away to expose a surface of the second P-type gate electrode 202P, and the fifty-second via hole V52 is configured such that a second connection electrode formed subsequently is connected to the second P-type gate electrode 202P through the fifty-second via hole.

In an exemplary implementation, an orthographic projection of a fifty-third via hole V53 on the silicon base substrate may be located within a range of an orthographic projection of the third P-type gate electrode 203P on the silicon base substrate. The second insulation layer within the fifty-third via hole V53 is etched away to expose a surface of the third P-type gate electrode 203P, and the fifty-third via hole V53 is configured such that a third connection electrode formed subsequently is connected to the third P-type gate electrode 203P through the fifty-third via hole.

In an exemplary implementation, an orthographic projection of the fifty-fourth via hole 54 on the silicon base substrate may be located within a range of an orthographic projection of the fourth P-type gate electrode 204P on the silicon base substrate. The second insulation layer within the fifty-fourth via hole V54 is etched away to expose a surface of the fourth P-type gate electrode 204P, and the fifty-fourth via hole V54 is configured such that a fourth connection electrode formed subsequently is connected to the fourth P-type gate electrode 204P through the fifty-fourth via hole V54.

In an exemplary implementation, an orthographic projection of the fifty-fifth via hole V55 on the silicon base substrate may be located within a range of an orthographic projection of the fifth P-type gate electrode 205P on the silicon base substrate. The second insulation layer within the fifty-fifth via hole V55 is etched away to expose a surface of the fifth P-type gate electrode 205P, and the fifty-fifth via hole V55 is configured such that a fifth connection electrode formed subsequently is connected to the fifth P-type gate electrode 205P through the fifty-fifth via hole.

In an exemplary implementation, an orthographic projection of a fifty-sixth via hole V56 on the silicon base substrate may be located within a range of an orthographic projection of the sixth P-type gate electrode 206P on the silicon base substrate. The second insulation layer within the fifty-sixth via hole V56 is etched away to expose a surface of the sixth P-type gate electrode 206P, and the fifty-sixth via hole V56 is configured such that a sixth connection electrode formed subsequently is connected to the sixth P-type gate electrode 206P through the fifty-sixth via hole.

In an exemplary implementation, an orthographic projection of the fifty-seventh via hole 57 on the silicon base substrate may be located within a range of an orthographic projection of the seventh P-type gate electrode 207P on the silicon base substrate. The second insulation layer within the fifty-seventh via hole V57 is etched away to expose a surface of the seventh P-type gate electrode 207P, and the fifty-seventh via hole V57 is configured such that a seventh connection electrode formed subsequently is connected to the seventh P-type gate electrode 207P through the fifty-seventh via hole.

In an exemplary implementation, an orthographic projection of the fifty-eighth via hole V58 on the silicon base substrate may be located within a range of an orthographic projection of the eighth P-type gate electrode 208P on the silicon base substrate. The second insulation layer within the fifty-eighth via hole V58 is etched away to expose a surface of the eighth P-type gate electrode 208P, and the fifty-eighth via hole V58 is configured such that an eighth connection electrode formed subsequently is connected to the eighth P-type gate electrode 208P through the fifty-eighth via hole.

In an exemplary implementation, an orthographic projection of a fifty-ninth via hole V59 on the silicon base substrate may be located within a range of an orthographic projection of the ninth P-type gate electrode 209P on the silicon base substrate. The second insulation layer within the fifty-ninth via hole V59 is etched away to expose a surface of the ninth P-type gate electrode 209P, and the fifty-ninth via hole V59 is configured such that a ninth connection electrode formed subsequently is connected to the ninth P-type gate electrode 209P through the fifty-ninth via hole.

In an exemplary implementation, an orthographic projection of the sixtieth via hole V60 on the silicon base substrate may be located within a range of an orthographic projection of the tenth P-type gate electrode 210P on the silicon base substrate. The second insulation layer within the sixtieth via hole V60 is etched away to expose a surface of the tenth P-type gate electrode 210P, and the sixtieth via hole V60 is configured such that a tenth connection electrode formed subsequently is connected to the tenth P-type gate electrode 210P through the sixtieth via hole.

In an exemplary implementation, an orthographic projection of the sixty-first via hole V61 on the silicon base substrate may be located within a range of an orthographic projection of the eleventh P-type gate electrode 211P on the silicon base substrate. The second insulation layer within the sixty-first via hole V61 is etched away to expose a surface of the eleventh P-type gate electrode 211P, and the sixty-first via hole V61 is configured such that an eleventh connection electrode formed subsequently is connected to the eleventh P-type gate electrode 211P through the sixty-first via hole.

In an exemplary implementation, an orthographic projection of the sixty-second via hole V62 on the silicon base substrate may be located within a range of an orthographic projection of the twelfth P-type gate electrode 212P on the silicon base substrate. The second insulation layer within the sixty-second via hole V62 is etched away to expose a surface of the twelfth P-type gate electrode 212P, and the sixty-second via hole V62 is configured such that a twelfth connection electrode formed later is connected to the twelfth P-type gate electrode 212P through the sixty-second via hole.

In an exemplary implementation, an orthographic projection of the sixty-third via hole V63 on the silicon base substrate may be located within a range of an orthographic projection of the thirteenth P-type gate electrode 213P on the silicon base substrate. The second insulation layer within the sixty-third via hole V63 is etched away to expose a surface of the thirteenth P-type gate electrode 213P, and the sixty-third via hole V63 is configured such that a thirteenth connection electrode formed later is connected to the thirteenth P-type gate electrode 213P through the sixty-third via hole.

In an exemplary implementation, an orthographic projection of the sixty-fourth via hole V64 on the silicon base substrate may be located within a range of an orthographic projection of the second N-type gate electrode 202N on the silicon base substrate. The second insulation layer within the sixty-fourth via hole V64 is etched away to expose a surface of the second N-type gate electrode 202N, and the sixty-fourth via hole V64 is configured such that a fourteenth connection electrode formed subsequently is connected to the second N-type gate electrode 202P through the sixty-fourth via hole.

In an exemplary implementation, an orthographic projection of the sixty-fifth via hole V65 on the silicon base substrate may be located within a range of an orthographic projection of the third N-type gate electrode 203N on the silicon base substrate. The second insulation layer within the sixty-fifth via hole V65 is etched away to expose a surface of the third N-type gate electrode 203N, and the sixty-fifth via hole V65 is configured such that a fifteenth connection electrode formed subsequently is connected to the third N-type gate electrode 203N through the sixty-fifth via hole.

In an exemplary implementation, an orthographic projection of the sixty-sixth via hole V66 on the silicon base substrate may be located within a range of an orthographic projection of the twenty-first P-type gate electrode 221P (also the twenty-first N-type gate electrode 221N) on the silicon base substrate. The second insulation layer within the sixty-sixth via hole V66 is etched away to expose a surface of the twenty-first P-type gate electrode 221P (also the twenty-first N-type gate electrode 221N), and the sixty-sixth via hole V66 is configured such that a thirty-fifth connection electrode formed subsequently is connected to the twenty-first P-type gate electrode 221P (also the twenty-first N-type gate electrode 221N) through the sixty-sixth via hole.

In an exemplary implementation, an orthographic projection of the sixty-seventh via hole V67 on the silicon base substrate may be located within a range of an orthographic projection of the twenty-second P-type gate electrode 222P (also the twenty-second N-type gate electrode 222N) on the silicon base substrate. The second insulation layer within the sixty-seventh via hole V67 is etched away to expose a surface of the twenty-second P-type gate electrode 222P (also the twenty-second N-type gate electrode 222N), and the sixty-seventh via hole V67 is configured such that a thirty-sixth connection electrode formed subsequently is connected to the twenty-second P-type gate electrode 222P (also the twenty-second N-type gate electrode 222N) through the sixty-seventh via hole.

In an exemplary implementation, an orthographic projection of the sixty-eighth via hole V68 on the silicon base substrate may be located within a range of an orthographic projection of the twenty-third P-type gate electrode 223P on the silicon base substrate. The second insulation layer within the sixty-eighth via hole V68 is etched away to expose a surface of the twenty-third P-type gate electrode 223P, and the sixty-eighth via hole V68 is configured such that a thirty-seventh connection electrode formed subsequently is connected to the twenty-third P-type gate electrode 223P through the sixty-eighth via hole.

In an exemplary implementation, an orthographic projection of the sixty-ninth via hole V69 on the silicon base substrate may be located within a range of an orthographic projection of the twenty-third N-type gate electrode 223N on the silicon base substrate. The second insulation layer within the sixty-ninth via hole V69 is etched away to expose a surface of the twenty-third N-type gate electrode 223N, and the sixty-ninth via hole V69 is configured such that a thirty-eighth connection electrode formed subsequently is connected to the twenty-third N-type gate electrode 223N through the sixty-ninth via hole.

In an exemplary implementation, an orthographic projection of the seventieth via hole V70 on the silicon base substrate may be located within a range of an orthographic projection of the twenty-fourth P-type gate electrode 224P (also the twenty-fourth N-type gate electrode 224N) on the silicon base substrate. The second insulation layer within the seventieth via hole V70 is etched away to expose a surface of the twenty-fourth P-type gate electrode 224P (also the twenty-fourth N-type gate electrode 224N), and the seventieth via hole V70 is configured such that a thirty-ninth connection electrode formed subsequently is connected to the twenty-fourth P-type gate electrode 224P (also the twenty-fourth N-type gate electrode 224N) through the seventieth via hole.

In an exemplary implementation, an orthographic projection of the seventy-first via hole V71 on the silicon base substrate may be located within a range of an orthographic projection of the twenty-fifth P-type gate electrode 225P (also the twenty-fifth N-type gate electrode 225N) on the silicon base substrate. The second insulation layer within the seventy-first via hole V71 is etched away to expose a surface of the twenty-fifth P-type gate electrode 225P (also the twenty-fifth N-type gate electrode 225N), and the seventy-first via hole V71 is configured such that a fortieth connection electrode formed subsequently is connected to the twenty-fifth P-type gate electrode 225P (also the twenty-fifth N-type gate electrode 225N) through the seventy-first via hole.

In an exemplary implementation, an orthographic projection of the seventy-second via hole V72 on the silicon base substrate may be located within a range of an orthographic projection of the twenty-sixth P-type gate electrode 226P (also the twenty-sixth N-type gate electrode 226N) on the silicon base substrate. The second insulation layer within the seventy-second via hole V72 is etched away to expose a surface of the twenty-sixth P-type gate electrode 226P (also the twenty-sixth N-type gate electrode 226N), and the seventy-second via hole V72 is configured such that a forty-first connection electrode formed subsequently is connected to the twenty-sixth P-type gate electrode 226P (also the twenty-sixth N-type gate electrode 226N) through the seventy-second via hole.

In an exemplary implementation, an orthographic projection of the seventy-third via hole V73 on the silicon base substrate may be located within a range of an orthographic projection of the twenty-seventh P-type gate electrode 227P on the silicon base substrate. The second insulation layer within the seventy-third via hole V73 is etched away to expose a surface of the twenty-seventh P-type gate electrode 227P, and the seventy-third via hole V73 is configured such that a forty-second connection electrode formed subsequently is connected to the twenty-seventh P-type gate electrode 227P through the seventy-third via hole.

In an exemplary implementation, an orthographic projection of the seventy-fourth via hole V74 on the silicon base substrate may be located within a range of an orthographic projection of the twenty-eighth P-type gate electrode 228P on the silicon base substrate. The second insulation layer within the seventy-fourth via hole V74 is etched away to expose a surface of the twenty-eighth P-type gate electrode 228P, and the seventy-fourth via hole V74 is configured such that a forty-second connection electrode formed subsequently is connected to the twenty-eighth P-type gate electrode 228P through the seventy-fourth via hole.

In an exemplary implementation, an orthographic projection of the seventy-fifth via hole V75 on the silicon base substrate may be located within a range of an orthographic projection of the twenty-ninth P-type gate electrode 229P on the silicon base substrate. The second insulation layer within the seventy-fifth via hole V75 is etched away to expose a surface of the twenty-ninth P-type gate electrode 229P, and the seventy-fifth via hole V75 is configured such that a forty-second connection electrode formed subsequently is connected to the twenty-ninth P-type gate electrode 229P through the seventy-fifth via hole.

In an exemplary implementation, an orthographic projection of the seventy-sixth via hole V76 on the silicon base substrate may be located within a range of an orthographic projection of the thirtieth P-type gate electrode 230P on the silicon base substrate. The second insulation layer within the seventy-sixth via hole V76 is etched away to expose a surface of the thirtieth P-type gate electrode 230P, and the seventy-sixth via hole V76 is configured such that a forty-second connection electrode formed subsequently is connected to the thirtieth P-type gate electrode 230P through the seventy-sixth via hole.

In an exemplary implementation, an orthographic projection of the seventy-seventh via hole V77 on the silicon base substrate may be located within a range of an orthographic projection of the twenty-seventh N-type gate electrode 227N on the silicon base substrate. The second insulation layer within the seventy-seventh via hole V77 is etched away to expose a surface of the twenty-seventh N-type gate electrode 227N, and the seventy-seventh via hole V77 is configured such that a forty-third connection electrode formed subsequently is connected to the twenty-seventh N-type gate electrode 227N through the seventy-seventh via hole.

In an exemplary implementation, an orthographic projection of the seventy-eighth via hole V78 on the silicon base substrate may be located within a range of an orthographic projection of the twenty-eighth N-type gate electrode 228N on the silicon base substrate. The second insulation layer within the seventy-eighth via hole V78 is etched away to expose a surface of the twenty-eighth N-type gate electrode 228N, and the seventy-eighth via hole V78 is configured such that a forty-third connection electrode formed subsequently is connected to the twenty-eighth N-type gate electrode 228N through the seventy-eighth via hole.

In an exemplary implementation, an orthographic projection of the seventy-ninth via hole V79 on the silicon base substrate may be located within a range of an orthographic projection of the twenty-ninth N-type gate electrode 229N on the silicon base substrate. The second insulation layer within the seventy-ninth via hole V79 is etched away to expose a surface of the twenty-ninth N-type gate electrode 229N, and the seventy-ninth via hole V79 is configured such that a forty-third connection electrode formed subsequently is connected to the twenty-ninth N-type gate electrode 229N through the seventy-ninth via hole.

In an exemplary implementation, an orthographic projection of the eightieth via hole V80 on the silicon base substrate may be located within a range of an orthographic projection of the thirtieth N-type gate electrode 230N on the silicon base substrate. The second insulation layer within the eightieth via hole V80 is etched away to expose a surface of the thirtieth N-type gate electrode 230N, and the eightieth via hole V80 is configured such that a forty-third connection electrode formed subsequently is connected to the thirtieth N-type gate electrode 230N through the eightieth via hole.

In an exemplary implementation, the quantity of each of the first via hole V1 to the eightieth via hole V80 may be plural to reduce the contact resistance and improve the connection reliability.

In an exemplary implementation, the fifty-first via hole V51 to the eightieth via hole V80 may be referred to as gate via holes, and one or more of the above gate via holes may be located in a gap region 50 between an P-type active region and an N-type active region, so as to be beneficial for an arrangement of a plurality of connection electrodes formed subsequently, and optimize the connection structure between the first conductive layer and the gate conductive layer, reducing the occupied area of the gate driving circuit.

In an exemplary implementation, gate via holes in the first NAND gate and the second NAND gate may be referred to as first gate via holes, which are configured such that a first gate connection electrode formed subsequently is connected to a P-type gate electrode of a P-type transistor and an N-type gate electrode of an N-type transistor through the first gate via holes, and the first gate via holes may be disposed in the gap region 50. The first gate via holes may include a sixty-sixth via hole V66, a sixty-seventh via hole V67, a seventieth via hole V70, and a seventy-first via hole V71.

In an exemplary implementation, a plurality of first gate via holes in the first NAND gate and the second NAND gate may be located on the same straight line extending along the first direction X.

In an exemplary implementation, gate via holes in the first inverter and the second inverter may be referred to as second gate via holes, which are configured such that a second gate connection electrode formed subsequently is connected to a P-type gate electrode of a P-type transistor and an N-type gate electrode of an N-type transistor through the second gate via holes, and the second gate via holes may be disposed in the gap region 50. The second gate via holes may include a fifty-first via hole V51 and a seventy-second via hole V72.

In an exemplary implementation, a plurality of second gate via holes in the first inverter and the second inverter may be located on the same straight line extending along the first direction X.

In an exemplary implementation, in the second direction Y, positions of the first gate via holes may be substantially located in the middle of the gap region 50, and with respect to the first gate via holes, the at least one second gate via hole is closer to an N-type active region of an N-type transistor. For example, the fifty-first via hole V51 (a second gate via hole in the first inverter) is closer to an N-type active region of an N-type transistor than the sixty-sixth via hole V66 (a first gate via hole in the first NAND gate).

In an exemplary implementation, the gate via holes in the first transmission gate may be referred to as third gate via holes, which may include a third P-type gate via hole and a third N-type gate via hole, wherein the third P-type gate via hole is configured such that a third P-type gate connection electrode formed subsequently is connected to a P-type gate electrode of a P-type transistor through the third P-type gate via hole, the third N-type gate via hole is configured such that a third N-type gate connection electrode formed subsequently is connected to an N-type gate electrode of an N-type transistor through the third N-type gate via hole, and the third P-type gate via hole and the third N-type gate via hole may be disposed in the gap region 50. The third P-type gate via hole may include a sixty-eighth via hole V68, and the third N-type gate via hole may include a sixty-ninth via hole V69.

In an exemplary implementation, in the second direction Y, with respect to the first gate via holes, the third P-type gate via hole is closer to a P-type active region of a P-type transistor, and the third N-type gate via hole is closer to an N-type active region of an N-type transistor.

In an exemplary implementation, the gate via holes in the first P-type transistor unit, the second P-type transistor unit, and the third P-type transistor unit may be referred to as fourth gate via holes, which are configured such that a fourth gate connection electrode formed subsequently is connected to a P-type gate electrode of a P-type transistor through the fourth gate via holes, the fourth gate via holes may be disposed in the gap region 50, and a plurality of fourth gate via holes may be located on the same straight line extending along the first direction X. The fourth gate via holes may include a fifty-second via hole V52 to a fifty-seventh via hole V57, a fifty-eighth via hole V58 to a sixty-third via hole V63, and a seventy-third via hole V73 to a seventy-sixth via hole V76.

In an exemplary implementation, in the second direction Y, with respect to the first gate via holes, the fourth gate via hole is closer to a P-type active region of a P-type transistor.

In an exemplary implementation, the gate via holes in the first N-type transistor unit, the second N-type transistor unit, and the third N-type transistor unit may be referred to as fifth gate via holes, which are configured such that a fifth gate connection electrode formed subsequently is connected to an N-type gate electrode of an N-type transistor through the fifth gate via holes, the fifth gate via holes may be disposed in the gap region 50, and a plurality of fifth gate via holes may be located on the same straight line extending along the first direction X. The fifth gate via holes may include a sixty-fourth via hole V64, a sixty-fifth via hole V65, a seventy-seventh via hole V77 to an eightieth via hole V80.

In an exemplary implementation, in the second direction Y, with respect to the first gate via hole, the fifth gate via hole is closer to an N-type active region of an N-type transistor.

In the present disclosure, positions of the gate via holes are set, which is not only beneficial for process uniformity and signal transmission uniformity, but also beneficial for the arrangement of a plurality of connection electrodes formed subsequently, optimizing a connection structure between the first conductive layer and the gate conductive layer.

In an exemplary implementation, an orthographic projection of the eighty-first via hole V81 on the silicon base substrate may be located within a range of an orthographic projection of the first power supply active region 100P on the silicon base substrate. The first insulation layer and the second insulation layer within the eighty-first via hole V81 are etched away to expose a surface of the first power supply active region 100P, and the eighty-first via hole V81 is configured such that a first power supply line formed subsequently is connected to the first power supply active region 100P through the eighty-first via hole.

In an exemplary implementation, the quantity of the eighty-first via holes V81 is plural, and the plurality of eighty-first via holes V81 are disposed sequentially along the first direction D1 to reduce the contact resistance and improve the connection reliability.

In an exemplary implementation, an orthographic projection of the eighty-second via hole V82 on the silicon base substrate is located within a range of an orthographic projection of the second power supply active region 100N1 on the silicon base substrate. The first insulation layer and the second insulation layer within the eighty-second via hole V82 is etched away to expose a surface of the second power supply active region 100N1, and the eighty-second via hole V82 is configured such that a second power supply line formed sequentially is connected with the second power supply active region 100N1 through the eighty-second via hole.

In an exemplary implementation, the quantity of the eighty-second via holes V82 is plural, and the plurality of eighty-second via holes V82 are disposed sequentially along the first direction X to reduce the contact resistance and improve the connection reliability.

In an exemplary implementation, an orthographic projection of the eighty-third via hole V83 on the silicon base substrate may be located within a range of an orthographic projection of the ground active region 100N2 on the silicon base substrate. The first insulation layer and the second insulation layer within the eighty-third via hole V83 are etched away to expose a surface of the ground active region 100N2, and the eighty-third via hole V83 is configured such that a ground line formed subsequently is connected to the ground active region 100N2 through the eighty-third via hole.

In an exemplary implementation, the quantity of the eighty-third via holes V83 multiplies plural, and the plurality of eighty-third via holes V83 are disposed sequentially along the first direction X to reduce the contact resistance and improve the connection reliability.

In an exemplary implementation, a plurality of eighty-first via holes V81 disposed sequentially along the first direction X form a first via hole row, a plurality of eighty-second via holes V82 disposed sequentially along the first direction X form a second via row, and the first via row and the second via row are respectively located on both sides of a plurality of transistors in the second direction, so that the plurality of transistors are located between the first via row and the second via row, which may effectively avoid mutual interference between different gate driving circuits.

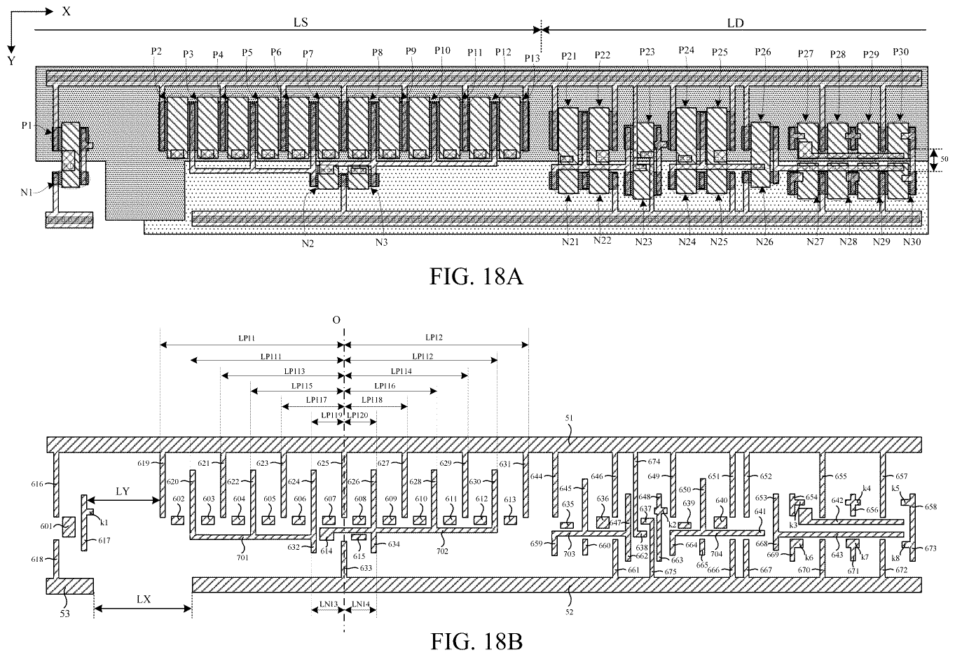

(7) A pattern of a first conductive layer is formed. In an exemplary implementation, forming the pattern of the first conductive layer may include: depositing a first conductive film on the silicon base, on which the aforementioned patterns are formed, and patterning the first conductive thin film through the patterning process to form the pattern of the first conductive layer on the second insulation layer. As shown in FIGS. 18A and 18B. FIG. 18B is a schematic diagram of the first conductive layer in FIG. 18A. In an exemplary implementation, the first conductive layer may be referred to as a first metal (Metal1) layer.

In an exemplary implementation, the pattern of the first conductive layer may at least include a first power supply line 51, a second power supply line 52, a ground line 53, a first connection electrode 601 to a seventy-fifth connection electrode 675, and a first connection line 701 to a fourth connection line 704.

In an exemplary implementation, the first power supply line 51 may be in a shape of a straight line or a bend line extending along the first direction X, and may be disposed on a side of the plurality of transistors opposite to the second direction Y. The first power supply line 51 is connected to the first power supply active region 100P through a plurality of eighty-first via holes V81.

In an exemplary implementation, the first power supply line 51 may be disposed in the first region LS and the second region LD, that is, the first power supply active region 100P extends from the first region LS to the second region LD. Since the first power supply active region 100P is located within a region where the N-well region 20 is located, the first power supply line 51 can write the first power supply signal to the N-well region 20, which can not only provide a better current driving capability and a response speed, meet the operation requirements of the output circuit, but also reduce the voltage drop and power consumption loss in the output circuit, and improve the overall efficiency of the output circuit.

In an exemplary implementation, the second power supply line 52 may be in a shape of a straight line or a bend line extending along the first direction X, and may be disposed on a side of a plurality of transistors in the second direction Y. The second power supply line 52 is connected to the second power supply active region 100N1 through a plurality of eighty-second via holes V82.

In an exemplary implementation, the second power supply line 52 may be disposed in the first region LS and the second region LD, that is, the second power supply active region 100N1 extends from the first region LS to the second region LD. Since the second power supply active region 100N1 is located within a region where the deep N-well region 10 is located, the second power supply line 52 can write the second power supply signal to the deep N-well region 10, which may not only ensure a good ground connection to eliminate noise, stabilize the potential, and provide a reliable reference level, but also provide a low impedance path so that current can be effectively returned to ground.

In the exemplary implementation, the ground line 53 may be in a straight line or a bend line extending along the first direction X, and may be disposed on a side of the first N-type transistor N1 in the second direction Y. The ground line 53 is connected to the ground active region 100N2 through a plurality of eighty-third via holes V83.

In an exemplary implementation, the ground line 53 may be disposed in the first region LS. Since the ground active region 100N2 is located outside a region where the deep N-well region 10 and the N-well region 20 are located, the ground line 53 may not only achieve a relatively stable potential reference, ensure that the output circuit has consistent and reliable performance under different working conditions, but also provide a better signal isolation effect, reduce the influence of interconnection capacitance, reduce signal crosstalk and interference, and improve the stability and reliability of the circuit.

In an exemplary implementation, there is a voltage line distance LX between an edge of the second power supply line 52 on a side close to the ground line 53 and an edge of the ground line 53 on a side close to the second power supply line 52, and the voltage line distance LX may be greater than or equal to 5 μm.

In an exemplary implementation, the level converter is configured to perform a voltage conversion, i.e. convert a low potential (the ground line, 0V) in the inverter circuit to a low potential (the second power supply line, −5V) in the 4 transistor unit circuit. It is shown that there is an interaction between the two low potentials, and the strength of the interaction is affected by a distance between the ground line and the second power supply line. When the distance between the ground line and the second power supply line is small, the insulation layer will be broken down. In the present disclosure, the minimum distance between the ground line and the second power supply line is set to be 5 μm, which may not only avoid the breakdown of the insulation layer, but also reduce the mutual influence between the ground line and the second power supply line, and improve the stability of the level converter circuit.

In an exemplary implementation, the first connection electrode 601 may be in a shape of a block (such as a rectangle), the first connection electrode 601 is connected to the first P-type gate electrode 201P (also the first N-type gate electrode 201N) through the fifty-first via hole V51, and the first connection electrode 601 is configured to be connected to a first signal line formed subsequently.

In an exemplary implementation, the second connection electrode 602 may be in a shape of a block (for example, a rectangle), and the second connection electrode 602 is connected to the second P-type gate electrode 202P through the thirty-second via hole V52 and is configured to be connected to a first signal line formed subsequently.

In an exemplary implementation, the third connection electrode 603 may be in a shape of a block (for example, a rectangle), and the third connection electrode 603 is connected to the third P-type gate electrode 203P through the fifty-third via hole V53 and is configured to be connected to a first signal line formed subsequently.

In an exemplary implementation, the fourth connection electrode 604 may be in a shape of a block (for example, a rectangle), and the fourth connection electrode 604 is connected to the fourth P-type gate electrode 204P through the fifty-fourth via hole V54 and is configured to be connected to a first signal line formed subsequently.

In an exemplary implementation, the fifth connection electrode 605 may be in a shape of a block (for example, a rectangle), and the fifth connection electrode 605 is connected to the fifth P-type gate electrode 205P through the fifty-fifth via hole V55 and is configured to be connected to a first signal line formed subsequently.

In an exemplary implementation, the sixth connection electrode 606 may be in a shape of a block (for example, a rectangle), and the sixth connection electrode 606 is connected to the sixth P-type gate electrode 206P through the fifty-sixth via hole V56 and is configured to be connected to a first signal line formed subsequently.

In an exemplary implementation, the seventh connection electrode 607 may be in a shape of a block (for example, a rectangle), and the seventh connection electrode 607 is connected to the seventh P-type gate electrode 207P through the fifty-seventh via hole V57 and is configured to be connected to a first signal line formed subsequently.

In an exemplary implementation, the eighth connection electrode 608 may be in a shape of a block (for example, a rectangle), and the eighth connection electrode 608 is connected to the eighth P-type gate electrode 208P through the fifty-eighth via hole V58 and is configured to be connected to a first signal transfer line formed subsequently.

In an exemplary implementation, the ninth connection electrode 609 may be in a shape of a block (for example, a rectangle), and the ninth connection electrode 609 is connected to the ninth P-type gate electrode 209P through the fifty-ninth via hole V59 and is configured to be connected to a first signal transfer line formed subsequently.

In an exemplary implementation, the tenth connection electrode 610 may be in a shape of a block (for example, a rectangle), and the tenth connection electrode 610 is connected to the tenth P-type gate electrode 210P through the sixtieth via hole V60 and is configured to be connected to a first signal transfer line formed subsequently.

In an exemplary implementation, the eleventh connection electrode 611 may be in a shape of a block (such as a rectangle), the eleventh connection electrode 611 is connected to the eleventh P-type gate electrode 211P through the sixty-first via hole V61, and the sixty-first connection electrode 611 is configured to be connected to a first signal transfer line formed subsequently.

In an exemplary implementation, the twelfth connection electrode 612 may be in a shape of a block (for example, a rectangle), and the twelfth connection electrode 612 is connected to the twelfth P-type gate electrode 212P through the sixty-second via hole V62 and is configured to be connected to a first signal transfer line formed subsequently.

In an exemplary implementation, the thirteenth connection electrode 613 may be in a shape of a block (for example, a rectangle), and the thirteenth connection electrode 613 is connected to the thirteenth P-type gate electrode 213P through the sixty-third via hole V63 and is configured to be connected to a first signal transfer line formed subsequently.

In an exemplary implementation, the fourteenth connection electrode 614 may be in a shape of a block (such as a rectangle), and the fourteenth connection electrode 614 is connected to the second N-type gate electrode 202N through the sixty-fourth via hole V64.

In an exemplary implementation, the fifteenth connection electrode 615 may be in a shape of a block (for example, a rectangle), and the thirteenth connection electrode 615 is connected to the third N-type gate electrode 203N through the sixty-fifth via hole V65 and is configured to be connected to a second signal transfer line formed subsequently.

In an exemplary implementation, the first connection electrode 601 to the fifteenth connection electrode 615 and the thirty-fifth connection electrode 635 to the forty-third connection electrode 643 may be referred to as gate connection electrodes, and the gate connection electrodes are connected to the corresponding gate electrodes through corresponding gate via holes.

In an exemplary implementation, the gate connection electrodes in the first NAND gate may include a thirty-fifth connection electrode 635 and a thirty-sixth connection electrode 636, the gate connection electrodes in the second NAND gate may include a thirty-ninth connection electrode 639 and a fortieth connection electrode 640, and the above gate connection electrodes may be referred to as first gate connection electrodes.

In an exemplary implementation, the gate connection electrodes in the first inverter may include the first connection electrode 601, the gate connection electrodes in the second inverter may include the forty-first connection electrode 641, and the above gate connection electrodes may be referred to as the second gate connection electrodes.

In an exemplary implementation, the gate connection electrodes in the first transmission gate may include the thirty-seventh connection electrode 637 and the thirty-eighth connection electrode 638, wherein the thirty-seventh connection electrode 637 may be referred to as a third P-type gate connection electrode, and the thirty-eighth connection electrode 638 may be referred to as a third N-type gate connection electrode.

In an exemplary implementation, the gate connection electrodes in the first P-type transistor unit may include the second connection electrode 602 to the seventh connection electrode 607, the gate connection electrodes in the second P-type transistor unit may include the eighth connection electrode 608 to the thirteenth connection electrode 613, the gate connection electrode in the third P-type transistor unit may include the forty-second connection electrode 642, and the above gate connection electrode may be referred to as the fourth gate connection electrode.

In an exemplary implementation, the gate connection electrodes in the first N-type transistor unit may include the fourteenth connection electrode 614, the gate connection electrodes in the second N-type transistor unit may include a fifteenth connection electrode 615, the gate connection electrodes in the third N-type transistor unit may include the forty-third connection electrode 643, and the above gate connection electrodes may be referred to as fifth gate connection electrodes.

In an exemplary implementation, the sixteenth connection electrode 616 may be in a shape of a strip extending along the second direction Y, a first end of the sixteenth connection electrode 616 is connected to the first power supply line 51, and a second end of the sixteenth connection electrode 616 is connected to the first P-type source region through a plurality of first via holes V1, thereby achieving that the first power supply line 51 writes the first power supply signal to a first electrode (a source electrode) of the first P-type transistor P1.

In an exemplary implementation, the seventeenth connection electrode 617 may be in a shape of a strip extending along the second direction Y, a first end of the seventeenth connection electrode 617 is connected to the first P-type drain region through the second via hole V2, a second end of the seventeenth connection electrode 617 is connected to the first N-type drain region through the fourth via hole V4, so that the seventeenth connection electrode 617 achieves a mutual connection between a second electrode (a drain electrode) of the first P-type transistor P1 and a second electrode (a drain electrode) of the first N-type transistor N1.

In an exemplary implementation, a first bump k1 is connected to the seventeenth connection electrode 617, and the first bump k1 is configured to be connected to a first signal transfer line formed subsequently.

In an exemplary implementation, the eighteenth connection electrode 618 may be in a shape of a strip extending along the second direction Y, a first end of the eighteenth connection electrode 618 is connected to the ground line 53, and a second end of the eighteenth connection electrode 618 is connected to the first N-type source region through the third via hole V3, thereby achieving the grounding of the first electrode (the source electrode) of the first N-type transistor N1.

In an exemplary implementation, the nineteenth connection electrode 619 may be in a shape of a strip extending along the second direction Y, a first end of the nineteenth connection electrode 619 is connected to the first power supply line 51, and a second end of the nineteenth connection electrode 619 is connected to the second P-type source region through a plurality of fifth via holes V5, thereby achieving that the first power supply line 51 writes the first power supply signal to a first electrode (a source electrode) of the second P-type transistor P2. In an exemplary implementation, the nineteenth connection electrode 619 may serve as the second P-type source electrode of the present disclosure.

In an exemplary implementation, the twentieth connection electrode 620 may be in a shape of a strip extending along the second direction Y, a first end of the twentieth connection electrode 620 is connected to the first connection line 701, and a second end of the twentieth connection electrode 620 is connected to the second P-type drain region (also the third P-type drain region) through a plurality of sixth via holes V6. In an exemplary implementation, the twentieth connection electrode 620 may simultaneously serve as the second P-type drain electrode and the third P-type drain electrode of the present disclosure.

In an exemplary implementation, the twenty-first connection electrode 621 may be in a shape of a strip extending along the second direction Y, a first end of the twenty-first connection electrode 621 is connected to the first power supply line 51, and a second end of the twenty-first connection electrode 621 is connected to the third P-type source region (also the fourth P-type source region) through a plurality of seventh via holes V7, thereby achieving the first power supply line 51 writes the first power supply signal to a first electrode (a source electrode) of the third P-type transistor P3 and a first electrode (a source electrode) of the fourth P-type transistor P4. In an exemplary implementation, the twenty-first connection electrode 621 may simultaneously serve as the third P-type source electrode and the fourth P-type source electrode of the present disclosure.

In an exemplary implementation, the twenty-second connection electrode 622 may be in a shape of a strip extending along the second direction Y, a first end of the twenty-second connection electrode 622 is connected to the first connection line 701, and a second end of the twenty-second connection electrode 622 is connected to the fourth P-type drain region (also the fifth P-type drain region) through a plurality of eighth via holes V8. In an exemplary implementation, the twenty-second connection electrode 622 may simultaneously serve as the fourth P-type drain electrode and the fifth P-type drain electrode of the present disclosure.

In an exemplary implementation, the twenty-third connection electrode 623 may be in a shape of a strip extending along the second direction Y, a first end of the twenty-third connection electrode 623 is connected to the first power supply line 51, and a second end of the twenty-third connection electrode 623 is connected to the fifth P-type source region (also the sixth P-type source region) through a plurality of ninth via holes V9, thereby achieving that the first power supply line 51 writes the first power supply signal to a first electrode (a source electrode) of the fifth P-type transistor P5 and a first electrode (a source electrode) of the sixth P-type transistor P6. In an exemplary implementation, the twenty-third connection electrode 623 may simultaneously serve as the fifth P-type source electrode and the sixth P-type source electrode of the present disclosure.

In an exemplary implementation, the twenty-fourth connection electrode 624 may be in a shape of a strip extending along the second direction Y, a first end of the twenty-fourth connection electrode 624 is connected to the first connection line 701, and a second end of the twenty-fourth connection electrode 624 is connected to the sixth P-type drain region (also the seventh P-type drain region) through a plurality of tenth via holes V10. In an exemplary implementation, the twenty-fourth connection electrode 624 may simultaneously serve as the sixth P-type drain electrode and the seventh P-type drain electrode of the present disclosure.

In an exemplary implementation, the twenty-fifth connection electrode 625 may be in a shape of a strip extending along the second direction Y, a first end of the twenty-fifth connection electrode 625 is connected to the first power supply line 51, and a second end of the twenty-fifth connection electrode 625 is connected to the seventh P-type source region (also the eighth P-type source region) through a plurality of eleventh via holes V11, thereby achieving that the first power supply line 51 writes the first power supply signal to a first electrode (a source electrode) of the seventh P-type transistor P7 and a first electrode (a source electrode) of the eighth P-type transistor P8. In an exemplary implementation, the twenty-fifth connection electrode 625 may simultaneously serve as the seventh P-type source electrode and the eighth P-type source electrode of the present disclosure.

In an exemplary implementation, the twenty-sixth connection electrode 626 may be in a shape of a strip extending along the second direction Y, a first end of the twenty-sixth connection electrode 626 is connected to the second connection line 702, and a second end of the twenty-sixth connection electrode 626 is connected to the eighth P-type drain region (also the ninth P-type drain region) through a plurality of twelfth via holes V12. In an exemplary implementation, the twenty-sixth connection electrode 626 may simultaneously serve as the eighth P-type drain electrode and the ninth P-type drain electrode of the present disclosure.

In an exemplary implementation, the twenty-seventh connection electrode 627 may be in a shape of a strip extending along the second direction Y, a first end of the twenty-seventh connection electrode 627 is connected to the first power supply line 51, and a second end of the twenty-seventh connection electrode 627 is connected to the ninth P-type source region (also the tenth P-type source region) through a plurality of thirteenth via holes V13, thereby achieving the first power supply line 51 writes the first power supply signal to a first electrode (a source electrode) of the ninth P-type transistor P9 and a first electrode (a source electrode) of the tenth P-type transistor P10. In an exemplary implementation, the twenty-seventh connection electrode 627 may simultaneously serve as the ninth P-type source electrode and the tenth P-type source electrode of the present disclosure.

In an exemplary implementation, the twenty-eighth connection electrode 628 may be in a shape of a strip extending along the second direction Y, a first end of the twenty-eighth connection electrode 628 is connected to the second connection line 702, and a second end of the twenty-eighth connection electrode 628 is connected to the tenth P-type drain region (also the eleventh P-type drain region) through a plurality of fourteenth via holes V14. In an exemplary implementation, the twenty-eighth connection electrode 628 may simultaneously serve as the tenth P-type drain electrode and the eleventh P-type drain electrode of the present disclosure.

In an exemplary implementation, the twenty-ninth connection electrode 629 may be in a shape of a strip extending along the second direction Y, a first end of the twenty-ninth connection electrode 629 is connected to the first power supply line 51, and a second end of the twenty-ninth connection electrode 629 is connected to the eleventh P-type source region (also the twelfth P-type source region) through a plurality of fifteenth via holes V15, thereby achieving the first power supply line 51 writes the first power supply signal to a first electrode (a source electrode) of the eleventh P-type transistor P11 and a first electrode (a source electrode) of the twelfth P-type transistor P12. In an exemplary implementation, the twenty-ninth connection electrode 629 may simultaneously serve as the eleventh P-type source electrode and the twelfth P-type source electrode of the present disclosure.

In an exemplary implementation, the thirtieth connection electrode 630 may be in a shape of a strip extending along the second direction Y, a first end of the thirtieth connection electrode 630 is connected to the second connection line 702, and a second end of the thirtieth connection electrode 630 is connected to the twelfth P-type drain region (also the thirteenth P-type drain region) through a plurality of sixteenth via holes V16. In an exemplary implementation, the thirtieth connection electrode 630 may simultaneously serve as the twelfth P-type drain electrode and the thirteenth P-type drain electrode of the present disclosure.

In an exemplary implementation, the thirty-first connection electrode 631 may be in a shape of a strip extending along the second direction Y, a first end of the thirty-first connection electrode 631 is connected to the first power supply line 51, and a second end of the thirty-first connection electrode 631 is connected to the thirteenth P-type source region through a plurality of seventeenth via holes V17, thereby achieving that the first power supply line 51 writes the first power supply signal to a first electrode (a source electrode) of the thirteenth P-type transistor P13. In an exemplary implementation, the thirty-first connection electrode 631 may serve as the thirteenth P-type source electrode of the present disclosure.

In an exemplary implementation, the nineteenth connection electrode 619 to the thirty-first connection electrode 631 may be disposed sequentially along the first direction X, and positions and shapes of the plurality of connection electrodes may be disposed symmetrically with respect to the active center line O.

In an exemplary implementation, the first electrode of the second P-type transistor P2 (the first P-type source electrode) to the first electrode of the seventh P-type transistor P7 (the seventh P-type source electrode) in the first P-type transistor unit and the first electrode of the eighth P-type transistor P8 (the eighth P-type source electrode) to the first electrode of the thirteenth P-type transistor P13 (the thirteenth P-type source electrode) in the second P-type transistor unit are symmetrically disposed with respect to the active center line O, and the first electrode of the second P-type transistor P2 (the first P-type drain electrode) to the second electrode of the seventh P-type transistor P7 (the seventh P-type drain electrode) in the first P-type transistor unit and the first electrode of the eight P-type transistor P8 (the eighth P-type drain electrode) to the second electrode of the thirteenth P-type transistor P13 (the thirteenth P-type drain electrode) in the second P-type transistor unit are symmetrically disposed with respect to the active center line O, which may ensure the symmetry of the P-type transistor units in the level converter and improve the consistency of outputting high and low levels.

In the exemplary implementation, a length of the nineteenth connection electrode 619 and a length of the thirty-first connection electrode 631 are equal, a width of the nineteenth connection electrode 619 and a width of the thirty-first connection electrode 631 are equal, and contact areas of the two connection electrodes connected to the active region through a via hole are equal; and there is an eleventh length LP11 between an edge of the nineteenth connection electrode 619 on a side away from the active center line O and the active center line O, there is a twelfth length LP12 between an edge of the thirty-first connection electrode 631 on a side away from the active center line O and the active center line O, and a ratio of the eleventh length LP11 to the twelfth length LP12 may be about 0.95 to 1.05.

In an exemplary implementation, the eleventh length LP11 and the twelfth length LP12 may be substantially equal.

In an exemplary implementation, a length of the twentieth connection electrode 620 and a length of the thirtieth connection electrode 630 are equal, a width of the twentieth connection electrode 620 and a width of the thirtieth connection electrode 630 are equal, and contact areas of the two connection electrodes connected to the active region through a via hole are equal; and there is an eleventh sub-length LP111 between an edge of the twentieth connection electrode 620 on a side away from the active center line O and the active center line O, there is a twelfth sub-length LP112 between an edge of the thirtieth connection electrode 630 on a side away from the active center line O and the active center line O, and a ratio of the eleventh sub-length LP111 to the twelfth sub-length LP112 may be about 0.95 to 1.05.

In an exemplary implementation, the eleventh sub-length LP111 and the twelfth sub-length LP112 may be substantially equal.

In an exemplary embodiment, a length of the twenty-first connection electrode 621 and a length of the twenty-ninth connection electrode 629 are equal, a width of the twenty-first connection electrode 621 and a width of the twenty-ninth connection electrode 629 are equal, and contact areas of the two connection electrodes connected to the active region through a via hole are equal; and there is a thirteenth sub-length LP113 between an edge of the twenty-first connection electrode 621 on a side away from the active center line O and the active center line O, and there is a fourteenth sub-length LP114 between an edge of the twenty-ninth connection electrode 629 on a side away from the active center line O and the active center line O, and a ratio of the thirteenth sub-length LP113 to the fourteenth sub-length LP114 may be about 0.95 to 1.05.

In an exemplary implementation, the thirteenth sub-length LP113 and the fourteenth sub-length LP114 may be substantially equal.

In an exemplary implementation, a length of the twenty-second connection electrode 622 and a length of the twenty-eighth connection electrode 628 are equal, a width of the twenty-second connection electrode 622 and a width of the twenty-eighth connection electrode 628 are equal, and contact areas of the two connection electrodes connected to the active region through a via hole are equal; and there is an fifteenth sub-length LP115 between an edge of the twenty-second connection electrode 622 on a side away from the active center line O and the active center line O, there is a sixteenth sub-length LP116 between an edge of the twenty-eighth connection electrode 628 on a side away from the active center line O and the active center line O, and a ratio of the fifteenth sub-length LP115 and the sixteenth sub-length LP116 may be about 0.95 to 1.05.

In an exemplary implementation, the fifteenth sub-length LP 115 and the sixteenth sub-length LP 116 may be substantially equal.

In an exemplary implementation, a length of the twenty-third connection electrode 623 and a length of the twenty-seventh connection electrode 627 are equal, a width of the twentieth connection electrode 623 and a width of the twenty-seventh connection electrode 627 are equal, and contact areas of the two connection electrodes connected to the active region through a via hole are equal; and there is an seventeenth sub-length LP117 between an edge of the twenty-third connection electrode 623 on a side away from the active center line O and the active center line O, there is an eighteenth sub-length LP118 between an edge of the twenty-seventh connection electrode 627 on a side away from the active center line O and the active center line O, and a ratio of the eleventh sub-length LP117 to the eighteenth sub-length LP118 may be about 0.95 to 1.05.

In an exemplary implementation, the seventeenth sub-length LP117 and the eighteenth sub-length LP118 may be substantially equal.

In an exemplary implementation, a length of the twenty-fourth connection electrode 624 and a length of the twenty-sixth connection electrode 626 are equal, a width of the twenty-fourth connection electrode 624 and a width of the twenty-sixth connection electrode 626 are equal, and contact areas of the two connection electrodes connected to the active region through a via hole are equal; and there is an nineteenth sub-length LP119 between an edge of the twenty-fourth connection electrode 624 on a side away from the active center line O and the active center line O, there is a twentieth sub-length LP120 between an edge of the twenty-sixth connection electrode 626 on a side away from the active center line O and the active center line O, and a ratio of the nineteenth sub-length LP119 and the twentieth sub-length LP120 may be about 0.95 to 1.05.

In an exemplary implementation, the nineteenth sub-length LP 119 and the twentieth sub-length LP 120 may be substantially equal.

In an exemplary implementation, the twenty-fifth connection electrode 625 may be disposed symmetrically with respect to the active center line O, that is, a length between the edges on both sides of the twenty-fifth connection electrode 625 and the active center line O may be equal.

In an exemplary implementation, the thirty-second connection electrode 632 may be in a shape of a strip extending along the second direction Y, a first end of the thirty-second connection electrode 632 is connected to the first connection line 701, and a second end of the thirty-second connection electrode 632 is connected to the second N-type drain region through the eighteenth via hole V18. In an exemplary implementation, the thirty-second connection electrode 632 may serve as the second N-type drain electrode of the present disclosure.

In an exemplary implementation, the thirty-third connection electrode 633 may be in a shape of a strip extending along the second direction Y, a first end of the thirty-third connection electrode 633 is connected to the second power supply line 52, and a second end of the thirty-third connection electrode 633 is connected to the second N-type source region (also the third N-type source region) through the nineteenth via hole V19, thereby achieving the second power supply line 52 writes the second power supply signal to a first electrode (a source electrode) of the second N-type transistor N2 and a first electrode (a source electrode) of the third N-type transistor N3. In an exemplary implementation, the thirty-third connection electrode 633 may simultaneously serve as the second N-type source electrode and the third N-type source electrode of the present disclosure.

In an exemplary implementation, the thirty-fourth connection electrode 634 may be in a shape of a strip extending along the second direction Y, a first end of the thirty-fourth connection electrode 634 is connected to the second connection line 702, and a second end of the thirty-fourth connection electrode 634 is connected to the third N-type drain region through the twentieth via hole V20. In an exemplary implementation, the thirty-fourth connection electrode 634 may serve as the third N-type drain electrode of the present disclosure.

In an exemplary implementation, the thirty-second connection electrode 632 and the thirty-fourth connection electrode 634 may be disposed sequentially along the first direction X, and the two connection electrodes may be disposed symmetrically with respect to the active center line O.

In an exemplary implementation, the second electrode of the second N-type transistor N2 (the second N-type drain electrode) in the first N-type transistor unit and the second electrode of the third N-type transistor N3 (the third N-type drain electrode) in the second N-type transistor unit are symmetrically arranged with respect to the active center line O, which may ensure the symmetry of the N-type transistor unit in the level converter and improve the consistency of outputting high and low levels.

In an exemplary implementation, a length of the thirty-second connection electrode 632 and a length of the thirty-fourth connection electrode 634 are equal, a width of the thirty-second connection electrode 632 and a width of the thirty-fourth connection electrode 634 are equal, and contact areas of the two connection electrodes connected to the active region through a via hole are equal; and there is an thirteenth sub-length LN13 between an edge of the thirty-second connection electrode 632 on a side away from the active center line O and the active center line O, there is a fourteenth sub-length LN14 between an edge of the thirty-fourth connection electrode 634 on a side away from the active center line O and the active center line O, and a ratio of the thirteenth sub-length LN13 to the fourteenth sub-length LN14 may be about 0.95 to 1.05.

In an exemplary implementation, the thirteenth length LN13 and the fourteenth length LN14 may be substantially equal.

In an exemplary implementation, the thirty-third connection electrode 633 may be disposed symmetrically with respect to the active center line O, that is, a length between the edges on both sides of the thirty-third connection electrode 633 and the active center line O may be equal.

In an exemplary implementation, the first connection line 701 may be in a shape of a strip extending along the first direction X, the first connection line 701 is respectively connected to the twentieth connection electrode 620, the twenty-second connection electrode 622, the twenty-fourth connection electrode 624, and the thirty-second connection electrode 632, and the first connection line 701 achieves a mutual connection between the second electrode of the second P-type transistor P2, the second electrode of the third P-type transistor P3, the second electrode of the fourth P-type transistor P4, the second electrode of the fifth P-type transistor P5, the second electrode of the sixth P-type transistor P6, the second electrode of the seventh P-type transistor P7, and the second electrode of the second N-type transistor N2.

In an exemplary implementation, the first connection line 701 may be located in the gap region 50 and located on a side of the gap region 50 close to the second N-type active region. An orthographic projection of the first connection line 701 on the silicon base substrate is not overlapped with orthographic projections of the P-type gate electrodes of the second P-type transistor P2 to the seventh P-type transistor P7 on the silicon base substrate, and the orthographic projection of the first connection line 701 on the silicon base substrate is not overlapped with an orthographic projection of the N-type gate electrode of the second N-type transistor N2 on the silicon base substrate, which may reduce the influence on the transistor channel region.

In an exemplary implementation, the second connection line 702 may be in a shape of a strip extending along the first direction X and is respectively connected to the fourteenth connection electrode 614, the twenty-sixth connection electrode 626, the twenty-eighth connection electrode 628, the thirtieth connection electrode 630, and the thirty-fourth connection electrode 634. The second connection line achieves a mutual connection between the N-type gate electrode of the second N-type transistor N2, the second electrode of the eighth P-type transistor P8, the second electrode of the ninth P-type transistor P9, the second electrode of the tenth P-type transistor P10, the second electrode of the eleventh P-type transistor P11, the second electrode of the twelfth P-type transistor P12, the second electrode of the thirteenth P-type transistor P13, and the second electrode of the third N-type N3.

In an exemplary implementation, the second connection line 702 may be located in the gap region 50 and located on a side of the gap region 50 close to the third N-type active region. An orthographic projection of the second connection line 702 on the silicon base substrate is not overlapped with orthographic projections of the P-type gate electrodes of the eighth P-type transistor P8 to the thirteenth P-type transistor P13 on the silicon base substrate, and the orthographic projection of the second connection line 702 on the silicon base substrate is not overlapped with an orthographic projection of the N-type gate electrode of the third N-type transistor N3 on the silicon base substrate, which may reduce the influence on the transistor channel region.

In an exemplary implementation, there is a voltage domain distance LY between an edge of the seventeenth connection electrode 617 on a side close to the nineteenth connection electrode 619 and an edge of the nineteenth connection electrode 619 on a side close to the seventeenth connection electrode 617.

In an exemplary implementation, the voltage domain distance LY may be greater than or equal to 3.67 μm.

In an exemplary implementation, in the level converter, the inverter is in a first voltage domain and the four transistor units are in a second voltage domain, and the first voltage domain is different from the second voltage domain. Research shows that there is an interaction between the transistors in the first voltage domain and the transistors in the second voltage domain, and the strength of the interaction is affected by the distance between the transistors. In the present disclosure, the minimum distance between the transistors in the two voltage domains is set to be 3.67 μm, which may reduce a mutual influence between the transistors in the two voltage domains, and improve the stability of the level converter circuit.

In an exemplary implementation, the thirty-fifth connection electrode 635 may be in a shape of a block (a rectangle), and the thirty-fifth connection electrode 635 is connected to the twenty-first P-type gate electrode 221 P (also the twenty-first N-type gate electrode 221 N) through the sixty-sixth via hole V 66.

In an exemplary implementation, the thirty-sixth connection electrode 636 may be in a shape of a block (a rectangle), the thirty-sixth connection electrode 636 is connected to the twenty-second P-type gate electrode 222P (also the twenty-second N-type gate electrode 222N) through the sixty-seventh via hole V67, and the thirty-sixth connection electrode 636 is configured to be connected to a second signal line formed subsequently.

In an exemplary implementation, the thirty-seventh connection electrode 637 may be in a shape of a block (a rectangle), the thirty-seventh connection electrode 637 is connected to the twenty-third P-type gate electrode 223 P through the sixty-eighth via hole V68, and the thirty-seventh connection electrode 637 is simultaneously connected to the seventy-fifth connection electrode 675.

In an exemplary implementation, the thirty-eighth connection electrode 638 may be in a shape of a block (a rectangle), the thirty-eighth connection electrode 638 is connected to the twenty-third N-type gate electrode 223 N through the sixty-ninth via hole V69, and the thirty-eighth connection electrode 638 is simultaneously connected to the seventy-fourth connection electrode 674.

In an exemplary implementation, the thirty-ninth connection electrode 639 may be in a shape of a block (a rectangle), and the thirty-ninth connection electrode 639 is connected to the twenty-fourth P-type gate electrode 224 P (also the twenty-fourth N-type gate electrode 224 N) through the seventieth via hole V 70.

In an exemplary implementation, the fortieth connection electrode 640 may be in a shape of a block (a rectangle), the fortieth connection electrode 640 is connected to the twenty-fifth P-type gate electrode 225 P (also the twenty-fifth N-type gate electrode 225 N) through the seventy-first via hole V71, and the fortieth connection electrode 640 is configured to be connected to a second signal line formed subsequently.

In an exemplary implementation, the forty-first connection electrode 641 may be in a shape of a block (a rectangle), the forty-first connection electrode 641 is connected to the twenty-sixth P-type gate electrode 226 P (also the twenty-sixth N-type gate electrode 226 N) through the seventy-second via hole V72, and the forty-first connection electrode 641 is connected to the fourth connection line 704.

In an exemplary implementation, the forty-second connection electrode 642 may be in a shape of a strip extending along the first direction, the forty-second connection electrode 642 is sequentially connected to the twenty-seventh P-type gate electrode 227P through the seventy-third via hole V73, connected to the twenty-eighth P-type gate electrode 228P through the seventy-fourth via hole V74, connected to the twenty-ninth P-type gate electrode 229P through the seventy-fifth via hole V75, and connected to the thirtieth P-type gate electrode 230P through the seventy-sixth via hole V76. The forty-second connection electrode 642 is configured to be connected to a fourth signal transfer line, and achieves a mutual connection between the gate electrode of the twenty-seventh P-type transistor P27, the gate electrode of the twenty-eighth P-type transistor P28, the gate electrode of the twenty-ninth P-type transistor P29, and the gate electrode of the thirtieth P-type transistor P30.

In an exemplary implementation, the forty-third connection electrode 643 may be in a shape of a strip extending along the first direction, the forty-third connection electrode 643 is sequentially connected to the twenty-seventh N-type gate electrode 227N through the seventy-seventh via hole V77, connected to the twenty-eighth N-type gate electrode 228N through the seventy-eighth via hole V78, connected to the twenty-ninth N-type gate electrode 229N through the seventy-ninth via hole V79, and connected to the thirtieth N-type gate electrode 230N through the eightieth via hole V80. The forty-third connection electrode 643 is configured to be connected to a fifth signal transfer line formed subsequently, and achieves a mutual connection between the gate electrode of the twenty-seventh N-type transistor N27, the gate electrode of the twenty-eighth N-type transistor N28, the gate electrode of the twenty-ninth N-type transistor N29, and the gate electrode of the thirtieth N-type transistor N30.

In an exemplary implementation, the forty-fourth connection electrode 644 may be in a shape of a strip extending along the second direction Y, a first end of the forty-fourth connection electrode 644 is connected to the first power supply line 51, and a second end of the forty-fourth connection electrode 644 is connected to the twenty-first P-type source region through a plurality of twenty-first via holes V21, thereby achieving that the first power supply line 51 writes the first power supply signal to a first electrode (a source electrode) of the twenty-first P-type transistor P21.

In an exemplary implementation, the forty-fifth connection electrode 645 may be in a shape of a strip extending along the second direction Y, a first end of the forty-fifth connection electrode 645 is connected to the third connection line 703, and a second end of the forty-fifth connection electrode 645 is connected to the twenty-first P-type drain region (also the twenty-second P-type drain region) through a plurality of twenty-second via holes V22.

In an exemplary implementation, the forty-sixth connection electrode 646 may be in a shape of a strip extending along the second direction Y, a first end of the forty-sixth connection electrode 646 is connected to the first power supply line 51, and a second end of the forty-sixth connection electrode 646 is connected to the twenty-second P-type source region through a plurality of twenty-third via holes V23, thereby achieving that the first power supply line 51 writes the first power supply signal to a first electrode (a source electrode) of the twenty-second P-type transistor P22.

In an exemplary implementation, the forty-seventh connection electrode 647 may be in a shape of a strip extending along the second direction Y, a first end of the forty-seventh connection electrode 647 is connected to the third connection line 703, and a second end of the forty-seventh connection electrode 647 is connected to the twenty-third P-type source region through a plurality of twenty-fourth via hole V24.

In an exemplary implementation, the forty-eighth connection electrode 648 may be in a shape of a strip extending along the second direction Y, and the forty-eighth connection electrode 648 is connected to the twenty-third P-type drain region through a plurality of twenty-fifth via holes V25.

In an exemplary implementation, a second bump k2 is connected to the forty-eighth connection electrode 648, and the second bump k2 is configured to be connected to a third signal transfer line formed subsequently.

In an exemplary implementation, the forty-ninth connection electrode 649 may be in a shape of a strip extending along the second direction Y, a first end of the forty-ninth connection electrode 649 is connected to the first power supply line 51, a second end of the forty-ninth connection electrode 649 is connected to the twenty-fourth P-type source region through a plurality of twenty-sixth via holes V26, and the forty-ninth connection electrode 649 achieves that the first power supply line 51 writes the first power supply signal to a first electrode (a source electrode) of the twenty-fourth P-type transistor P24.

In an exemplary implementation, the fiftieth connection electrode 650 may be in a shape of a strip extending along the second direction Y, a first end of the fiftieth connection electrode 650 is connected to the fourth connection line 704, and a second end of the fiftieth connection electrode 650 is connected to the twenty-fourth P-type drain region (also the twenty-fifth P-type drain region) through a plurality of twenty-seventh via holes V27.

In an exemplary implementation, the fifty-first connection electrode 651 may be in a shape of a strip extending along the second direction Y, a first end of the fifty-first connection electrode 651 is connected to the first power supply line 51, and a second end of the fifty-first connection electrode 651 is connected to the twenty-fifth P-type source region through a plurality of twenty-eighth via holes V28, thereby achieving that the first power supply line 51 writes the first power supply signal to a first electrode (a source electrode) of the twenty-fifth P-type transistor P25.

In an exemplary implementation, the fifty-second connection electrode 652 may be in a shape of a strip extending along the second direction Y, a first end of the fifty-second connection electrode 652 is connected to the first power supply line 51, and a second end of the fifty-second connection electrode 652 is connected to the twenty-sixth P-type source region through a plurality of twenty-ninth via holes V29, thereby achieving that the first power supply line 51 writes the first power supply signal to a first electrode (a source electrode) of the twenty-sixth P-type transistor P26.

In an exemplary implementation, the fifty-third connection electrode 653 may be in a shape of a strip extending along the second direction Y, a first end of the fifty-third connection electrode 653 is connected to the forty-third connection electrode 643, and a second end of the fifty-third connection electrode 653 is connected to the twenty-sixth P-type drain region through a plurality of thirtieth via holes V30. Since the forty-third connection electrode 643 is respectively connected to the gate electrode of the twenty-seventh N-type transistor N27, the gate electrode of the twenty-eighth N-type transistor N28, the gate electrode of the twenty-ninth N-type transistor N29, and the gate electrode of the thirtieth N-type transistor N30, a mutual connection between the second electrode (the drain electrode) of the twenty-sixth P-type transistor P26, the gate electrode of the twenty-seventh N-type transistor N27, the gate electrode of the twenty-eighth N-type transistor N28, the gate electrode of the twenty-eighth N-type transistor N28, and the gate electrode of the twenty-ninth N-type transistor N29, and the gate electrode of the thirtieth N-type transistor N30 is achieved.

In an exemplary implementation, the fifty-fourth connection electrode 654 may be in a strip in which the main body portion extends along the second direction Y, and the fifty-fourth connection electrode 654 is connected to the twenty-seventh P-type drain region through a plurality of thirty-first via holes V31.

In an exemplary implementation, a third bump k3 is connected to the fifty-fourth connection electrode 654, and the third bump k3 is configured to be connected to a fourth signal transfer line formed subsequently.

In an exemplary implementation, the fifty-fifth connection electrode 655 may be in a shape of a strip extending along the second direction Y, a first end of the fifty-fifth connection electrode 655 is connected to the first power supply line 51, and a second end of the fifty-fifth connection electrode 655 is connected to the twenty-seventh P-type source region (also the twenty-eighth P-type source region) through a plurality of thirty-second via holes V32, thereby achieving the first power supply line 51 writes the first power supply signal to a first electrode (a source electrode) of the twenty-seventh P-type transistor P27 and a first electrode (a source electrode) of the twenty-eighth P-type transistor P8.

In an exemplary implementation, the fifty-sixth connection electrode 656 may be in a shape of a strip in which the main body portion extends along the second direction Y, and the fifty-sixth connection electrode 656 is connected to the twenty-eighth P-type drain region (also the twenty-ninth P-type drain region) through a plurality of thirty-third via holes V33.

In an exemplary implementation, a fourth bump k4 is connected to the fifty-fourth connection electrode 654, and the fourth bump k4 is configured to be connected to a fourth signal transfer line formed subsequently.

In an exemplary implementation, the fifty-seventh connection electrode 657 may be in a shape of a strip extending along the second direction Y, a first end of the fifty-seventh connection electrode 657 is connected to the first power supply line 51, and a second end of the fifty-seventh connection electrode 657 is connected to the twenty-ninth P-type source region (also the thirtieth P-type source region) through a plurality of thirty-fourth via holes V34, thereby achieving the first power supply line 51 writes the first power supply signal to a first electrode (a source electrode) of the twenty-ninth P-type transistor P29 and a first electrode (a source electrode) of the thirtieth P-type transistor P30.

In an exemplary implementation, the fifty-eighth connection electrode 658 may be in a shape of a strip extending along the second direction Y, and the fifty-eighth connection electrode 658 is connected to the thirtieth P-type drain region through a plurality of thirty-fifth via holes V35.

In an exemplary implementation, a fifth bump k5 is connected to the fifty-fourth connection electrode 654, and the fifth bump k5 is configured to be connected to a fourth signal transfer line formed subsequently.

In an exemplary implementation, the fifty-ninth connection electrode 659 may be in a shape of a strip extending along the second direction Y, a first end of the fifty-ninth connection electrode 659 is connected to the third connection line 703, and a second end of the fifty-ninth connection electrode 659 is connected to the twenty-first N-type drain region through a plurality of thirty-sixth via holes V36.

In an exemplary implementation, the sixtieth connection electrode 660 may be in a shape of a strip extending along the second direction Y, and the sixtieth connection electrode 660 is connected to the twenty-first N-type source region (also the twenty-second N-type drain region) through a plurality of thirty-seventh via holes V37.

In an exemplary implementation, the sixty-first connection electrode 661 may be in a shape of a strip extending along the second direction Y, a first end of the sixty-first connection electrode 661 is connected to the second power supply line 52, and a second end of the sixty-first connection electrode 661 is connected to the twenty-second N-type source region through a plurality of thirty-eighth via holes V38, thereby achieving that the second power supply line 52 writes the second power supply signal to a first electrode (a source electrode) of the twenty-second N-type transistor N22.

In an exemplary implementation, the sixty-second connection electrode 662 may be in a shape of a strip extending along the second direction Y, a first end of the sixty-second connection electrode 662 is connected to the third connection line 703, and a second end of the sixty-second connection electrode 662 is connected to the twenty-third N-type source region through a plurality of thirty-ninth via hole V39.

In an exemplary implementation, the sixty-third connection electrode 663 may be in a shape of a strip extending along the second direction Y, a first end of the sixty-third connection electrode 663 is connected to the forty-eighth connection electrode 648, and a second end of the sixty-third connection electrode 663 is connected to the twenty-third N-type drain region through a plurality of fortieth via holes V40, thereby achieving a mutual connection between the second electrode of the twenty-third P-type transistor P23 and the second electrode of the twenty-third N-type transistor N23.

In an exemplary implementation, the sixty-fourth connection electrode 664 may be in a shape of a strip extending along the second direction Y, a first end of the sixty-fourth connection electrode 664 is connected to the fourth connection line 704, and a second end of the sixty-fourth connection electrode 664 is connected to the twenty-fourth N-type drain region through a plurality of forty-first via hole V41.

In an exemplary implementation, the sixty-fifth connection electrode 665 may be in a shape of a strip extending along the second direction Y, and is connected to the twenty-fourth N-type source region (also the twenty-fifth N-type drain region) through a plurality of forty-second via holes V42.

In an exemplary implementation, the sixty-sixth connection electrode 666 may be in a shape of a strip extending along the second direction Y, a first end of the sixty-sixth connection electrode 666 is connected to the second power supply line 52, and a second end of the sixty-sixth connection electrode 666 is connected to the twenty-fifth N-type source region through a plurality of forty-third via holes V43, thereby achieving that the second power supply line 52 writes the second power supply signal to a first electrode (a source electrode) of the twenty-fifth N-type transistor N25.

In an exemplary implementation, the sixty-seventh connection electrode 667 may be in a shape of a strip extending along the second direction Y, a first end of the sixty-seventh connection electrode 667 is connected to the second power supply line 52, and a second end of the sixty-seventh connection electrode 667 is connected to the twenty-sixth N-type source region through the forty-fourth via holes V44, thereby achieving that the second power supply line 52 writes the second power supply signal to a first electrode (a source electrode) of the twenty-sixth N-type transistor N26.

In an exemplary implementation, the sixty-eighth connection electrode 668 may be in a shape of a strip extending along the second direction Y, a first end of the sixty-eighth connection electrode 668 is connected to the forty-third connection electrode 643, and a second end of the sixty-eighth connection electrode 668 is connected to the twenty-sixth N-type drain region through the forty-fifth via hole V45.

In the exemplary implementation, since the fifty-third connection electrode 653 and the sixty-eighth connection electrode 668 are both connected to the forty-third connection electrode 643, a mutual connection between the gate electrode of the twenty-seventh N-type transistor N27, the gate electrode of the twenty-eighth N-type transistor N28, the gate electrode of the twenty-ninth N-type transistor N29, the gate electrode of the thirtieth N-type transistor N30, the second electrode of the twenty-sixth P-type transistor P26, and the second electrode of the twenty-sixth N-type transistor N26 is achieved.

In an exemplary implementation, the forty-third connection electrode 643, the fifty-third connection electrode 653, and the sixty-eighth connection electrode 668 may be of an integral structure connected to each other.

In an exemplary implementation, the sixty-ninth connection electrode 669 may be in a shape of a strip in which the main body portion extends along the second direction Y, and the sixty-ninth connection electrode 669 is connected to the twenty-seventh N-type drain region through a plurality of forty-sixth via holes V46.

In an exemplary implementation, a sixth bump k6 is connected to the sixty-ninth connection electrode 669, and the sixth bump k6 is configured to be connected to a fifth signal transfer line formed subsequently.

In an exemplary implementation, the seventieth connection electrode 670 may be in a shape of a strip extending along the second direction Y, a first end of the seventieth connection electrode 670 is connected to the second power supply line 52, and a second end of the seventieth connection electrode 670 is connected to the twenty-seventh N-type source region (also the twenty-eighth N-type source region) through a plurality of forty-seventh via hole V47, thereby achieving the second power supply line 52 writes the second power supply signal to a first electrode (a source electrode) of the twenty-seventh N-type transistor N27 and a first electrode (a source electrode) of the twenty-eighth N-type transistor N28.

In an exemplary implementation, the seventy-first connection electrode 671 may be in a shape of a strip in which the main body portion extends along the second direction Y, and the seventy-first connection electrode 671 is connected to the twenty-eighth N-type drain region (also the twenty-ninth N-type drain region) through a plurality of forty-eighth via holes V48.

In an exemplary implementation, a seventh bump k7 is connected to the seventy-first connection electrode 671, and the seventh bump k7 is configured to be connected to a fifth signal transfer line formed sequentially.

In an exemplary implementation, the seventy-second connection electrode 672 may be in a shape of a strip extending along the second direction Y, a first end of the seventy-second connection electrode 672 is connected to the second power supply line 52, and a second end of the seventy-second connection electrode 672 is connected to the twenty-ninth N-type source region (also the thirtieth N-type source region) through a plurality of forty-ninth via hole V49, thereby achieving the second power supply line 52 writes the second power supply signal to a first electrode (a source electrode) of the twenty-ninth N-type transistor N29 and a first electrode (a source electrode) of the thirtieth N-type transistor N30.

In an exemplary implementation, the seventy-third connection electrode 673 may be in a shape of a strip extending along the second direction Y, a first end of the seventy-third connection electrode 673 is connected to the fifty-eighth connection electrode 658, and a second end of the seventy-third connection electrode 673 is connected to the thirtieth N-type drain region through a plurality of fiftieth via holes V50, thereby achieving a mutual connection between the second electrode (the drain electrode) of the thirtieth P-type transistor P30 and the second electrode (the drain electrode) of the thirtieth N-type transistor N30.

In an exemplary implementation, an eighth bump k8 is connected to the seventy-third connection electrode 673, and the eighth bump k8 is configured to be connected to a fifth signal transfer line formed sequentially.

In an exemplary implementation, the seventy-fourth connection electrode 674 may be in a shape of a strip extending along the second direction Y, a first end of the seventy-fourth connection electrode 674 is connected to the first power supply line 51, and a second end of the seventy-fourth connection electrode 674 is connected to the thirty-eighth connection electrode 638, thereby achieving a connection between the first power supply line 51 and the gate electrode of the twenty-third N-type transistor N23.

In an exemplary implementation, the seventy-fifth connection electrode 675 may be in a shape of a strip extending along the second direction Y, a first end of the seventy-fifth connection electrode 675 is connected to the second power supply line 52, and a second end of the seventy-fifth connection electrode 675 is connected to the thirty-seventh connection electrode 637, thereby achieving a connection between the second power supply line 52 and the gate electrode of the twenty-third P-type transistor P23.

In an exemplary implementation, the third connection line 703 may be in a shape of a strip extending along the first direction X and is respectively connected to the forty-fifth connection electrode 645, the forty-seventh connection electrode 647, the fifty-ninth connection electrode 659, and the sixty-second connection electrode 662, and the third connection line 703 achieves a mutual connection between the second electrode of the twenty-first P-type transistor P21, the second electrode of the twenty-second P-type transistor P22, the second electrode of the twenty-first N-type transistor N21, the first electrode of the twenty-third P-type transistor P23, and the first electrode of the twenty-third N-type transistor N23.

In an exemplary implementation, the forty-fifth connection electrode 645, the forty-seventh connection electrode 647, the fifty-ninth connection electrode 659, the sixty-second connection electrode 662, and the third connection line 703 may be of an integral structure connected to each other.

In an exemplary implementation, the third connection line 703 may be disposed in the gap region 50. An orthographic projection of the third connection line 703 on the silicon base substrate is at least partially overlapped with an orthographic projection of an integral structure of the twenty-first P-type gate electrode 21P and the twenty-first N-type gate electrode 21N. An orthographic projection of the third connection line 703 on the silicon base substrate is at least partially overlapped with an orthographic projection of an integral structure of the twenty-second P-type gate electrode 22P and the twenty-second N-type gate electrode 22N, that is, the third connection line 703 crosses the gate electrodes of two transistor groups (twenty-first P-type transistor P21 and twenty-first N-type transistor N21, twenty-second P-type transistor P22 and twenty-second N-type transistor N22), and is connected to the first transmission gate.

In an exemplary implementation, the fourth connection line 704 may be in a shape of a strip extending along the first direction X and is respectively connected to the forty-first connection electrode 641, the fiftieth connection electrode 650, and the sixty-fourth connection electrode 664, and the fourth connection line 704 achieves a mutual connection between the second electrode of the twenty-fourth P-type transistor P24, the second electrode of the twenty-fourth N-type transistor N24, the second electrode of the twenty-fifth P-type transistor P25, the gate electrode 226 of the twenty-sixth P-type transistor P26, and the gate electrode of the twenty-sixth N-type transistor N26.

In an exemplary implementation, the forty-first connection electrode 641, the fiftieth connection electrode 650, the sixty-fourth connection electrode 664, and the fourth connection line 704 may be of an integral structure connected to each other.

In an exemplary implementation, the fourth connection line 704 may be disposed in the gap region 50. An orthographic projection of the fourth connection line 704 on the silicon base substrate is at least partially overlapped with an orthographic projection of an integral structure of the twenty-fourth P-type gate electrode 24P and the twenty-fourth N-type gate electrode 24N, and is at least partially overlapped with an orthographic projection of an integral structure of the twenty-fifth P-type gate electrode 25P and the twenty-fifth N-type gate electrode 25N, that is, the fourth connection line 704 crosses the gate electrodes of two transistor groups (twenty-fourth P-type transistor P24 and twenty-fourth N-type transistor N24, twenty-fifth P-type transistor P25 and twenty-fifth N-type transistor N25), and is connected to the second inverter.

In an exemplary implementation, the third connection line 703 and the fourth connection line 704 may be located on the same straight line extending along the first direction X.

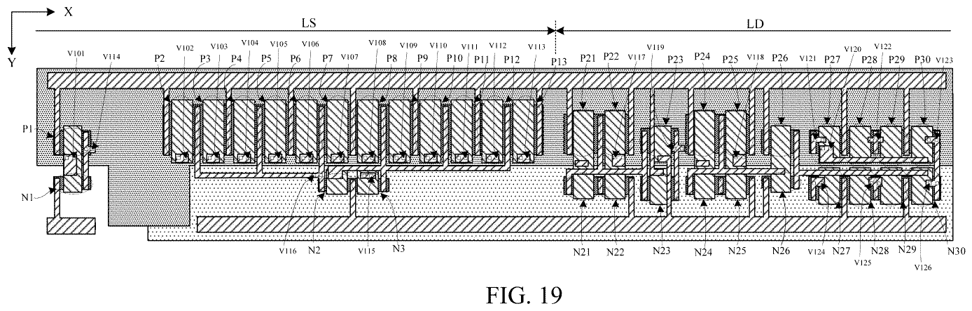

(8) A pattern of a third insulation layer is formed. In an exemplary implementation mode, forming the pattern of the third insulation layer may include: depositing a third insulation thin film on the silicon base substrate, on which the aforementioned patterns are formed, and patterning the third insulation thin film through a patterning process to form the third insulation layer covering the pattern of the first conductive layer. A plurality of via holes are disposed on the third insulation layer, as shown in FIG. 19.

In an exemplary implementation, the plurality of via holes may include a 101st via hole V101 to a 126th via hole V126.

In an exemplary implementation, an orthographic projection of the 101st via hole V101 on the silicon base substrate is within a range of an orthographic projection of the first connection electrode 601 on the silicon base substrate. The third insulation layer within the 101st via hole V101 is etched away to expose a surface of the first connection electrode 601, and the 101st via hole V101 is configured such that a first signal line formed sequentially is connected to the first connection electrode 601 through the 101st via hole.

In an exemplary implementation, an orthographic projection of the 102nd via hole V102 on the silicon base substrate is within a range of an orthographic projection of the second connection electrode 602 on the silicon base substrate. The third insulation layer within the 102nd via hole V102 is etched away to expose a surface of the second connection electrode 602, and the 102nd via hole V102 is configured such that a first signal line formed sequentially is connected to the second connection electrode 602 through the 102nd via hole.

In an exemplary implementation, an orthographic projection of the 103rd via hole V103 on the silicon base substrate is within a range of an orthographic projection of the third connection electrode 603 on the silicon base substrate. The third insulation layer within the 103rd via hole V103 is etched away to expose a surface of the third connection electrode 603, and the 103rd via hole V103 is configured such that a first signal line formed sequentially is connected to the third connection electrode 603 through the 103rd via hole.

In an exemplary implementation, an orthographic projection of the 104th via hole V104 on the silicon base substrate is within a range of an orthographic projection of the fourth connection electrode 604 on the silicon base substrate. The third insulation layer within the 104th via hole V104 is etched away to expose a surface of the fourth connection electrode 604, and the 104th via hole V104 is configured such that a first signal line formed sequentially is connected to the fourth connection electrode 604 through the 104th via hole.

In an exemplary implementation, an orthographic projection of the 105th via hole V105 on the silicon base substrate is within a range of an orthographic projection of the fifth connection electrode 605 on the silicon base substrate. The third insulation layer within the 105th via hole V105 is etched away to expose a surface of the fifth connection electrode 605, and the 105th via hole V105 is configured such that a first signal line formed sequentially is connected to the fifth connection electrode 605 through the 105th via hole.

In an exemplary implementation, an orthographic projection of the 106th via hole V106 on the silicon base substrate is within a range of an orthographic projection of the sixth connection electrode 606 on the silicon base substrate. The third insulation layer within the 106th via hole V106 is etched away to expose a surface of the sixth connection electrode 606, and the 106th via hole V106 is configured such that a first signal line formed sequentially is connected to the sixth connection electrode 606 through the 106th via hole.

In an exemplary implementation, an orthographic projection of the 107th via hole V107 on the silicon base substrate is within a range of an orthographic projection of the seventh connection electrode 607 on the silicon base substrate. The third insulation layer within the 107th via hole V107 is etched away to expose a surface of the seventh connection electrode 607, and the 107th via hole V107 is configured such that a first signal line formed sequentially is connected to the seventh connection electrode 607 through the 107th via hole.

In an exemplary implementation, an orthographic projection of the 108th via hole V108 on the silicon base substrate is within a range of an orthographic projection of the eighth connection electrode 608 on the silicon base substrate. The third insulation layer within the 108th via hole V108 is etched away to expose a surface of the eighth connection electrode 608, and the 108th via hole V108 is configured such that a first signal transfer line formed sequentially is connected to the eighth connection electrode 608 through the 108th via hole.

In an exemplary implementation, an orthographic projection of the 109th via hole V109 on the silicon base substrate is within a range of an orthographic projection of the ninth connection electrode 609 on the silicon base substrate. The third insulation layer within the 109th via hole V109 is etched away to expose a surface of the ninth connection electrode 609, and the 109th via hole V109 is configured such that a first signal transfer line formed sequentially is connected to the ninth connection electrode 609 through the 109th via hole.

In an exemplary implementation, an orthographic projection of the 110th via hole V110 on the silicon base substrate is within a range of an orthographic projection of the tenth connection electrode 610 on the silicon base substrate. The third insulation layer within the 110th via hole V110 is etched away to expose a surface of the tenth connection electrode 610, and the 110th via hole V110 is configured such that a first signal transfer line formed sequentially is connected to the tenth connection electrode 610 through the 110th via hole.

In an exemplary implementation, an orthographic projection of the 111th via hole V111 on the silicon base substrate is within a range of an orthographic projection of the eleventh connection electrode 611 on the silicon base substrate. The third insulation layer within the 111th via hole V111 is etched away to expose a surface of the eleventh connection electrode 611, and the 111th via hole V111 is configured such that a first signal transfer line formed sequentially is connected to the eleventh connection electrode 611 through the 111th via hole.

In an exemplary implementation, an orthographic projection of the 112th via hole V112 on the silicon base substrate is within a range of an orthographic projection of the twelfth connection electrode 612 on the silicon base substrate. The third insulation layer within the 112th via hole V112 is etched away to expose a surface of the twelfth connection electrode 612, and the 112th via hole V112 is configured such that a first signal transfer line formed sequentially is connected to the twelfth connection electrode 612 through the 112th via hole.

In an exemplary implementation, an orthographic projection of the 113th via hole V113 on the silicon base substrate is within a range of an orthographic projection of the thirteenth connection electrode 613 on the silicon base substrate. The third insulation layer within the 113th via hole V113 is etched away to expose a surface of the thirteenth connection electrode 613, and the 113th via hole V113 is configured such that a first signal transfer line formed sequentially is connected to the thirteenth connection electrode 613 through the 113th via hole.

In an exemplary implementation, an orthographic projection of the 114th via hole V114 on the silicon base substrate is within a range of an orthographic projection of the first bump k1 on the silicon base substrate. The third insulation layer within the 114th via hole V114 is etched away to expose a surface of the first bump k1, and the 114th via hole V114 is configured such that a first signal transfer line formed sequentially is connected to the first bump k1 through the 114th via hole.

In an exemplary implementation, an orthographic projection of the 115th via hole V115 on the silicon base substrate is within a range of an orthographic projection of the fifteenth connection electrode 615 on the silicon base substrate. The third insulation layer within the 115th via hole V115 is etched away to expose a surface of the fifteenth connection electrode 615, and the 115th via hole V115 is configured such that a second signal transfer line formed sequentially is connected to the fifteenth connection electrode 615 through the 115th via hole.

In an exemplary implementation, an orthographic projection of the 116th via hole V116 on the silicon base substrate is within a range of an orthographic projection of the first connection line 701 on the silicon base substrate. The third insulation layer within the 116th via hole V116 is etched away to expose a surface of the first connection line 701, and the 116th via hole V116 is configured such that a second signal transfer line formed sequentially is connected to the first connection line 701 through the 116th via hole.

In an exemplary implementation, an orthographic projection of the 117th via hole V117 on the silicon base substrate is within a range of an orthographic projection of the thirty-sixth connection electrode 636 on the silicon base substrate. The third insulation layer within the 117th via hole V117 is etched away to expose a surface of the thirty-sixth connection electrode 636, and the 117th via hole V117 is configured such that a second signal line formed sequentially is connected to the thirty-sixth connection electrode 636 through the 117th via hole.

In an exemplary implementation, an orthographic projection of the 118th via hole V118 on the silicon base substrate is within a range of an orthographic projection of the fortieth connection electrode 640 on the silicon base substrate. The third insulation layer within the 118th via hole V118 is etched away to expose a surface of the fortieth connection electrode 640, and the 118th via hole V118 is configured such that a second signal line formed sequentially is connected to the fortieth connection electrode 640 through the 118th via hole.

In an exemplary implementation, an orthographic projection of the 119th via hole V119 on the silicon base substrate is within a range of an orthographic projection of the second bump k2 on the silicon base substrate. The third insulation layer within the 119th via hole V119 is etched away to expose a surface of the second bump k2, and the 119th via hole V119 is configured such that a third signal transfer line formed sequentially is connected to the second bump k2 through the 119th via hole.

In an exemplary implementation, an orthographic projection of the 120th via hole V120 on the silicon base substrate is within a range of an orthographic projection of the forty-second connection electrode 642 on the silicon base substrate. The third insulation layer within the 120th via hole V120 is etched away to expose a surface of the forty-second connection electrode 642, and the 120th via hole V120 is configured such that a third signal transfer line formed sequentially is connected to the forty-second connection electrode 642 through the 120th via hole.

In an exemplary implementation, an orthographic projection of the 121st via hole V121 on the silicon base substrate is within a range of an orthographic projection of the third bump k3 on the silicon base substrate. The third insulation layer within the 121th via hole V121 is etched away to expose a surface of the third bump k3, and the 121th via hole V121 is configured such that a fourth signal transfer line formed sequentially is connected to the third bump k3 through the 121th via hole.

In an exemplary implementation, an orthographic projection of the 122nd via hole V122 on the silicon base substrate is within a range of an orthographic projection of the fourth bump k4 on the silicon base substrate. The third insulation layer within the 122th via hole V122 is etched away to expose a surface of the fourth bump k4, and the 122th via hole V122 is configured such that a fourth signal transfer line formed sequentially is connected to the fourth bump k4 through the 122th via hole.

In an exemplary implementation, an orthographic projection of the 123rd via hole V123 on the silicon base substrate is within a range of an orthographic projection of the fifth bump k5 on the silicon base substrate. The third insulation layer within the 123rd via hole V123 is etched away to expose a surface of the fifth bump k5, and the 123th via hole V123 is configured such that a fourth signal transfer line formed sequentially is connected to the fifth bump k5 through the 123th via hole.

In an exemplary implementation, an orthographic projection of the 124th via hole V124 on the silicon base substrate is within a range of an orthographic projection of the sixth bump k6 on the silicon base substrate. The third insulation layer within the 124th via hole V124 is etched away to expose a surface of the sixth bump k6, and the 124th via hole V124 is configured such that a fifth signal transfer line formed sequentially is connected to the sixth bump k6 through the 124th via hole.

In an exemplary implementation, an orthographic projection of the 125th via hole V125 on the silicon base substrate is within a range of an orthographic projection of the seventh bump k7 on the silicon base substrate. The third insulation layer within the 125th via hole V125 is etched away to expose a surface of the seventh bump k7, and the 125th via hole V125 is configured such that a fifth signal transfer line formed sequentially is connected to the seventh bump k7 through the 125th via hole.

In an exemplary implementation, an orthographic projection of the 126th via hole V126 on the silicon base substrate is within a range of an orthographic projection of the eighth bump k8 on the silicon base substrate. The third insulation layer within the 126th via hole V126 is etched away to expose a surface of the eighth bump k8, and the 126th via hole V126 is configured such that a fifth signal transfer line formed sequentially is connected to the eighth bump k8 through the 126th via hole.

In an exemplary implementation, there may be a plurality of 101st via holes V101 to 126th via holes V126 to reduce the contact resistance and improve the connection reliability.

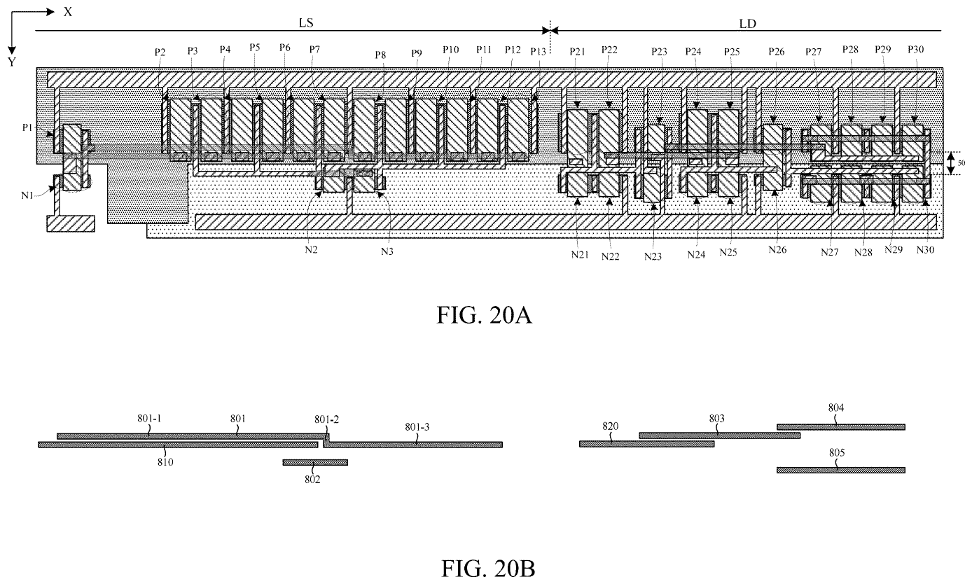

(9) A pattern of a second conductive layer is formed. In an exemplary implementation, forming the pattern of the second conductive layer may include: depositing a second conductive thin film on the silicon base, on which the aforementioned patterns are formed, and patterning the second conductive thin film through the patterning process to form the pattern of the second conductive layer on the third insulation layer. As shown in FIGS. 20A and 20B. FIG. 20B is a schematic diagram of the second conductive layer in FIG. 20A. In an exemplary implementation, the second conductive layer may be referred to as a second metal (Metal2) layer.

In an exemplary implementation, the pattern of the second conductive layer may at least include a first signal transfer line 801, a second signal transfer line 802, a third signal transfer line 803, a fourth signal transfer line 804, a fifth signal transfer line 805, a first signal line 810, and a second signal line 820.

In an exemplary implementation, the first signal line 810 may be in a shape of a straight line extending along the first direction X or a bend line. The first signal line 810 may be connected to the first connection electrode 601 through the 101st via hole V101, connected to the second connection electrode 602 through the 102nd via hole V102, connected to the third connection electrode 603 through the 103rd via hole V103, connected to the fourth connection electrode 604 through the 104th via hole V104, connected to the fifth connection electrode 605 through the 105th via hole V105, connected to the sixth connection electrode 606 through the 106th via hole V106, and connected to the seventh connection electrode 607 through the 107th via hole V107, the first signal line 810 may write the input signal to the P-type gate electrode of the first P-type transistor P1, the N-type gate electrode of the first N-type transistor N1, the P-type gate electrode of the second P-type transistor P2, the P-type gate electrode of the third P-type transistor P3, the P-type gate electrode of the fourth P-type transistor P4, the P-type gate electrode of the fifth P-type transistor P5, the P-type gate electrode of the sixth P-type transistor P6, and the P-type gate electrode of the seventh P-type transistor P7, to control the first N-type transistor N1, the first P-type transistor P1 to the seventh P-type transistor P7 to be turned on and off.

In an exemplary implementation, the first signal line 810 may be disposed in the gap region 50 between the P-type active region and the N-type active region, which is not only beneficial for optimization of the connection structure, but also may reduce the influence on channel regions of transistors.

In an exemplary implementation, the first signal line 810 may be located on a side of the gap region 50 close to the P-type active region, which may reduce the influence on the N-type transistor.

In an exemplary implementation, the first signal line 810 may be an input signal line of a level converter and also an output signal line of a logic operation unit in a gate driving circuit.

In an exemplary implementation, the second signal line 820 may be a straight line extending along the first direction X or a bend line, and the second signal line 820 may be connected to the thirty-sixth connection electrode 636 through the 117th via hole V117, and connected to the fortieth connection electrode 640 through the 118th via hole V118. Because the thirty-sixth connection electrode 636 is connected to the twenty-second P-type gate electrode 222P (also the twenty-second N-type gate electrode 222N) through a via hole, and the fortieth connection electrode 640 is connected to the twenty-fifth P-type gate electrode 225P (also the twenty-fifth N-type gate electrode 225N) through a via hole, thus a mutual connection between a P-type gate electrode of the twenty-second P-type transistor P22, a P-type gate electrode of the twenty-second N-type transistor N22, a P-type gate electrode of the twenty-fifth P-type transistor P25, and a P-type gate electrode of the twenty-fifth N-type transistor N25 is achieved. The second signal line 820 may simultaneously write an enabling signal to the P-type gate electrode of the twenty-second P-type transistor P22, the P-type gate electrode of the twenty-second N-type transistor N22, the P-type gate electrode of the twenty-fifth P-type transistor P25, and the P-type gate electrode of the twenty-fifth N-type transistor N25 to control the twenty-second P-type transistor P22, the twenty-second N-type transistor N22, the twenty-fifth P-type transistor P25 and the twenty-fifth P-type transistor N25 to be turned on and off.

In an exemplary implementation, the second signal line 820 may be an enabling signal line of the level converter.

In an exemplary implementation, the second signal line 820 may be located in the gap region 50 between the P-type active region and the N-type active region, which is not only beneficial for optimization of the connection structure, but also may reduce the influence on channel regions of transistors.

In an exemplary implementation, the second signal line 820 may be disposed on a side of the gap region 50 close to the P-type active region, which may reduce the influence on the N-type transistor.

In an exemplary implementation, the first signal transfer line 801 may be in a shape of a bend line extending along the first direction X. The first signal transfer line 801 may be connected to the first bump k1 through the 114th via hole V114, connected to the eighth connection electrode 608 through the 108th via hole V108, connected to the ninth connection electrode 609 through the 109th via hole V109, connected to the tenth connection electrode 610 through the 110th via hole V110, connected to the eleventh connection electrode 611 through the 111th via hole V111, connected to the twelfth connection electrode 612 through the 112th via hole V112, and connected to the thirteenth connection electrode 613 through the 113th via hole V113. Because the first bump k1 is connected to the seventeenth connection electrode 617, and the seventeenth connection electrode 617 is connected to the first P-type drain region and the first N-type drain region through a via hole, thus the first signal transfer line achieves a mutual connection between a second electrode of the first P-type transistor P1, a second electrode of the first N-type transistor N1, a P-type gate electrode of the eighth P-type transistor P8, a P-type gate electrode of the ninth P-type transistor P9, a P-type gate electrode of the tenth P-type transistor P10, a P-type gate electrode of the eleventh P-type transistor P11, a P-type gate electrode of the twelfth P-type transistor P12, and a P-type gate electrode of the thirteenth P-type transistor P13.

In an exemplary implementation, the first signal transfer line 801 may include a first transfer sub-line 801-1, a second transfer sub-line 801-2, and a third transfer sub-line 801-3 connected sequentially, wherein a first end of the first transfer sub-line 801-1 is connected to the first bump k1, a second end of the first transfer sub-line 801-1 is connected to a first end of the second transfer sub-line 801-2 after extending along the first direction X, and a second end of the second transfer sub-line 801-2 is connected to a first end of the third transfer sub-line 801-3 after extending along the second direction Y, and a second end of the third transfer sub-line 801-3 extends along the first direction X and is respectively connected to the eighth connection electrode 608, the ninth connection electrode 609, the tenth connection electrode 610, the eleventh connection electrode 611, the twelfth connection electrode 612, and the thirteenth connection electrode 613.

In an exemplary implementation, the first transfer sub-line 801-1 may be disposed on a side of the first signal line 810 close to the first power supply line 51 (that is, away from the second N-type transistor N2), and an orthographic projection of the first transfer sub-line 801-1 on the silicon base substrate is at least partially overlapped with orthographic projections of the channel regions of the second P-type transistor P2 to the seventh P-type transistor P7 (the second P-type active region 102P to the seventh P-type transistor P7) on the silicon base substrate, that is, the first transfer sub-line 801-1 crosses the channel regions of the second P-type transistor P2 to the seventh P-type transistor P7 to save the wiring space.

In an exemplary implementation, in the second direction Y, the first transfer sub-line 801-1 may be disposed on a side of the second P-type active region 102P to the seventh P-type active region 107P close to the second power supply line 52 (i.e. close to the second N-type transistor N2).

In an exemplary implementation, the third transfer sub-line 801-3 may be located in the gap region 50 between the P-type active region and the N-type active region, and is located on a side of the second connection line 702 close to the first power supply line 51, which is not only beneficial for optimization of the connection structure, but also may reduce the influence on channel regions of transistors.

In an exemplary implementation, the second signal transfer line 802 may be in a shape of a straight line extending along the first direction X or a bend line, and the second signal transfer line 802 may be connected to the fifteenth connection electrode 615 through the 115th via hole V115, and connected to the first connection line 701 through the 116th via hole V116. Because the fifteenth connection electrode 615 is connected to the third N-type gate electrode 203N through a via hole, and the first connection line 701 is respectively connected to a second electrode of the second P-type transistor P2 to a second electrode of the seventh P-type transistor P7 and a second electrode of the second N-type transistor N2, thus the second signal transfer line achieves a mutual connection between the second electrode of the second P-type transistor P2, the second electrode of the third P-type transistor P3, the second electrode of the fourth P-type transistor P4, the second electrode of the fifth P-type transistor P5, the second electrode of the sixth P-type transistor P6, the second electrode of the seventh P-type transistor P7, the second electrode of the second N-type transistor N2, and the gate electrode of the third N-type transistor N3.

In an exemplary implementation, the second signal transfer line 802 may be located in the gap region 50 between the P-type active region and the N-type active region, which is not only beneficial for optimization of the connection structure, but also may reduce the influence on channel regions of transistors.

In an exemplary implementation, the second signal transfer line 802 may be disposed on a side of the gap region 50 close to the N-type active region, which may reduce the influence on the P-type transistor.

In an exemplary implementation, the third signal transfer line 803 may be in a shape of a straight line extending along the first direction X or a bend line, and the third signal transfer line 803 may be connected to the second bump k2 through the 119th via hole V119, and connected to the forty-second connection electrode 642 through the 120th via hole V120. Because the forty-second connection electrode 642 is respectively connected to a gate electrode of the twenty-seventh P-type transistor P 27 to a gate electrode of the thirtieth P-type transistor P 30, the second bump k2 is connected to the forty-eighth connection electrode 648 and the sixty-third connection electrode 663, the forty-eighth connection electrode 648 is connected to the twenty-third P-type drain region through a via hole, and the sixty-third connection electrode 663 is connected to the twenty-third N-type drain region through a via hole, the third signal transfer line 803 achieves a mutual connection between a second electrode of the twenty-third P-type transistor P23, a second electrode of the twenty-third P-type transistor N23, a gate electrode of the twenty-seventh P-type transistor P27, a gate electrode of the twenty-eighth P-type transistor P28, a gate electrode of the twenty-ninth P-type transistor P29 and a gate electrode of the thirtieth P-type transistor P30.

In an exemplary implementation, the third signal transfer line 803 may be disposed on a side of the second signal line 820 close to the first power supply line 51 (that is, away from the N-type active layer), and an orthographic projection of the third signal transfer line 803 on the silicon base substrate is at least partially overlapped with orthographic projections of channel regions of the twenty-fourth P-type transistor P24, the twenty-fifth P-type transistor P25, and the twenty-sixth P-type transistor P26 (the twenty-fourth P-type active region 124P, the twenty-fifth P-type active region 125P, and the twenty-sixth P-type transistor P26) on the silicon base substrate, that is, the third signal transfer line 803 crosses the channel regions of the twenty-fourth P-type transistor P24 to the twenty-sixth P-type transistor P26 to save the wiring space.

In an exemplary implementation, along the first direction X, an extension length of the third signal transfer line 803 may be greater than an extension length of the second signal line 820.

In an exemplary implementation, in the second direction Y, a spacing between the second signal line 820 and the third connection line 703 (the fourth connection line 704) may be larger than a spacing between the second signal line 820 and the third signal transfer line 803, which may ensure the accuracy of the gate via hole and improve the process quality.

In an exemplary implementation, the fourth signal transfer line 804 may be in a shape of a straight line extending along the first direction X or a bend line, and the fourth signal transfer line 804 may be connected to the third bump k3 through the 121st via hole V121, connected to the fourth bump k4 through the 122nd via hole V122, and connected to the fifth bump k5 through the 123rd via hole V123. Because the third bump k3 is connected to the fifty-fourth connection electrode 654, the fifty-fourth connection electrode 654 is connected to the twenty-seventh P-type drain region through a via hole, the fourth bump k4 is connected to the fifty-sixth connection electrode 656, the fifty-sixth connection electrode 656 is connected to the twenty-eighth P-type drain region through a via hole, the fifth bump k5 is connected to the fifty-eighth connection electrode 658, and the fifty-eighth connection electrode 658 is connected to the thirtieth P-type drain region through a via hole, thus the fourth signal transfer line 804 achieves a mutual connection between a second electrode of the twenty-seventh P-type transistor P27, a second electrode of the twenty-eighth P-type transistor P28, a second electrode of the twenty-ninth P-type transistor P29, and a second electrode of the thirtieth P-type transistor P30.

In an exemplary implementation, for the twenty-seventh P-type transistor P27 and the twenty-eighth P-type transistor P28 with a parallel structure, the P-type drain electrode of the twenty-seventh P-type transistor P27 (the third bump k3) is located on a side of the twenty-seventh P-type transistor P27 in an opposite direction to the first direction X, the P-type drain electrode of the twenty-eighth P-type transistor P28 (the fourth bump k4) is located on a side of the twenty-eighth P-type transistor P28 in the first direction X, and the fourth signal transfer line 804 is respectively connected to the third bump k3 and the fourth bump k4, that is, the fourth signal transfer line 804 crosses these two P-type transistors and is respectively connected to different sides of the two P-type transistors, and the twenty-seventh P-type transistor P27 and the twenty-eighth P-type transistor P28 are respectively connected to the fourth signal transfer line 804 on different sides.

In an exemplary implementation, for the twenty-ninth P-type transistor P29 and the thirtieth P-type transistor P30 of with a parallel structure, the P-type drain electrode of the twenty-ninth P-type transistor P29 (the fourth bump k4) is located on a side of the twenty-ninth P-type transistor P29 in an opposite direction to the first direction X, the P-type drain electrode of the thirtieth P-type transistor P30 (the fifth bump k5) is located on a side of the thirtieth P-type transistor P30 in the first direction X, and the fourth signal transfer line 804 is respectively connected to the fourth bump k4 and the fifth bump k5, that is, the fourth signal transfer line 804 crosses these two P-type transistors and is respectively connected to different sides of the two P-type transistors, and the twenty-ninth P-type transistor P29 and the thirtieth P-type transistor P30 are respectively connected to the fourth signal transfer line 804 on different sides.

In an exemplary implementation, the fourth signal transfer line 804 may be disposed on a side of the forty-second connection electrode 642 close to the first power supply line 51, and an orthographic projection of the fourth signal transfer line 804 on the silicon base substrate is at least partially overlapped with orthographic projections of channel regions of the twenty-seventh P-type transistor P27 to the thirtieth P-type transistor P30 on the silicon base substrate to save wiring space.

In an exemplary implementation, in the second direction Y, with respect to a P-type channel center line, the fourth signal transfer line 804 may be disposed on a side of the P-type channel center line close to the first power supply line 51, and the P-type channel center line is a straight line that bisects the channel regions of the twenty-seventh P-type transistor P27 to the thirtieth P-type transistor P30 in the second direction Y and extends along the first direction X.

In an exemplary implementation, the fifth signal transfer line 805 may be in a shape of a straight line extending along the first direction X or a bend line, and the fifth signal transfer line 805 may be connected to the sixth bump k6 through the 124th via hole V124, connected to the seventh bump k7 through the 125th via hole V125, and connected to the eighth bump k8 through the 126th via hole V126. Because the sixth bump k6 is connected to the sixty-ninth connection electrode 669, the sixty-ninth connection electrode 669 is connected to the twenty-seventh N-type drain region through a via hole, the seventh bump k7 is connected to the seventy-first connection electrode 671, the seventy-first connection electrode 671 is connected to the twenty-eighth N-type drain region (also the twenty-ninth N-type drain region) through a via hole, the eighth bump k8 is connected to the seventy-third connection electrode 673, and the seventy-third connection electrode 673 is connected to the thirtieth N-type drain region through a via hole, thus the fifth signal transfer line achieves a mutual connection between a second electrode of the twenty-seventh N-type transistor N27, a second electrode of the twenty-eighth N-type transistor N28, a second electrode of the twenty-ninth N-type transistor N29, and a second electrode of the thirtieth P-type transistor P30.

In an exemplary implementation, for the twenty-seventh N-type transistor N27 and the twenty-eighth N-type transistor N28 with a parallel structure, the N-type drain electrode of the twenty-seventh N-type transistor N27 (the sixth bump k6) is located on a side of the twenty-seventh N-type transistor N27 in an opposite direction to the first direction X, the N-type drain electrode of the twenty-eighth N-type transistor N28 (the seventh bump k7) is located on a side of the twenty-eighth N-type transistor N28 in the first direction X, and the fifth signal transfer line 805 is respectively connected to the sixth bump k6 and the seventh bump k7, that is, the fifth signal transfer line 805 crosses these two N-type transistors and is respectively connected to different sides of the two N-type transistors, and the twenty-seventh N-type transistor N27 and the twenty-eighth N-type transistor N28 are respectively connected to the fifth signal transfer line 805 on different sides.

In an exemplary implementation, for the twenty-ninth N-type transistor N29 and the thirtieth N-type transistor N30 with a parallel structure, the N-type drain electrode of the twenty-ninth N-type transistor N29 (the seventh bump k7) is located on a side of the twenty-ninth N-type transistor N29 in an opposite direction to the first direction X, the N-type drain electrode of the thirtieth N-type transistor N30 (the eighth bump k8) is located on a side of the thirtieth N-type transistor N30 in the first direction X, and the fifth signal transfer line 805 is respectively connected to the seventh bump k7 and the eighth bump k8, that is, the fifth signal transfer line 805 crosses these two N-type transistors and is respectively connected to different sides of the two N-type transistors, and the twenty-ninth N-type transistor N29 and the thirtieth N-type transistor N30 are respectively connected to the fifth signal transfer line 804 on different sides.

In an exemplary implementation, the fifth signal transfer line 805 may be disposed on a side of the forty-third connection electrode 643 close to the second power supply line 52, and an orthographic projection of the fifth signal transfer line 805 on the silicon base substrate is at least partially overlapped with orthographic projections of channel regions of the twenty-seventh N-type transistor N27 to the thirtieth N-type transistor N30 on the silicon base substrate to save wiring space.

In an exemplary implementation, in the second direction Y, with respect to an N-type channel center line, the fifth signal transfer line 805 may be disposed on a side of the N-type channel center line close to the first power supply line 51, and the N-type channel center line is a straight line that bisects the channel regions of the twenty-seventh N-type transistor N27 to the thirtieth N-type transistor N30 in the second direction Y and extends along the first direction X.

In the exemplary implementation, because the fifty-eighth connection electrode 658 and the seventy-third connection electrode 673 are connected to each other, it is achieved that the fourth signal transfer line and the fifth signal transfer line are connected to each other, and a mutual connection between a second electrode of the twenty-seventh P-type transistor P27, a second electrode of the twenty-seventh N-type transistor N27, a second electrode of the twenty-eighth P-type transistor P28, a second electrode of the twenty-eighth N-type transistor N28, a second electrode of the twenty-ninth P-type transistor P29, a second electrode of the twenty-ninth N-type transistor P29, a second electrode of the thirtieth P-type transistor P30 and a second electrode of the thirtieth N-type transistor N30 are achieved. In an exemplary implementation, the fourth signal transfer line or the fifth signal transfer line may serve as output signal lines of the row driving enhancer. The fourth signal transfer line or the fifth signal transfer line may extend to the display region, is connected to the first scanning signal line, the second scanning signal line, or the third scanning signal line of one pixel row in the display region, and provide a scanning signal to the connected scanning signal line.

In the exemplary implementation, the fourth signal transfer line 804 is disposed on a side of the P-type channel center line close to the first power supply line, and the fifth signal transfer line 805 is disposed on a side of the N-type channel center line close to the first power supply line, which may ensure the process uniformity and improve the product quality.

In an exemplary implementation, the subsequent flow may include patterns of a fourth insulation layer and a third conductive layer, and the third conductive layer may at least include one signal connection line. For example, one signal connection line may be respectively connected to the second connection line 702 and the thirty-fifth connection electrode 635 through a via hole to achieve a connection between a first output end OUT_shifter of the converter and the first input end IN_driver of the level converter and the enhancer. As another example, another signal connection line may be respectively connected to the first connection line 701 and the thirty-ninth connection electrode 639 through a via hole to achieve a connection between the second output end OUT_B_shifter of the converter and the second input end IN_B_driver of the level converter and the enhancer.

So far, the preparation of the display substrate according to an exemplary implementation of the present disclosure is completed.

In an exemplary implementation, the first insulation layer to the third insulation layer may adopt silicon oxide SiOx, silicon nitride SiNx, silicon oxynitride SiON, or the like, and may be of a single-layer structure, or may be of a multilayer composite structure. The first metal layer and the second metal layer may be made of a metal material, such as Argentum (Ag), Copper (Cu), Aluminum (Al), or Molybdenum (Mo), or may be made of an alloy material formed by metals, such as Aluminum Neodymium (AlNd) alloy or Molybdenum Niobium (MoNb) alloy, and the alloy material may be a single-layer structure or may be a multi-layer composite structure, such as a composite structure formed by an Mo layer, a Cu layer, and an Mo layer. In an exemplary implementation, a plane shape of a via hole may be a rectangle, a circle, or an ellipse. Sizes of a plurality of via holes may be the same or different, and the present disclosure is not limited thereto.

An exemplary embodiment of the present disclosure provides a display substrate, which is capable of driving a display panel having a pixel density of 4K or more through a reasonable layout of an output circuit, and may be applied to a silicon-based OLED display apparatus having a pixel density of 4K or more.

In the present disclosure, by setting the minimum distance between active regions of transistors in the signal control circuit portion, the occupied space of the row driving enhancer can be effectively reduced, thereby reducing the length of the signal line and the input impedance. In the present disclosure, a minimum distance between an active region of the transistors in the signal control circuit portion and an active region of the transistors in the signal output circuit portion is set, which may effectively reduce a mutual influence between the transistors in the signal control portion and the transistors in the signal output portion, thereby improving the operation reliability and ensuring the signal control and the signal output.

In the present disclosure, a plurality of transistors in the first P-type transistor unit and a plurality of transistors in the second P-type transistor unit are disposed to be mirror-symmetrical with respect to the active center line O, which may ensure the symmetry of the transistor units in the level converter, and improve the consistency of outputting high and low levels.

In the present disclosure, the minimum distance between the ground line and the second power supply line is set, which may not only avoid the breakdown of the insulation layer, but also reduce the mutual influence between the ground line and the second power supply line, and improve the stability of the level converter circuit.

In the present disclosure, the minimum distance between the transistors in the two voltage domains is set, which may reduce a mutual influence between the transistors in the two voltage domains, and may improve the stability of the level converter circuit.

In the present disclosure, positions of a plurality of gate connection via holes are set, which may not only ensure process uniformity and signal transmission uniformity, but also may be beneficial for the arrangement of the connection electrodes, optimizing a connection structure between the first conductive layer and the gate conductive layer, and reducing the occupied area of the gate drive circuit.

In the present disclosure, the positions of the connection lines and the signal transfer lines are set, which may be beneficial for layout arrangement, optimizing the connection structure, reducing the influence on the channel region of the transistor, and improving the circuit quality and signal quality of the gate driving circuit.

In the present disclosure, through the above structural design, the layout of the gate driving circuit is optimized, the layout space is optimized, the occupied area of the gate driving circuit is reduced, the circuit quality and the signal quality are improved, which may achieve higher display quality and display effect.

The preparation process of the present disclosure may be achieved by using mature preparation equipment, with little process improvement, high compatibility, simple process realization, easy implementation, high production efficiency, low production cost, and high yield rate.

A structure of the display substrate and the preparation process thereof according to exemplary embodiments of the present disclosure are described by way of example only. Corresponding structures may be changed and patterning processes may be added or reduced according to actual needs, the present disclosure is not limited thereto.

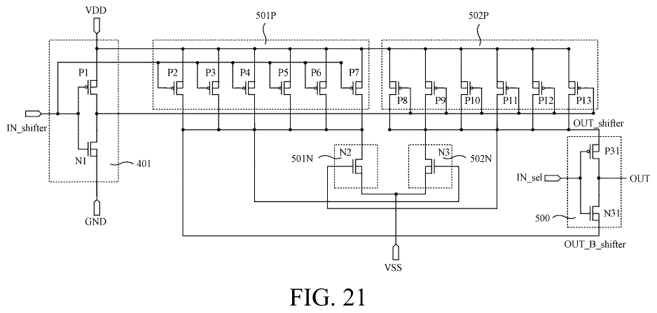

FIG. 21 is an equivalent circuit diagram of another level converter according to an exemplary embodiment of the present disclosure. As shown in FIG. 21, a structure of a level converter of a gate driving circuit in a display substrate of an embodiment of the present disclosure is substantially the same as that of the level converter of FIG. 9, and includes a first inverter 401, a first P-type transistor unit 501P, a second P-type transistor unit 502P, a first N-type transistor unit 501N, and a second N-type transistor unit 502N, except that the level converter of the present embodiment further includes a selection output unit 500, which is configured to select an output of the level converter.

In an exemplary implementation, the selection output unit 500 may include a thirty-first P-type transistor P31 and a thirty-first N-type transistor N31. A gate electrode of the thirty-first P-type transistor P31 and the gate electrode of the thirty-first N-type transistor N31 are connected to each other and are connected to a selection signal input end IN_sel, a first electrode of the thirty-first P-type transistor P31 is connected to a first output end OUT_shifter of the converter, a first electrode of the thirty-first N-type transistor N31 is connected to a second output end OUT_B_shifter of the converter, and a second electrode of the thirty-first P-type transistor P31 and a second electrode of the thirty-first N-type transistor N31 are connected to each other and are connected to an output end OUT.

In the exemplary implementation, when the selection input signal of the selection signal input end IN_sel is at a low level, the thirty-first P-type transistor P31 is turned on, the thirty-first N-type transistor N31 is turned off, and the output end OUT outputs a signal of the first output end OUT_shifter of the converter. When the selection input signal of the selection signal input end IN_sel is at a high level, the thirty-first P-type transistor P31 is turned off, the thirty-first N-type transistor N31 is turned on, and the output end OUT outputs a signal of the second output end OUT_B_shifter of the converter.

In the present disclosure, the selection output unit is provided so that the level converter may selectively output the signal of the first output end OUT_shifter of the converter or the signal of the second output end OUT_B_shifter of the converter, and the application range of the gate driving circuit may be increased.

An exemplary embodiment of the present disclosure further provides a display apparatus, including the aforementioned display substrate. The display apparatus of the present disclosure may be used in a Virtual Reality (VR) device, an augmented display (AR) device, an Extended Reality (XR) device, a Mixed Reality (MR) device, an aiming tool, a rangefinder, and the like.

Although implementation modes disclosed in the present disclosure are as above, it should be noted that the above implementation modes are exemplary only rather than restrictive. Therefore, the present disclosure is not limited to what is specifically shown and described herein. Various modifications, substitutions or omissions may be made in forms and details of implementation without departing from the scope of the present disclosure.

1. A gate driving circuit, comprising an output circuit disposed on a silicon base substrate, wherein the output circuit comprises at least one level converter and at least one row driving enhancer, the level converter is configured to perform voltage domain conversions on target timings, the row driving enhancer is configured to enhance converted signals and output the converted signals to a scanning signal line of a display region, at least one input signal of the row driving enhancer is provided by the level converter, and the row driving enhancer is disposed on a side of the level converter close to the display region.

2. The gate driving circuit according to claim 1, wherein the level converter comprises at least a first inverter, a first level conversion unit, and a second level conversion unit; an input end of the first level conversion unit is connected to an input end of the first inverter, an output end of the first level conversion unit is connected to the row driving enhancer; an input end of the second level conversion unit is connected to an output end of the first inverter, an output end of the second level conversion unit is connected to the row driving enhancer; the first level conversion unit is disposed on a side of the first inverter close to the display region, and the second level conversion unit is disposed on a side of the first level conversion unit close to the display region.

3. The gate driving circuit according to claim 2, wherein the level converter further comprises a selection output unit, which is respectively connected to the output end of the first level conversion unit and the output end of the second level conversion unit, and the selection output unit is configured to selectively output an output signal of the first level conversion unit or an output signal of the second level conversion unit under control of a selection input signal.

4. The gate driving circuit according to claim 2, wherein the first inverter comprises a first P-type transistor and a first N-type transistor disposed on a side of the first P-type transistor in a second direction; the first level conversion unit comprises a first P-type transistor unit disposed on a side of the first P-type transistor in a first direction and a first N-type transistor unit disposed on a side of the first P-type transistor unit in the second direction, the second level conversion unit comprises a second P-type transistor unit disposed on a side of the first P-type transistor unit in the first direction and a second N-type transistor unit disposed on a side of the second P-type transistor unit in the second direction, and the first direction is intersected with the second direction; the first P-type transistor unit comprises a second P-type transistor to a seventh P-type transistor disposed on a side of the first P-type transistor in the first direction and sequentially along the first direction; the second P-type transistor unit comprises an eighth P-type transistor to a thirteenth P-type transistor disposed on a side of the seventh P-type transistor in the first direction and sequentially along the first direction; the first N-type transistor unit comprises a second N-type transistor disposed on a side of the seventh P-type transistor in the second direction, and the second N-type transistor unit comprises a third N-type transistor disposed on a side of the eighth P-type transistor in the second direction; at least one P-type transistor comprises at least a P-type active layer, at least one N-type transistor comprises at least an N-type active layer, and the P-type active layers of the second P-type transistor to the thirteenth P-type transistor are of an integral structure connected to each other; the second P-type transistor to the seventh P-type transistor and the eighth P-type transistor to the thirteenth P-type transistor are symmetrical with respect to an active center line, the second N-type transistor and the third N-type transistor are symmetrical with respect to the active center line, the active center line is a straight line that bisects the P-type active layers of the second P-type transistor to the thirteenth P-type transistor in the first direction and extends along the second direction.

5. The gate driving circuit according to claim 4, wherein the at least one P-type transistor further comprises a P-type gate electrode, and the at least one N-type transistor further comprises an N-type gate electrode; P-type gate electrodes of the second P-type transistor to the seventh P-type transistor and P-type gate electrodes of the eighth P-type transistor to the thirteenth P-type transistor are symmetrical with respect to the active center line and the N-type gate electrode of the second N-type transistor, and the N-type gate electrode of the third N-type transistor are symmetrical with respect to the active center line.

6. The gate driving circuit according to claim 5, wherein there is a first length between an edge of the P-type gate electrode of the second P-type transistor on a side away from the active center line and the active center line, there is a second length between an edge of the P-type gate electrode of the thirteenth P-type transistor on a side away from the active center line and the active center line, and a ratio of the first length to the second length is 0.95 to 1.05; and there is a third length between an edge of the N-type gate electrode of the second N-type transistor on a side away from the active center line and the active center line, there is a fourth length between an edge of the N-type gate electrode of the third N-type transistor on a side away from the active center line and the active center line, and a ratio of the third length to the fourth length is 0.95 to 1.05.

7. The gate driving circuit of claim 4, wherein the at least one P-type transistor further comprises a P-type source electrode and a P-type drain electrode, and the at least one N-type transistor further comprises an N-type source electrode and an N-type drain electrode; P-type source electrodes of the second to seventh P-type transistors and P-type source electrodes of the eighth to thirteenth P-type transistors are symmetrical with respect to the active center line, and P-type drain electrodes of the second to seventh P-type transistors and P-type drain electrodes of the eighth to thirteenth P-type transistors are symmetrical with respect to the active center line; the N-type source electrode of the second N-type transistor and the N-type source electrode of the third N-type transistor are symmetrical with respect to the active center line, and the N-type drain electrode of the second N-type transistor and the N-type drain electrode of the third N-type transistor are symmetrical with respect to the active center line.

8. The gate driving circuit according to claim 7, wherein there is a eleventh length between an edge of the P-type source electrode of the second P-type transistor on a side away from the active center line and the active center line, there is a twelfth length between an edge of the P-type source electrode of the thirteenth P-type transistor on a side away from the active center line and the active center line, and a ratio of the eleventh length to the twelfth length is 0.95 to 1.05; and there is a thirteenth length between an edge of the N-type drain electrode of the second N-type transistor on a side away from the active center line and the active center line, there is a fourteenth length between an edge of the N-type drain electrode of the third N-type transistor on a side away from the active center line and the active center line, in and a ratio of the thirteenth length to the fourteenth length is 0.95 to 1.05.

9. The gate driving circuit according to claim 4, wherein in the first direction, there is a voltage domain distance between an edge of the P-type drain electrode of the first P-type transistor on a side close to the second P-type transistor and an edge of the P-type source electrode of the second P-type transistor on a side close to the first P-type transistor, and the voltage domain distance is greater than or equal to 3.67 μm.

10. The gate driving circuit according to claim 4, wherein the level converter further comprises a first power supply line, a second power supply line, and a ground line, and the first power supply line, the second power supply line, and the ground line are in a shape of a line extending along the first direction or a bend line; the first power supply line is disposed on a side of the first P-type transistor to the thirteenth P-type transistor away from the first N-type transistor to the third N-type transistor, the second power supply line is disposed on a side of the second N-type transistor to the third N-type transistor away from the second P-type transistor to the thirteenth P-type transistor, and the ground line is disposed on a side of the first N-type transistor away from the first P-type transistor; and there is a voltage line distance between an edge of the second power supply line on a side close to the ground line and an edge of the ground line on a side close to the second power supply line, and the voltage line distance is greater than or equal to 5 μm.

11. The gate driving circuit according to claim 4, wherein in the second direction, a dimension of the P-type transistor in the first P-type transistor unit is larger than a dimension of the P-type transistor in the first inverter, and a dimension of the P-type transistor in the second P-type transistor unit is larger than a dimension of the P-type transistor in the first inverter.

12. The gate driving circuit according to claim 4, wherein the at least one P-type transistor further comprises a P-type gate electrode and the at least one N-type transistor further comprises an N-type gate electrode; the level converter further comprises a first signal line, wherein one end of the first signal line is connected to the P-type gate electrode of the first P-type transistor and the N-type gate electrode of the first N-type transistor, and the other end of the first signal line is respectively connected to P-type gate electrodes of the second P-type transistor to the seventh P-type transistor; the first signal line is disposed in a gap region between a P-type active region and an N-type active region, and is located on a side of the gap region close to the P-type active region.

13. The gate driving circuit according to claim 12, wherein the at least one P-type transistor further comprises a P-type drain electrode and the at least one N-type transistor further comprises an N-type drain electrode; the level converter further comprises a first signal transfer line, wherein one end of the first signal transfer line is connected to the P-type drain electrode of the first P-type transistor and the N-type drain electrode of the first N-type transistor, and the other end of the first signal transfer line is respectively connected to P-type gate electrodes of the eighth P-type transistor to the thirteenth P-type transistor; at least a portion of the first signal transfer line is disposed on a side of the first signal line away from the second N-type transistor, an orthographic projection of the first signal line on the silicon base substrate is at least partially overlapped with orthographic projections of channel regions of the second P-type transistor to the seventh P-type transistor on the silicon base substrate; and at least a portion of the first signal transfer line is disposed in the gap region between the P-type active region and the N-type active region, and is located on a side of the gap region close to the P-type active region.

14. The gate driving circuit according to claim 12, wherein the at least one P-type transistor further comprises a P-type drain electrode and the at least one N-type transistor further comprises an N-type drain electrode; the level converter further comprises a first connection line and a second connection line, P-type drain electrodes of the second P-type transistor to the seventh P-type transistor are connected to the N-type drain electrode of the second N-type transistor through the first connection line, and P-type drain electrodes of the eighth P-type transistor to the thirteenth P-type transistor are connected to the N-type drain electrode of the third N-type transistor through the second connection line; and the first connection line and the second connection line are disposed in the gap region between the P-type active region and the N-type active region, and are located on a side of the gap region close to the N-type active region.

15. The gate driving circuit according to claim 14, wherein the level converter further comprises a second signal transfer line, the first connection line is connected to the N-type gate electrode of the third N-type transistor through the second signal transfer line, and the second connection line is directly connected to the N-type gate electrode of the second N-type transistor; and the second signal transfer line is disposed in the gap region between the P-type active region and the N-type active region, and is located on a side of the gap region close to the N-type active region.

16. The gate driving circuit according to claim 15, wherein in a direction perpendicular to the silicon base substrate, the output circuit comprises at least a first conductive layer and a second conductive layer disposed on a side of the first conductive layer away from the silicon base substrate, the first connection line and the second connection line are disposed in the first conductive layer, and the second signal transfer line is disposed in the second conductive layer.

17. The gate driving circuit according to claim 1, wherein the row driving enhancer comprises a plurality of transistor groups disposed sequentially along a first direction, at least one transistor group comprises a P-type transistor and an N-type transistor disposed on a side of the P-type transistor in a second direction, the first direction is intersected with the second direction; a plurality of transistor groups form a first NAND gate, a first transmission gate, a second NAND gate, a second inverter, and an output unit disposed sequentially along a direction close to the display region, wherein there is a first distance between a transistor group in the second inverter and a transistor group in the output unit, there is a second distance between two adjacent transistor groups in the first NAND gate, the first transmission gate, the second NAND gate and the second inverter, the first distance is larger than the second distance, and both the first distance and the second distance are dimensions in the first direction.

18-19. (canceled)

20. The gate driving circuit according to claim 17, wherein there is a first distance between the P-type transistor in the second inverter and the P-type transistor in the output unit, and there is a second distance between two adjacent P-type transistors in the first NAND gate, the first transmission gate, the second NAND gate, and the second inverter; and/or there is a first distance between the N-type transistor in the second inverter and the N-type transistor in the output unit, and there is a second distance between two adjacent N-type transistors in the first NAND gate, the first transmission gate, the second NAND gate, and the second inverter.

21-38. (canceled)

39. A display substrate, comprising a display region and a non-display region, wherein the display region comprises a plurality of sub-pixels, and at least one sub-pixel comprises a pixel driving circuit and at least one scanning signal line, the at least one scanning signal line is configured to provide a scanning signal to the connected pixel driving circuit; and the non-display region comprises a plurality of gate driving circuits which are cascaded, at least one gate driving circuit is connected to a scanning signal line in the display region, and at least one gate driving circuit comprises the gate driving circuit according to claim 1.

40. A display apparatus, comprising the display substrate according to claim 39.
